(19) United States
(12) Patent Application Publication
(10) Pub. No.: US 2010/0167199 A1
(43) Pub. Date: Jul. 1, 2010

(54) CHEMICALLY AMPLIFIED POSITIVE RESIST COMPOSITION

(75) Inventors: Takayuki MIYAGAWA, Osaka (JP); Satoshi Yamamoto, Kawabe-gun (JP); Yusuke Fuji, Osaka (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: SUMITOMO CHEMICAL COMPANY, LIMITED, Chuo-ku (JP)

(21) Appl. No.: 12/641,914

(22) Filed: Dec. 18, 2009

(30) Foreign Application Priority Data
Dec. 25, 2008 (JP) 2008-331127

(51) Int. Cl. G03F 7/004

(52) U.S. Cl. 430/270.1

(57) ABSTRACT

A chemically amplified positive resist composition comprising: a resin comprising a structural unit having an acid-labile group in a side chain and an acid generator wherein the resin contains 40 to 90% by mole of the structural unit having an acid-labile group in a side chain based on all the structural units and the structural unit having an acid-labile group in a side chain contains a structural unit represented by the formula (I):

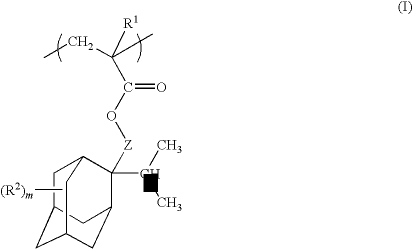

wherein R¹ represents a hydrogen atom or a methyl group, Z represents a single bond or —(CH₂)ₖ—CO—O—, k represents an integer of 1 to 4, R² is independently in each occurrence a C1-C6 alkyl group, and m represents an integer of 0 to 14.

This nonprovisional application claims priority under 35 U.S.C. §119 (a) on Patent Application No. 2008-331127 filed in JAPAN on Dec. 25, 2008, the entire contents of which are hereby incorporated by reference.

### FIELD OF THE INVENTION

The present invention relates to a chemically amplified positive resist composition.

### BACKGROUND OF THE INVENTION

A chemically amplified positive resist composition used for semiconductor microfabrication employing a lithography process contains an acid generator comprising a compound generating an acid by irradiation.

U.S. Pat. No. 6,239,231 B1 discloses a chemically amplified positive resist composition comprising a resin which comprises a structural unit derived from 2-ethyl-2-adamantyl methacrylate, a structural unit derived from 3-hydroxy-1-adamantyl methacrylate and a structural unit derived from α-methacryloyloxy-γ-butyrolactone, and an acid generator.

US 2005/0100819 A1 disclose a chemically amplified positive resist composition comprising a resin which comprises a structural unit derived from 2-isopropyl-2-adamantyl methacrylate, a structural unit derived from 3-hydroxy-1-adamantyl methacrylate and a structural unit derived from 5-acryloyloxy-2,6-norbornenelactone, and an acid generator.

### SUMMARY OF THE INVENTION

The present invention is to provide a chemically amplified positive resist composition.

The present invention relates to the followings:
<1> A chemically amplified positive resist composition comprising: a resin comprising a structural unit having an acid-labile group in a side chain and an acid generator wherein the resin contains 40 to 90% by mole of the structural unit having an acid-labile group in a side chain based on total molar amounts of all the structural units and the structural unit having an acid-labile group in a side chain contains a structural unit represented by the formula (I):

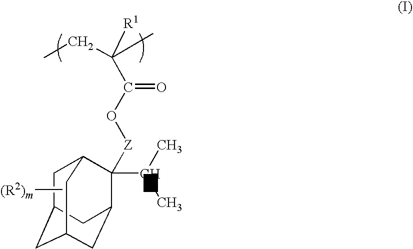

wherein R¹ represents a hydrogen atom or a methyl group, Z represents a single bond or —(CH₂)ₖ—CO—O—, k represents an integer of 1 to 4, R² is independently in each occurrence a C1-C6 alkyl group, and m represents an integer of 0 to 14;
<2> The chemically amplified positive resist composition according to <1>, wherein the resin contains 50 to 70% by mole of the structural unit having an acid-labile group in a side chain based on total molar amounts of all the structural units;
<3> The chemically amplified positive resist composition according to <1> or <2>, wherein the structural unit having an acid-labile group in a side chain further contains a structural unit represented by the formula (II):

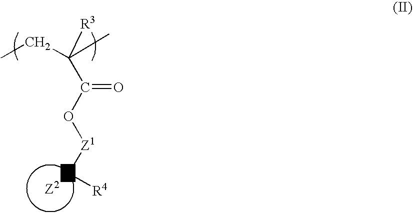

wherein R³ represents a hydrogen atom or a methyl group, Z¹ represents a single bond or —(CH₂)ⱼ—CO—O—, j represents an integer of 1 to 4, R⁴ represents a C1-C8 alkyl group or a C3-C8 cycloalkyl group, and ring Z² represents an unsubstituted or substituted C3-C30 cyclic hydrocarbon group, in addition to the structural unit represented by the formula (I), with the proviso that the structural unit represented by the formula (II) is different from the unit represented by the formula (I);
<4> The chemically amplified positive resist composition according to <1>, <2> or <3>, wherein the resin further contains a structural unit represented by the formula (IV):

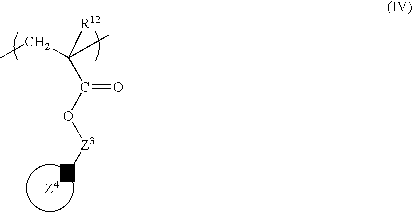

wherein R¹² represents a hydrogen atom or a methyl group, Z³ represents a single bond or —(CH₂)ᵢ—CO—O—, i represents an integer of 1 to 4, and ring Z⁴ represents an unsubstituted or substituted C3-C30 cyclic hydrocarbon group having —CO—O— in the ring structure;
<5> The chemically amplified positive resist composition according to any one of <1> to <4>, wherein the acid generator is an acid generator represented by the formula (V):

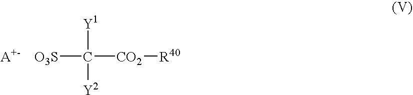

wherein Y¹ and Y² each independently represent a fluorine atom or a C1-C6 perfluoroalkyl group, R⁴⁰ represents a C1-C36 hydrocarbon group which may have at least one selected from the group consisting of a C1-C6 alkoxy group, a C1-C4 perfluoroalkyl group, a C1-C6 hydroxyalkyl group, a hydroxyl group and a cyano group, and one or more —CH₂— in the hydrocarbon group may be replaced by —CO—, —O— or —COO—, and A⁺ represents an organic counter ion.

### DESCRIPTION OF PREFERRED EMBODIMENTS

The present resist composition comprises a resin comprising a structural unit having an acid-labile group in a side chain and an acid generator, and the resin contains 40 to 90% by mole of the structural unit having an acid-labile group in a side chain based on total molar amounts of all the structural units, and the structural unit having an acid-labile group in a side chain contains a structural unit represented by the formula (I):

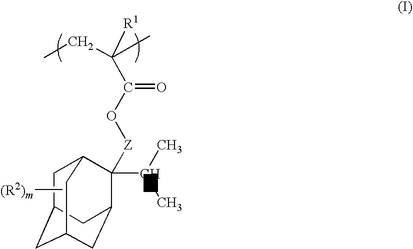

(hereinafter, simply referred to as the structural unit (I)).

The resin preferably contains 45 to 70% by mole of the structural unit having an acid-labile group in a side chain based on total molar amounts of all the structural units.

In this specification, “an acid-labile group” means a group capable to eliminate by the action of an acid.

In the present specification, “ester group” means “a structure having ester of carboxylic acid”. Specifically, “tert-butyl ester group” is “a structure having tert-butyl ester of carboxylic acid”, and may be described as “—COOC(CH₃)₃”.

In the formula (I), R¹ represents a hydrogen atom or a methyl group, Z represents a single bond or —(CH₂)ₖ—CO—O—, k represents an integer of 1 to 4, R² is independently in each occurrence a C1-C6 alkyl group, and m represents an integer of 0 to 14.

Examples of the C1-C6 alkyl group include a methyl group, an ethyl group, a propyl group, an isopropyl group, a butyl group, an isobutyl group, a sec-butyl group, tert-butyl group, a pentyl group and a hexyl group, and a methyl group is preferable.

Z is preferably a single bond.

Examples of the structural unit (I) include the followings.

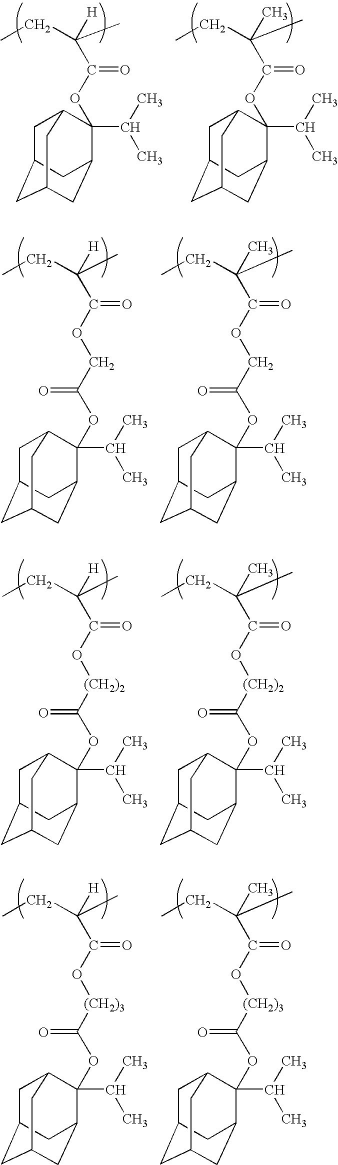

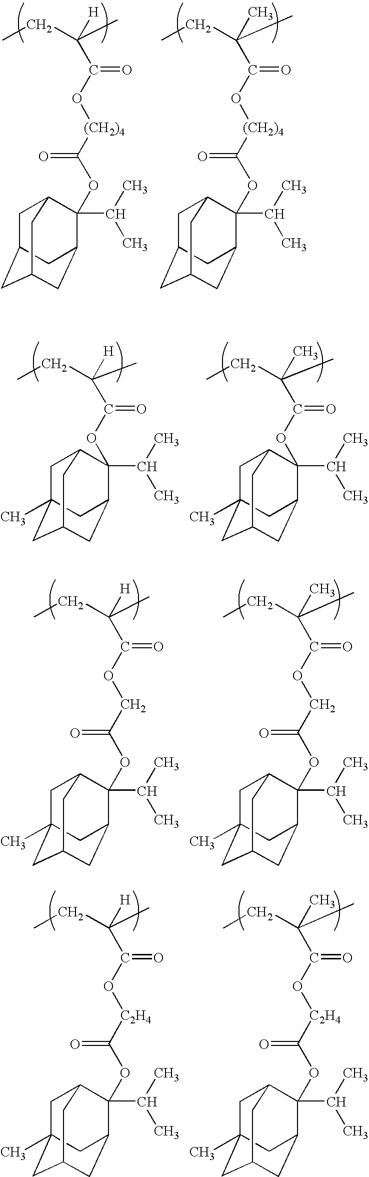

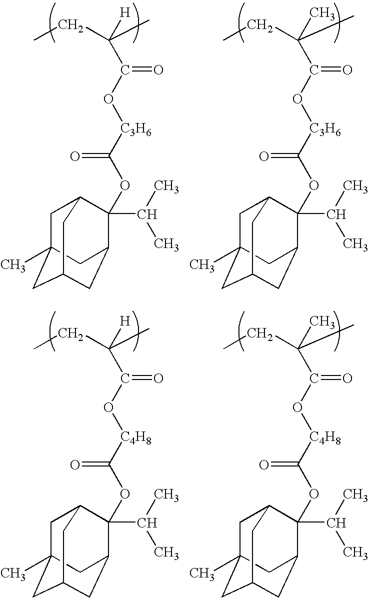

The structural unit (I) is a structural unit having an acid-labile group in its side chain.

The content of the structural unit (I) is usually 30 to 100 mol %, preferably 60 to 100 mol % and more preferably 80 to 100 mol % based on total molar amounts of all the structural units having an acid-labile group in its side chain.

Examples of the acid-labile group include a structure having ester of carboxylic acid such as an alkyl ester group in which a carbon atom adjacent to the oxygen atom is quaternary carbon atom, an alicyclic ester group in which a carbon atom adjacent to the oxygen atom is quaternary carbon atom, and a lactone ester group in which a carbon atom adjacent to the oxygen atom is quaternary carbon atom. The “quaternary carbon atom” means a “carbon atom joined to four substituents other than hydrogen atom”.

Examples of the acid-labile group include an alkyl ester group in which a carbon atom adjacent to the oxygen atom is quaternary carbon atom such as a tert-butyl ester group; an acetal type ester group such as a methoxymethyl ester, ethoxymethyl ester, 1-ethoxyethyl ester, 1-isobutoxyethyl ester, 1-isopropoxyethyl ester, 1-ethoxypropoxy ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester and tetrahydro-2-pyranyl ester group; an alicyclic ester group in which a carbon atom adjacent to the oxygen atom is quaternary carbon atom such as an isobornyl ester, 1-alkylcycloalkyl ester, 2-alkyl-2-adamantyl ester, and 1-(1-adamantyl)-1-alkylalkyl ester group.

The resin preferably contains a structural unit represented by the formula (II):

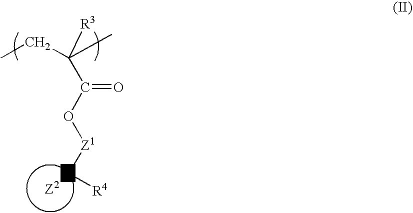

(hereinafter, simply referred to as the structural unit (II)) or a structural unit having an acetal structure, a monothioacetal structure or a dithioacetal structure in its side chain as the structural unit having an acid-labile group in a side chain.

The structural unit (II) is different from the structural unit (I).

In the formula (II), R³ represents a hydrogen atom or a methyl group, Z¹ represents a single bond or —(CH₂)ⱼ—CO—O—, j represents an integer of 1 to 4, R⁴ represents a C1-C8 alkyl group or a C3-C8 cycloalkyl group, and ring Z² represents an unsubstituted or substituted C3-C30 cyclic hydrocarbon group.

Examples of the C1-C8 alkyl group include a methyl group, an ethyl group, a propyl group, an isopropyl group, a butyl group, an isobutyl group, a sec-butyl group, tert-butyl group, a pentyl group, a hexyl group and an octyl group, and a methyl group, an ethyl group are preferable. Examples of the C3-C8 cycloalkyl group include a cyclopropyl group, a cyclobutyl group, a cyclopentyl group, a cyclohexyl group and a cyclooctyl group.

The C3-C30 cyclic hydrocarbon group preferably has no aromatic ring. Examples of the C3-C30 cyclic hydrocarbon group include a C3-C8 cycloalkyl group such as a cyclopropyl group, a cyclobutyl group, a cyclopropyl group and a cyclohexyl group, an adamantyl group and a norbornyl group.

Preferable examples of the structural unit (II) include the structural units represented by the formulae (IIa) and (IIb):

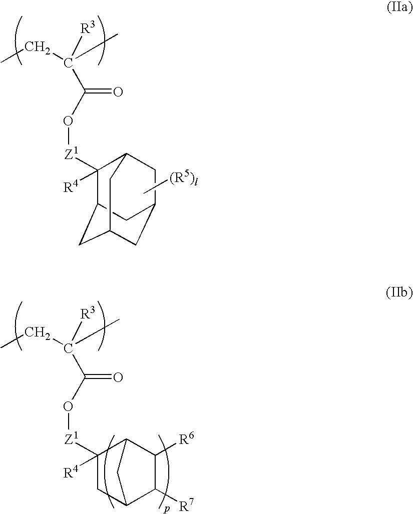

wherein R³, R⁴ and Z¹ are the same as defined above, R⁵ is independently in each occurrence a C1-C12 alkyl group or a C1-C12 alkoxy group, 1 represents an integer of 0 to 14, R⁶ and R⁷ each independently represent a hydrogen atom or a C1-C8 monovalent hydrocarbon group which may have one or more heteroatoms, or R⁶ and R⁷ may be bonded to form a C1-C8 divalent hydrocarbon group which may have one or more heteroatoms and which forms a ring together with the adjacent carbon atoms to which R⁶ and R⁷ are bonded, or R⁶ and R⁷ may be bonded to form a carbon-carbon double bond between the carbon atom to which R⁶ is bonded and the carbon atom to which R⁷ is bonded, and p represents an integer of 1 to 3 (hereinafter, simply referred to as the structural unit (IIa), (IIb), respectively).

Examples of the C1-C12 alkyl group include a methyl group, an ethyl group, a propyl group, an isopropyl group, a butyl group, an isobutyl group, a sec-butyl group, a pentyl group, an isopentyl group, a neopentyl group, a hexyl group, a heptyl group and an octyl group, and a methyl group is preferable. Examples of the C1-C12 alkoxy group include a methoxy group, an ethoxy group, a propoxy group, an isopropoxy group, a butoxy group, an isobutoxy group, a sec-butoxy group, a pentyloxy group, an isopentyloxy group, a neopentyloxy group, a hexyloxy group, a heptyloxy group and an octyloxy group.

Examples of the C1-C8 divalent hydrocarbon group formed by bonding R⁶ and R⁷ include an ethylene group and a trimethylene group.

R⁶ and R⁷ are preferably bonded to form a C2-C4 divalent hydrocarbon group which forms a C4-C6 ring together with the adjacent carbon atoms to which R⁶ and R⁷ are bonded, or R⁶ and R⁷ are preferably bonded to form a carbon-carbon double bond between the carbon atom to which R⁶ is bonded and the carbon atom to which R⁷ is bonded.

In the formula (IIa), 1 is preferably 0 or 1, and Z¹ preferably represents a single bond or —CH₂—COO—, and more preferably represents a single bond. In the formula (IIb), p is preferably 1 or 2.

The resin may have one or more structural units (II). Examples of the monomer used for giving the structural unit (IIa) include the followings:

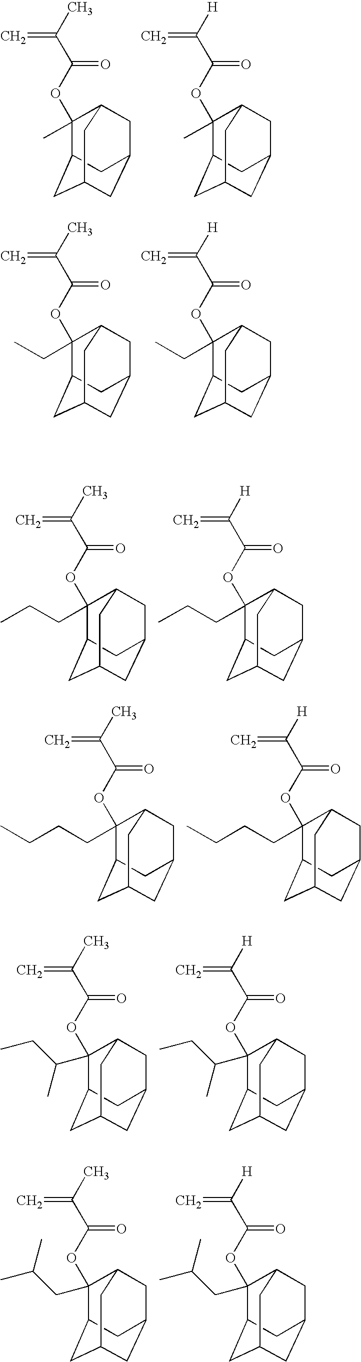

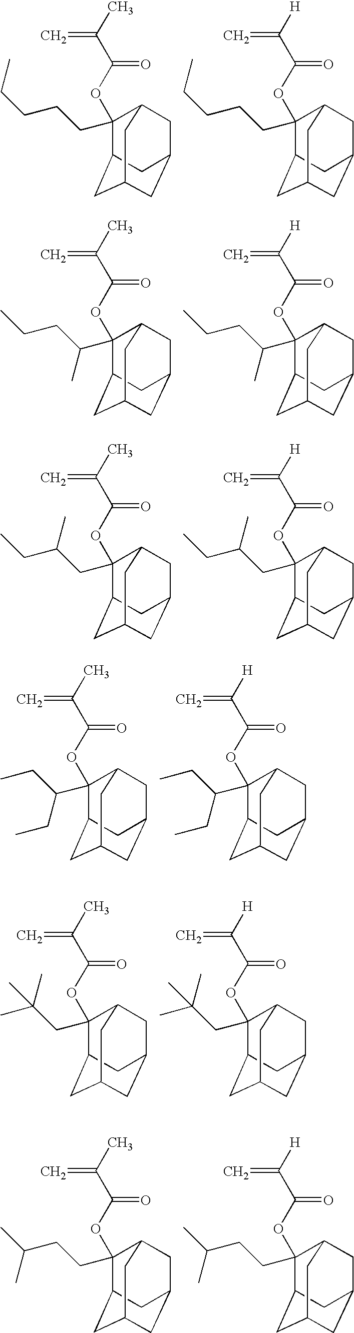

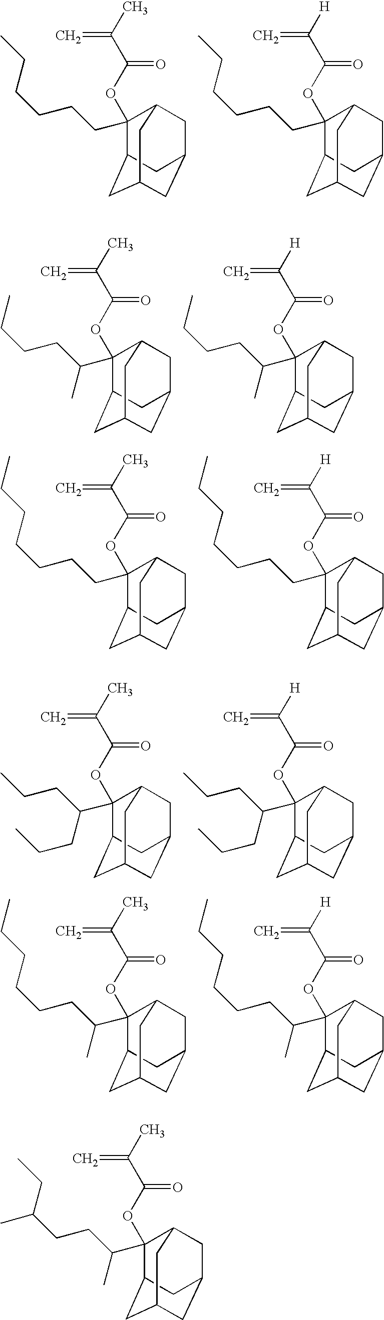

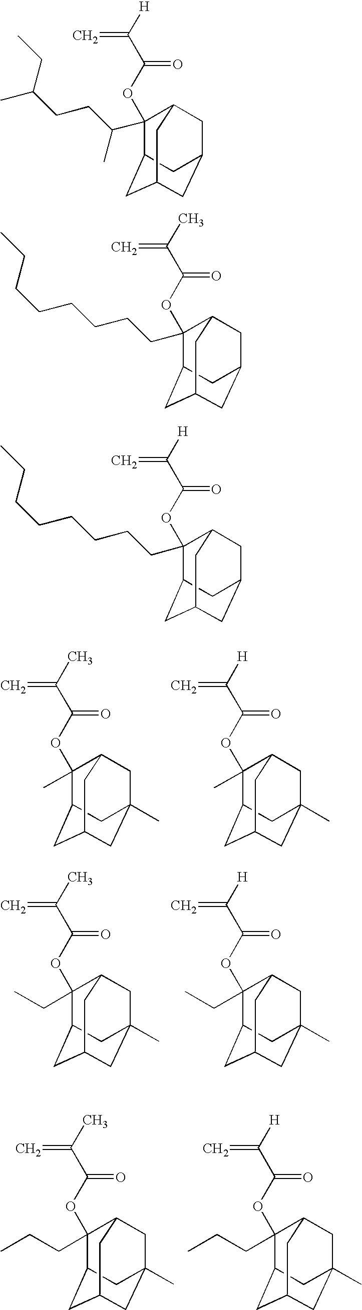

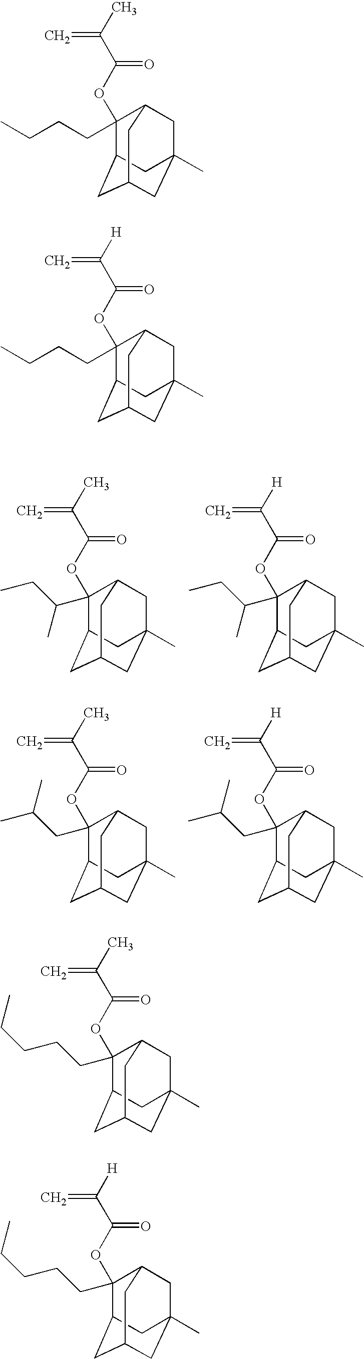

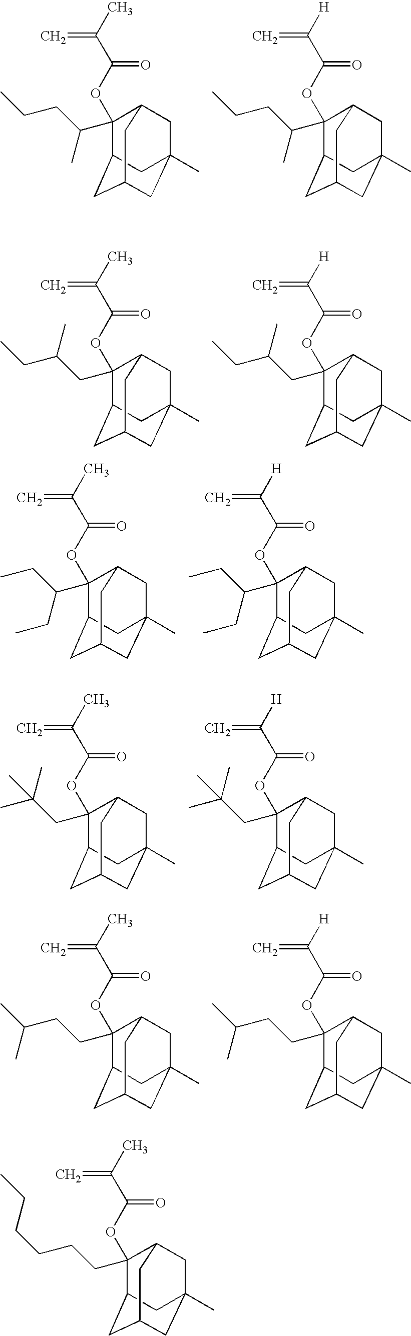

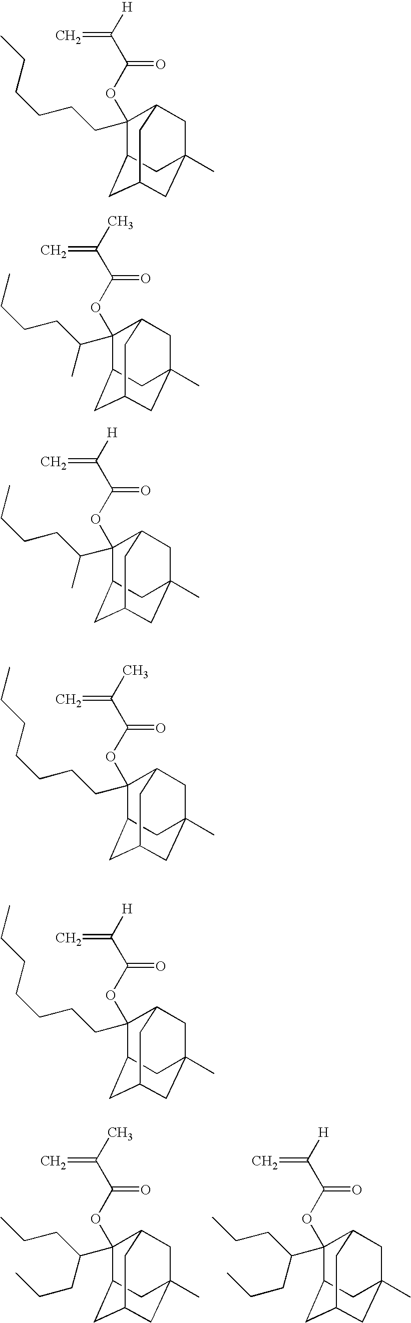

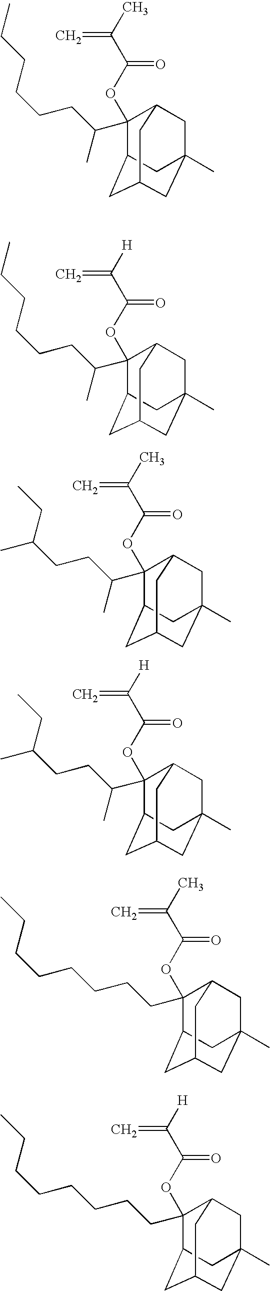

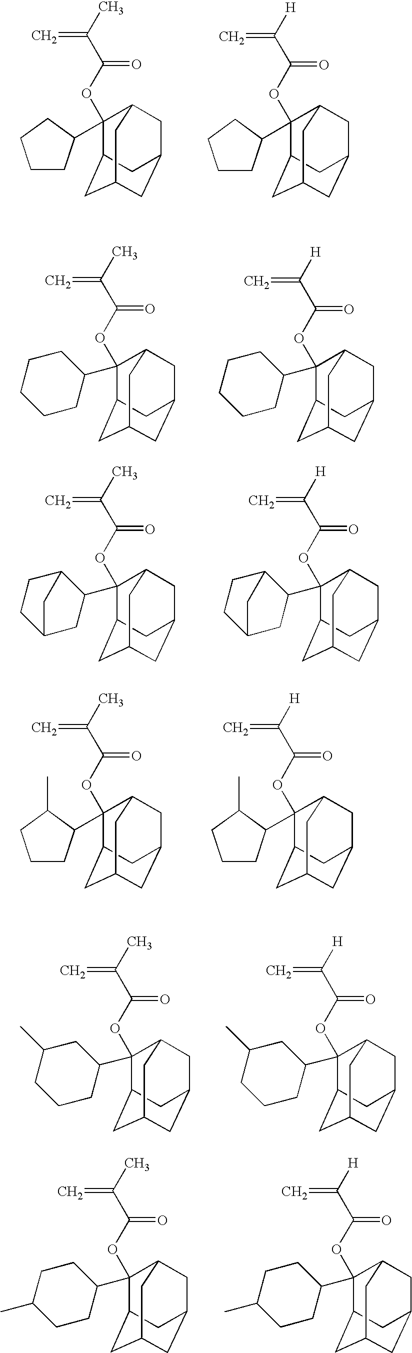

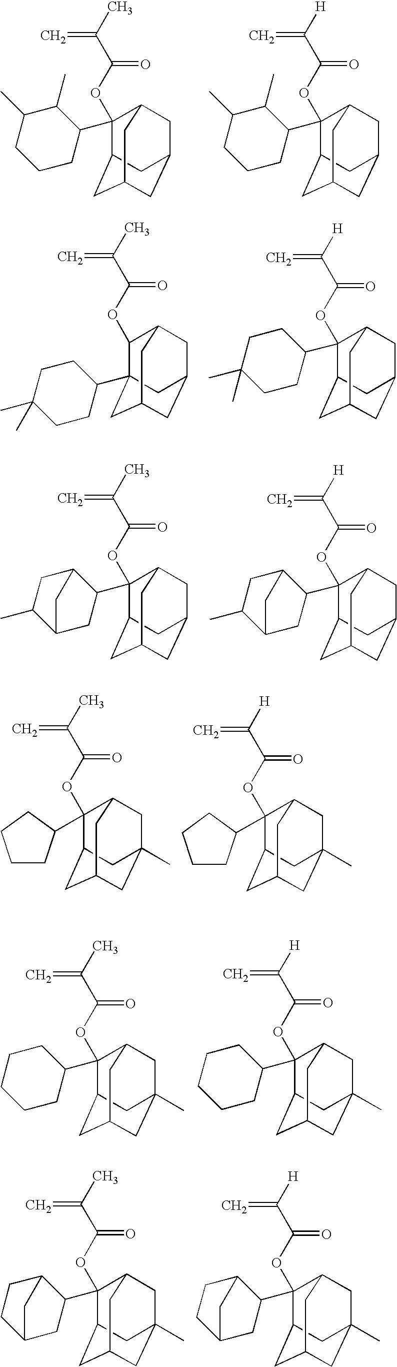

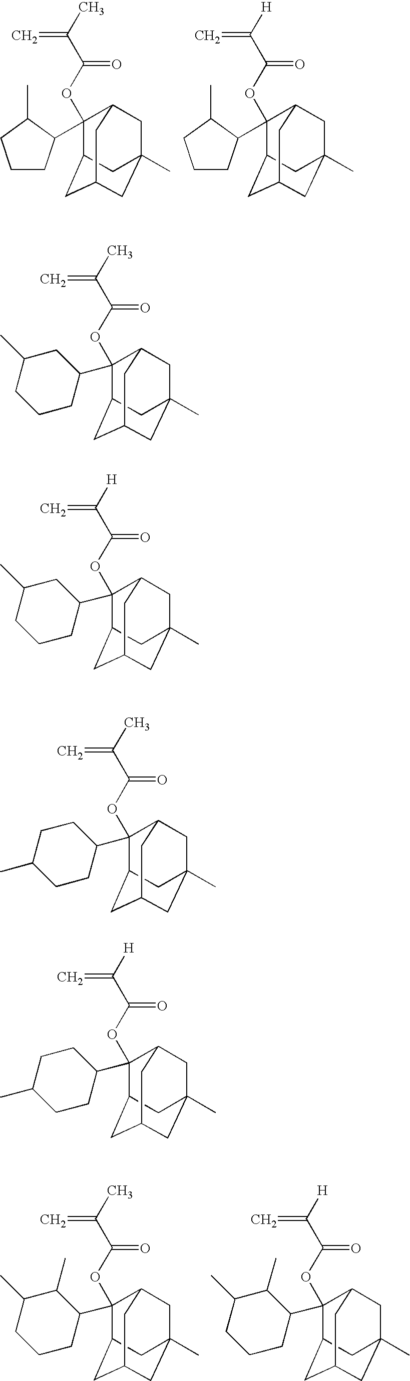

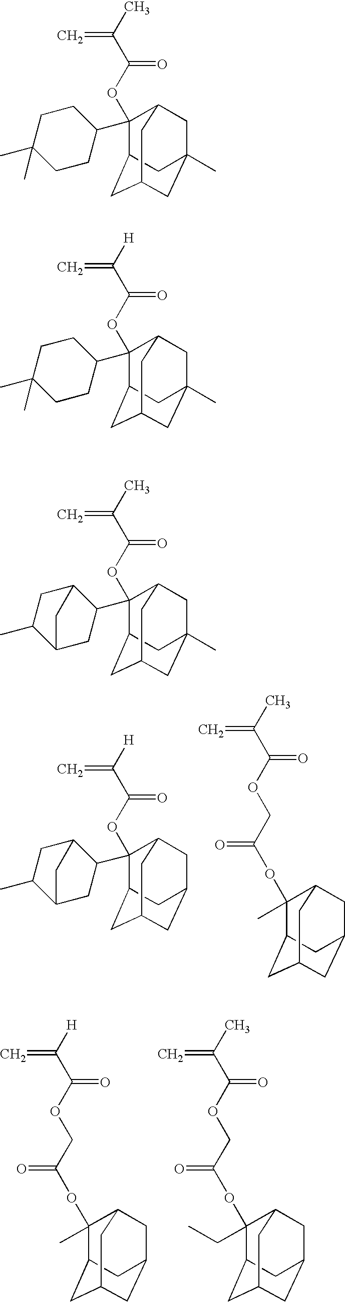

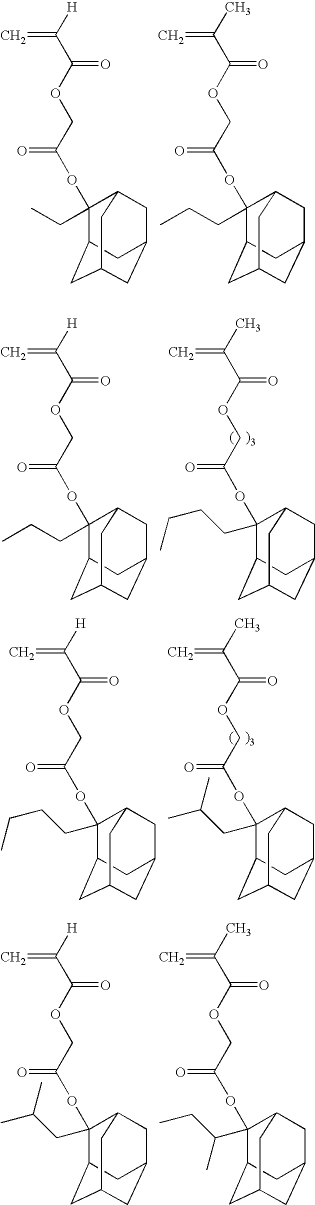

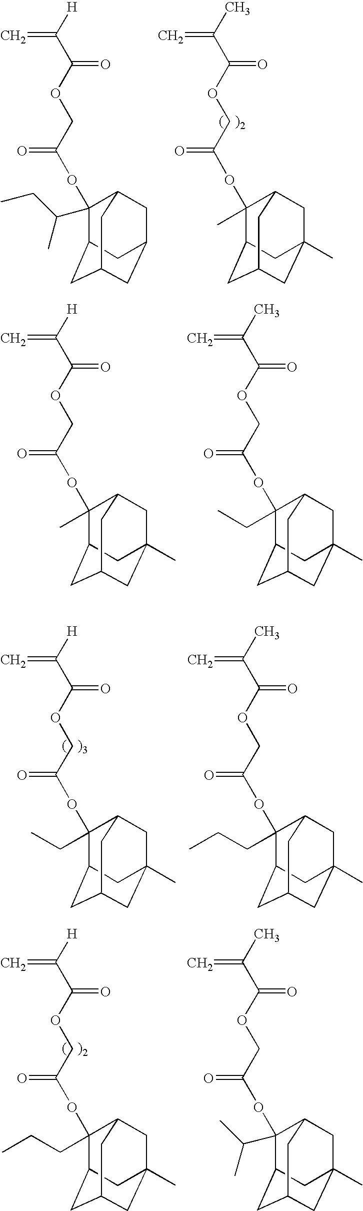

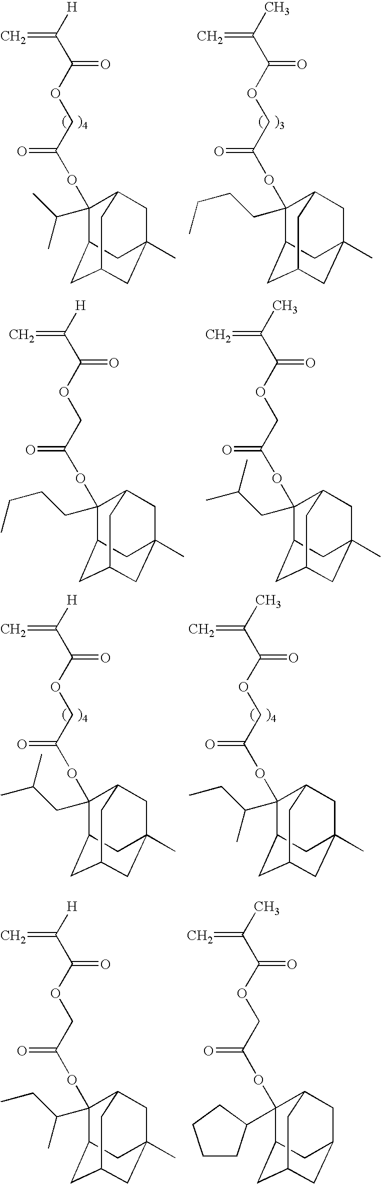

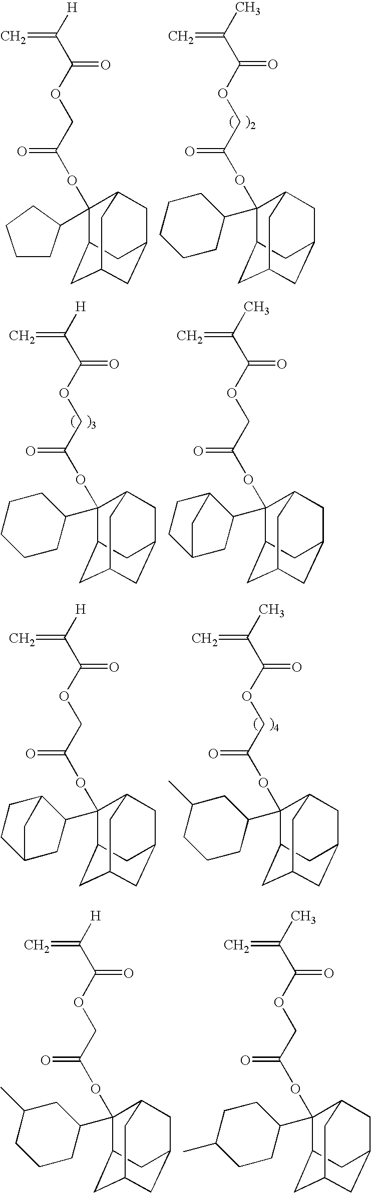

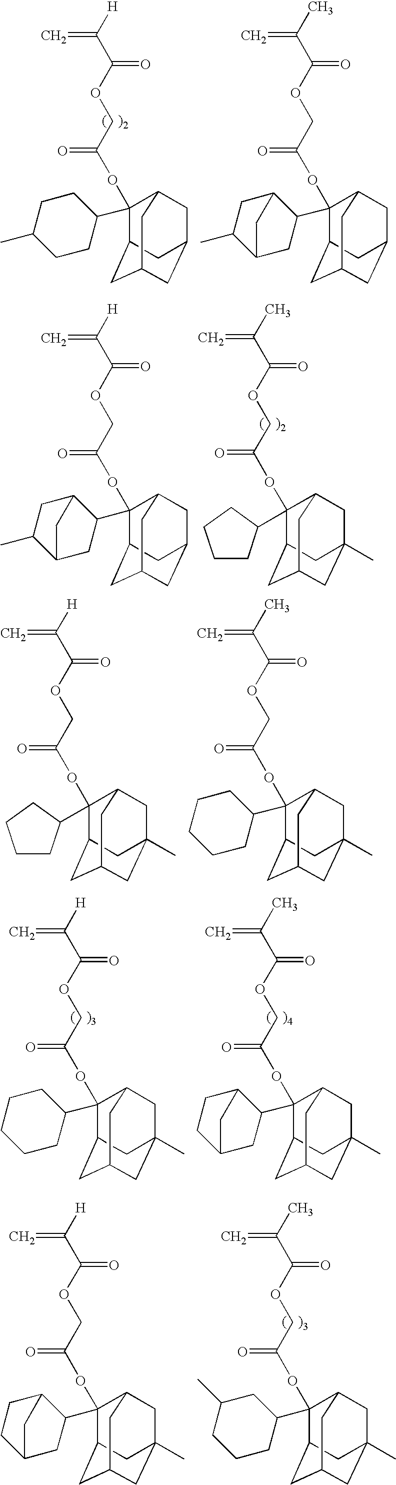

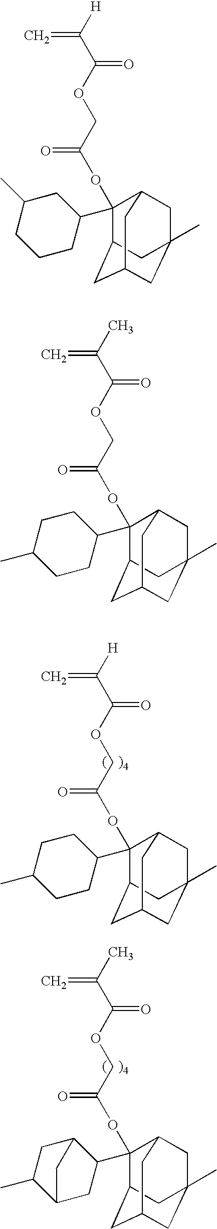

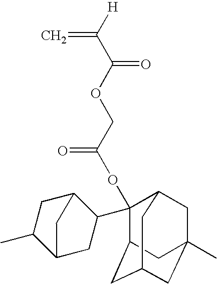

Examples of the monomer giving the structural unit represented by the formula (IIb) include the followings:

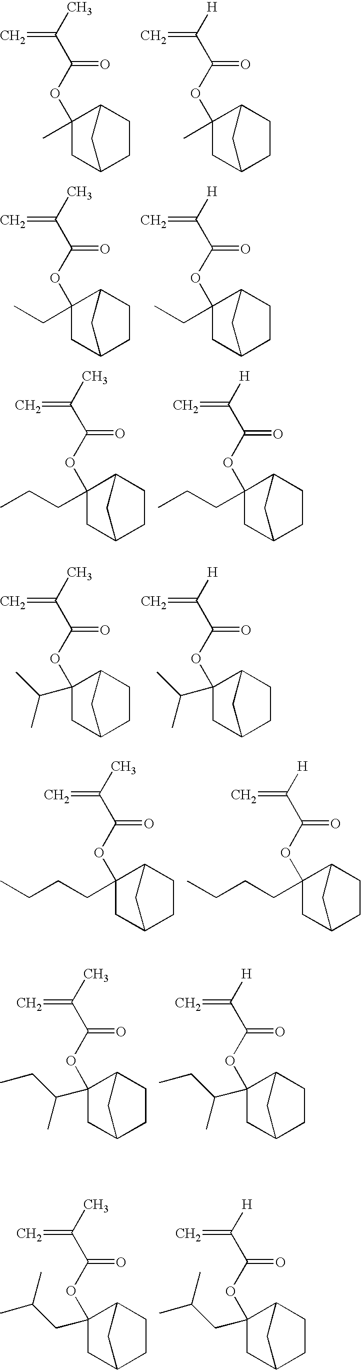

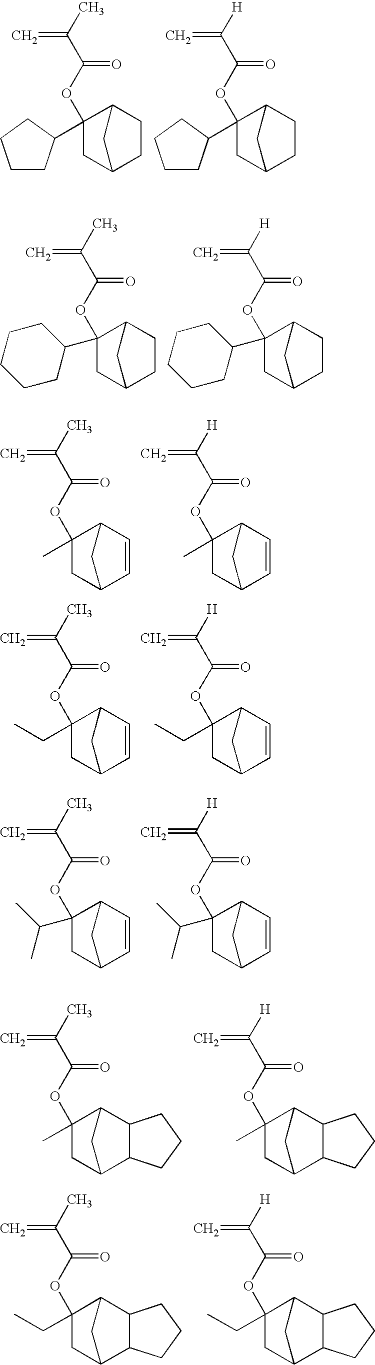

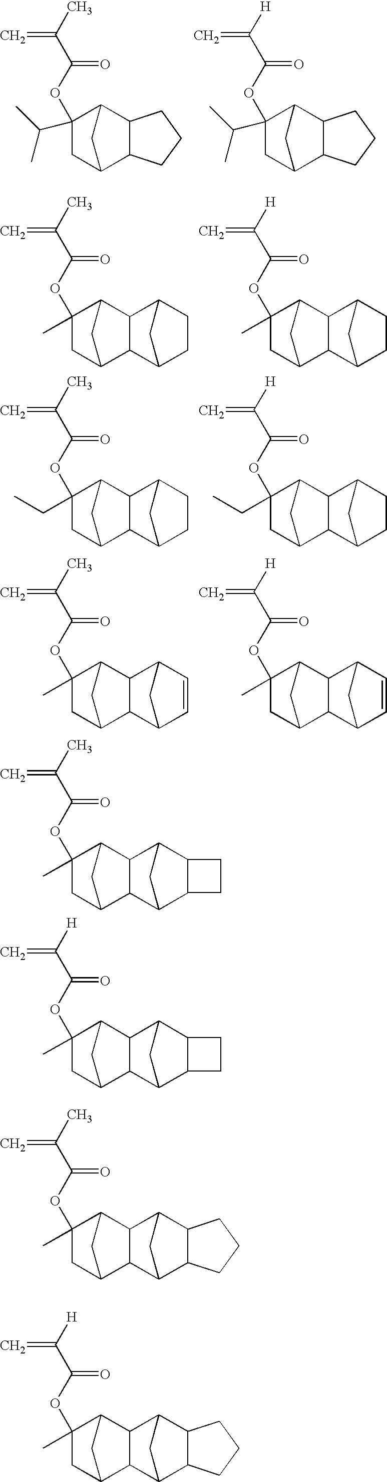

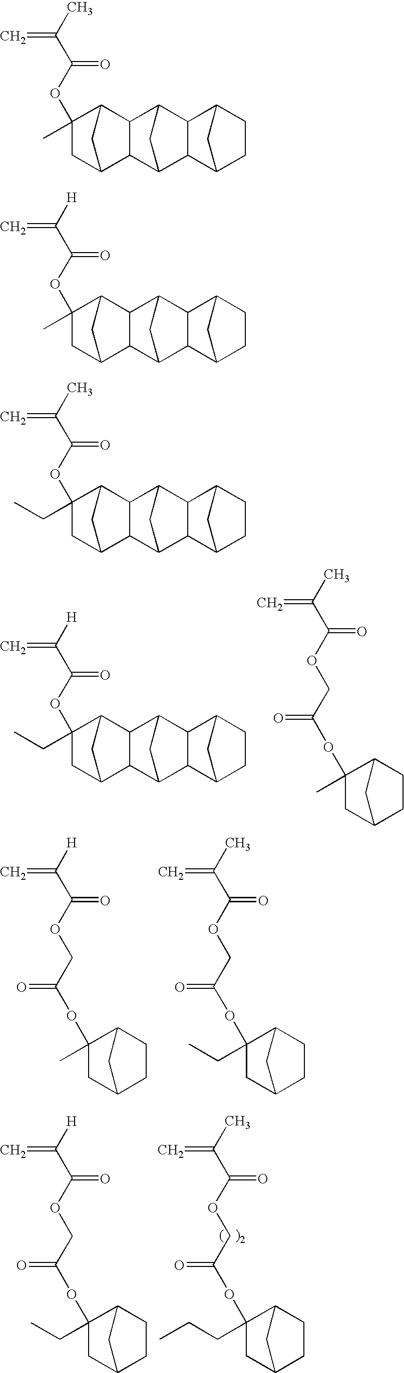

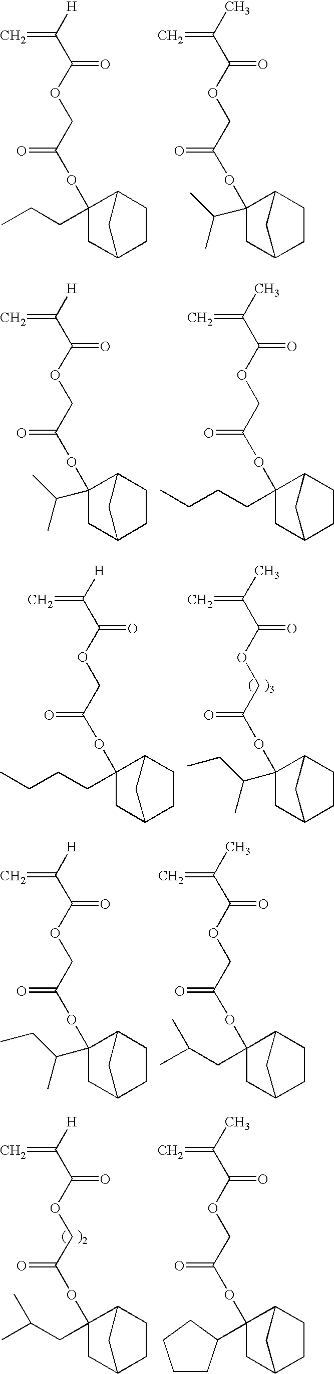

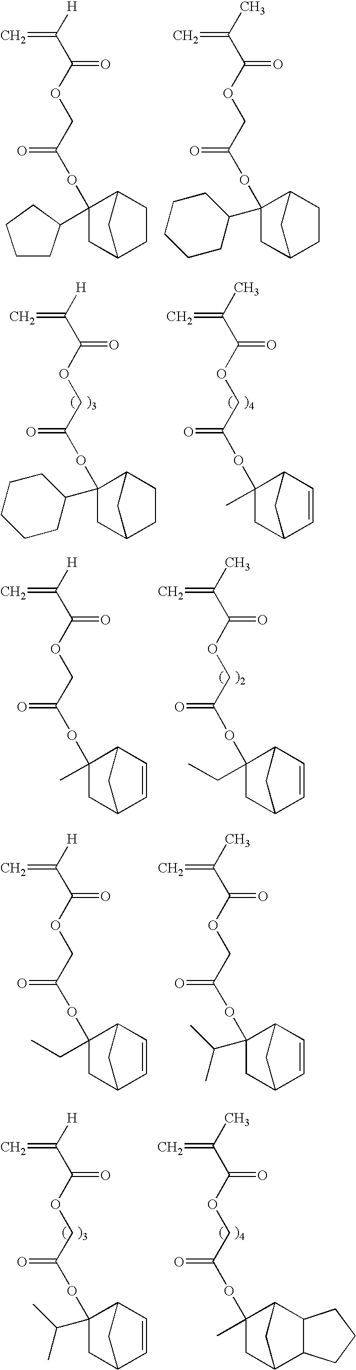

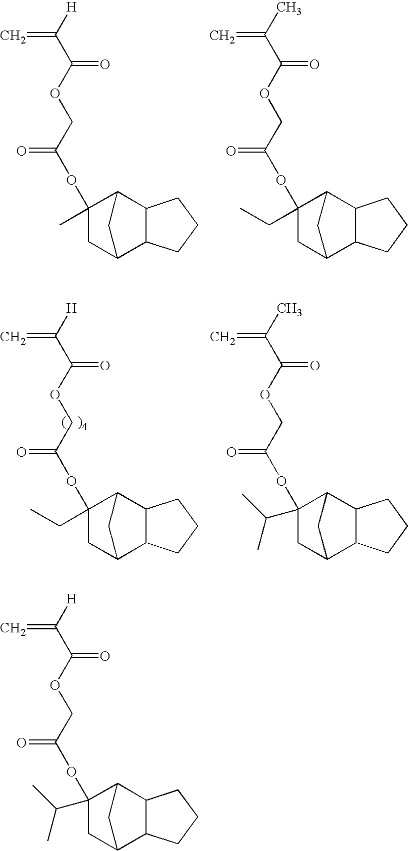

Among them, 2-ethyl-2-adamantyl acrylate, 2-ethyl-2-adamantyl methacrylate, (2-methyl-2-adamantyloxycarbonyl)methyl acrylate and (2-methyl-2-adamantyloxycarbonyl)methyl methacrylate are preferable from the viewpoint of resolution and heat resistance.

Examples of the other structural unit having an acid-labile group in its side chain include structural units represented by the formulae (IIc) and (IId):

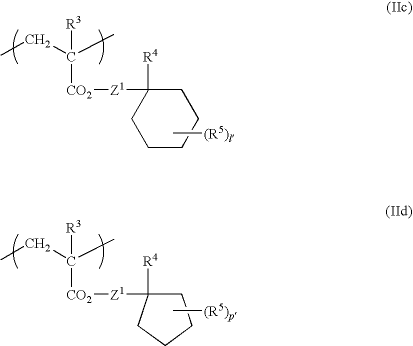

wherein R³, R⁴, R⁵, and Z¹ are the same as defined above, l′ represents an integer of 0 to 10 and p′ represents an integer of 0 to 8.

Examples of the monomer giving the structural units represented by the formulae (IIc) and (IId) include the followings:

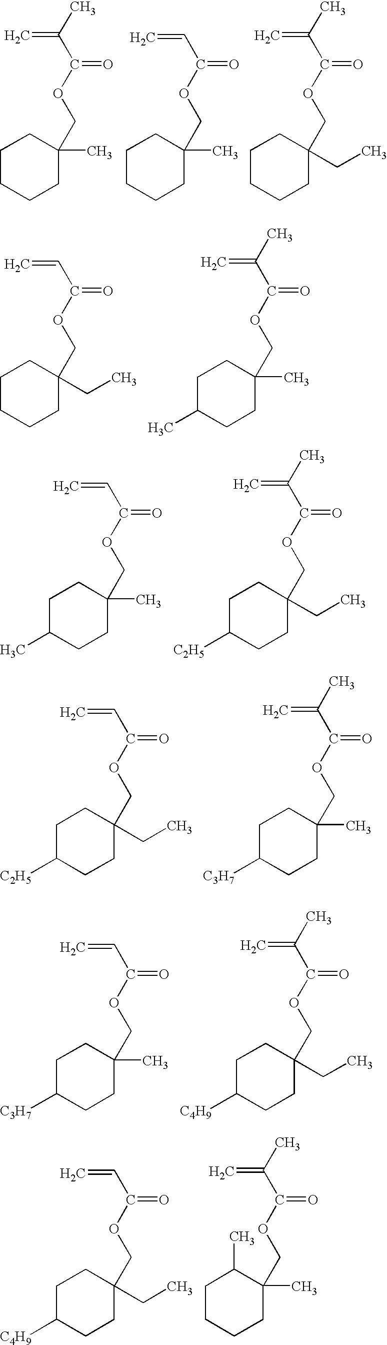

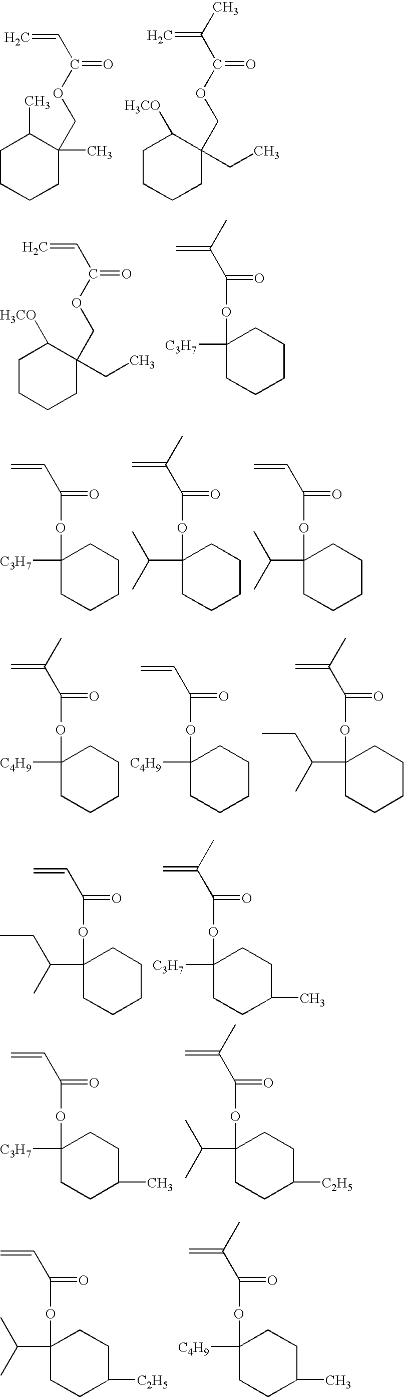

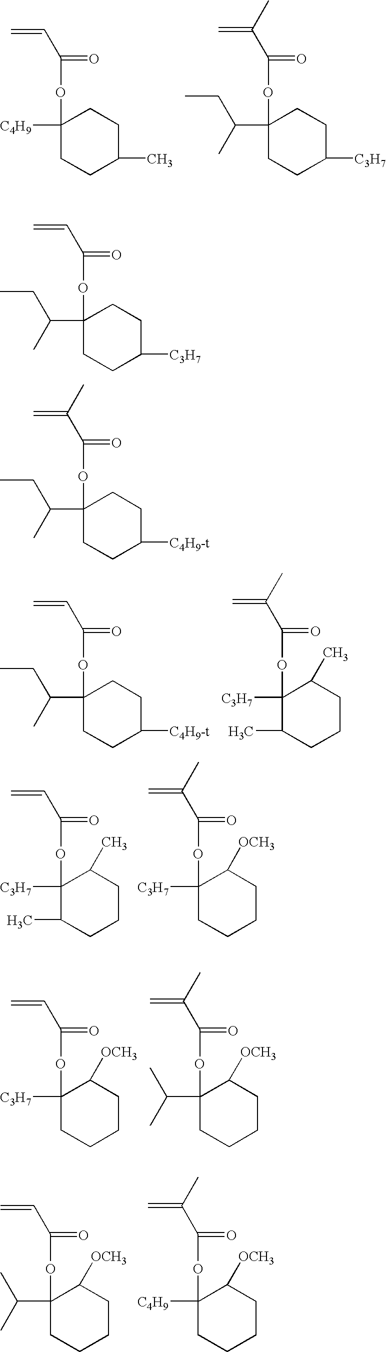

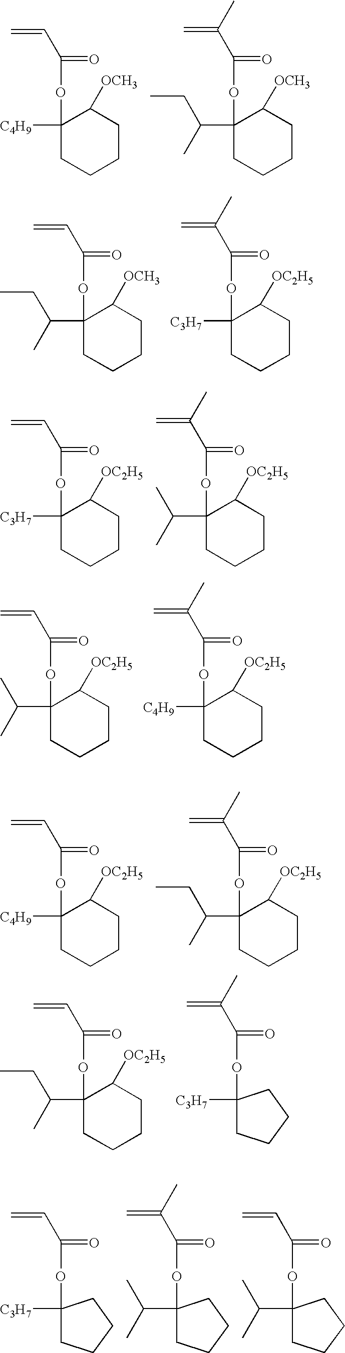

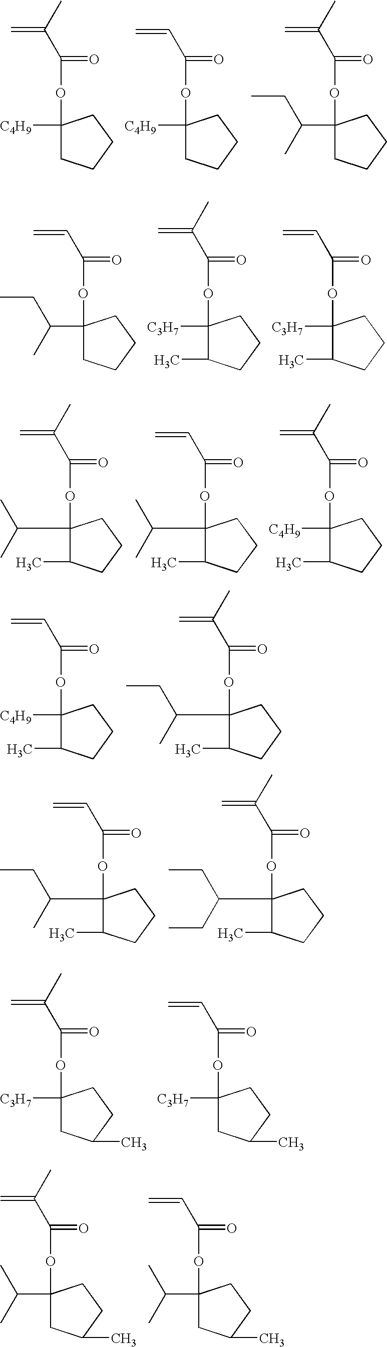

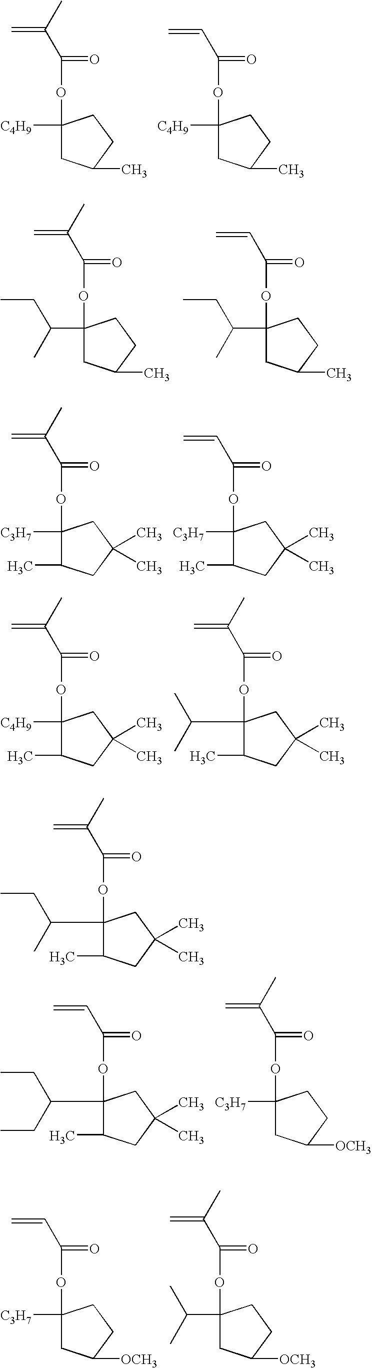

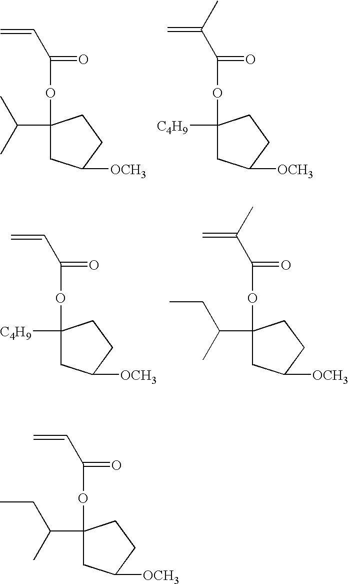

The monomers giving the structural unit represented by the formula (IIa), (IIb), (IIc) and (IId) can be produced, for example, by reacting acrylic halide or methacrylic halide with the corresponding alcohol compound or its alkali salt.

While the resin has no structural unit (II), the content of the structural unit (II) in the resin is preferably 1 to 50 mol %, more preferably 2 to 30 mol % and especially preferably 2 to 20 mol % based on total molar amounts of all the structural units having an acid-labile group in its side chain.

The acetal structure may be a cyclic acetal structure. The monothioacetal structure maybe a cyclic structure. The dithioacetal structure may be a cyclic structure. A monothioacetal structure is preferable and a cyclic monothioacetal structure is more preferable.

Examples of the structural unit having an acetal structure, a monothioacetal structure or a dithioacetal structure in its side chain include a structural unit represented by the formula (XIII):

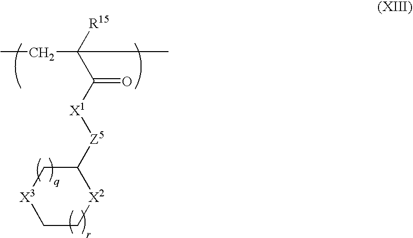

wherein R¹⁵ represents a hydrogen atom, a halogen atom, a C1-C4 alkyl group or a C1-C4 perfluoroalkyl group, Z⁵ represents a single bond or —(CH₂)ₛ—CO—X⁴—, s represents an integer of 1 to 4, X¹, X², X³ and X⁴ each independently represents an oxygen atom or a sulfur atom, q represents an integer of 1 to 3 and r represents an integer of 0 to 3 (hereinafter, simply referred to as the structural unit (XIII)).

Examples of the halogen atom include a fluorine atom. Examples of the C1-C4 alkyl group include a methyl group, an ethyl group, a propyl group, an isopropyl group, a butyl group and tert-butyl group, and a methyl group is preferable. Examples of the C1-C4 perfluoroalkyl group include a trifluoromethyl group, a pentafluoroethyl group, a heptafluoropropyl group and a nonafluorobutyl group, and a trifluoromethyl group is preferable. R¹⁵ is preferably a hydrogen atom, a C1-C4 alkyl group or a C1-C4 perfluoroalkyl group, and is more preferably a hydrogen atom, a methyl group or a trifluoromethyl group.

X¹, X² and X⁴ are preferably oxygen atoms or a sulfur atom, and X³ is preferably a sulfur atom.

In the formula (XIII), q is preferably 1 and r is preferably 0, 1 or 2.

Examples of a monomer used for giving the structural unit (XIII) include the followings:

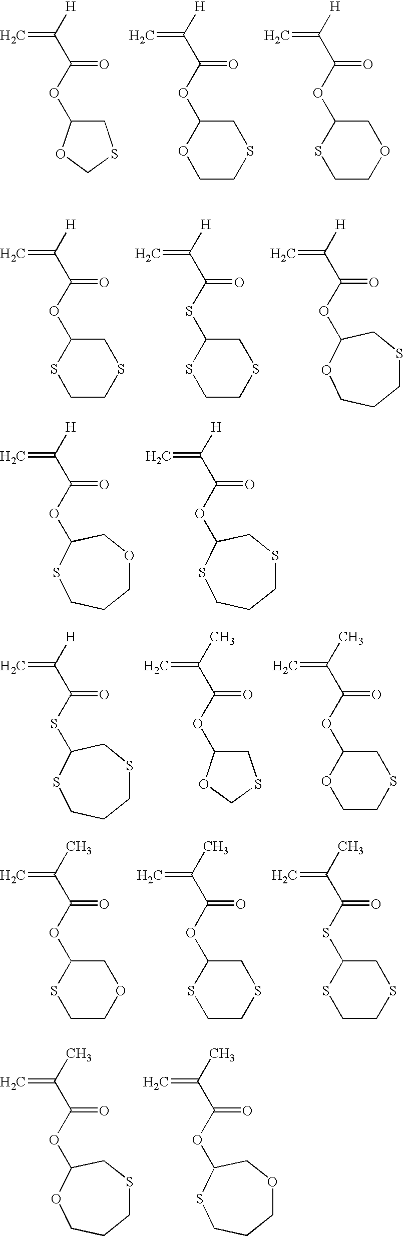

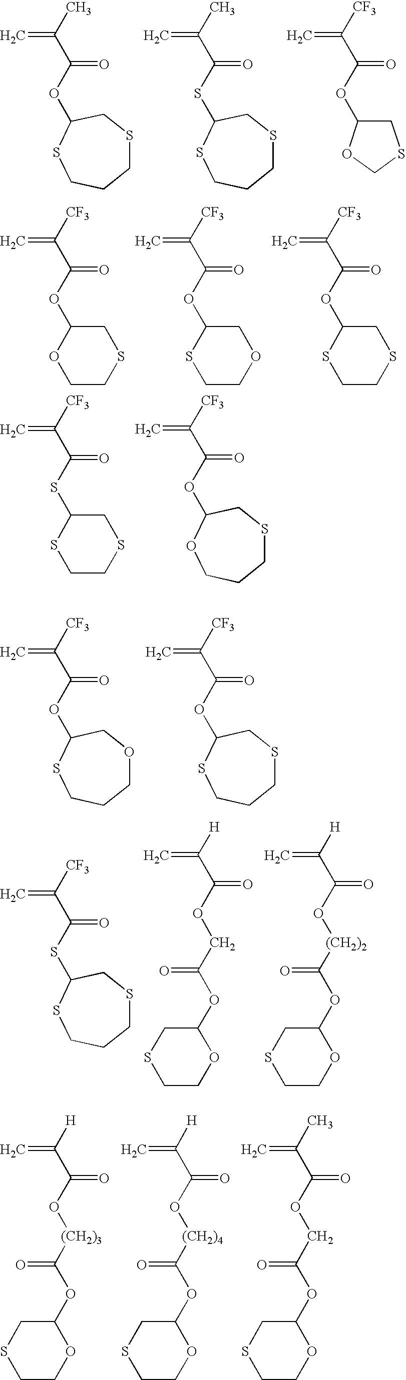

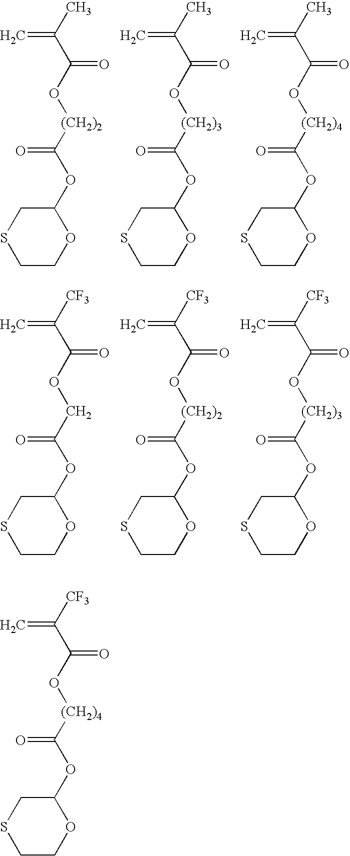

These monomers can be produced by reacting the corresponding alcohol compounds with acryloyl chloride, methacryloyl chloride, acrylic anhydride or methacrylic anhydride.

The resin preferably contains 1 to 50 mol % of the structural unit (XIII), more preferably 2 to 30 mol % of the structural unit (XIII) and especially preferably 2 to 20 mol % of the structural unit (XIII) based on total molar amounts of all the structural units having an acid-labile group in its side chain.

The resin may have a structural unit having a hydroxyl group in a side chain, and preferably has a structural unit having a hydroxyl group in a side chain. In the present specification, —OH of a carboxyl group is not a hydroxyl group.

Examples of the structural unit having a hydroxyl group in a side chain include the following structural unit represented by the formula (III):

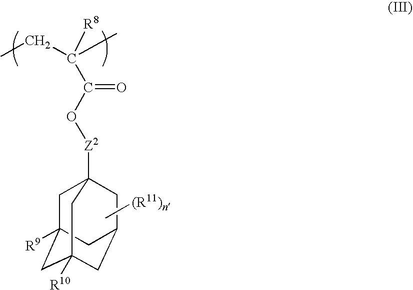

wherein R⁸ represents a hydrogen atom or a methyl group, R⁹ and R¹⁰ each independently represents a hydrogen atom, a methyl group or a hydroxyl group, R¹¹ represents a methyl group, n′ represents an integer of 0 to 12, Z² represents a single bond or a —(CH₂)_{s′}—COO— group, and s′ represents an integer of 1 to 4 (hereinafter, simply referred to as the structural unit (III)).

Z² preferably represents a single bond or —CH₂—COO—, and n′ is preferably 0.

The resin may have two or more kinds of the structural unit (III),

Examples of the monomer used for giving the structural unit (III) include the followings.

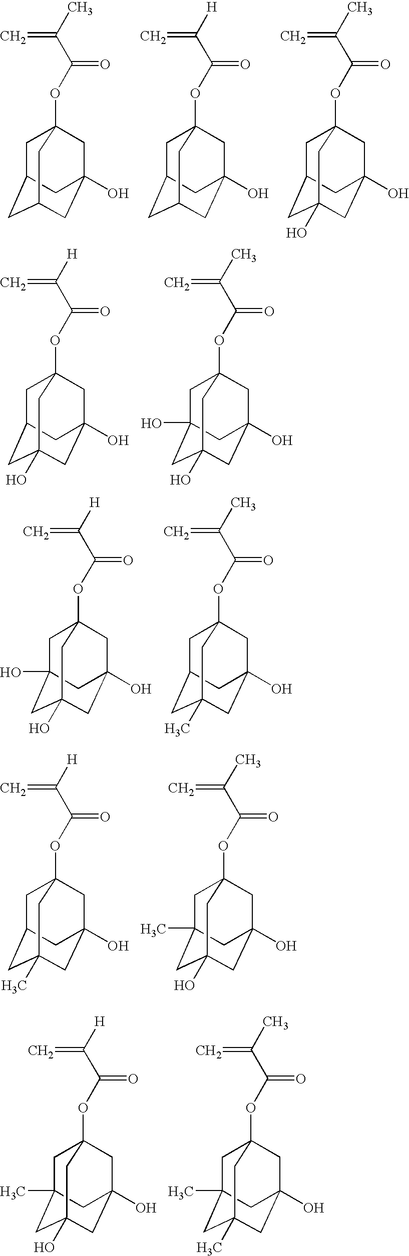

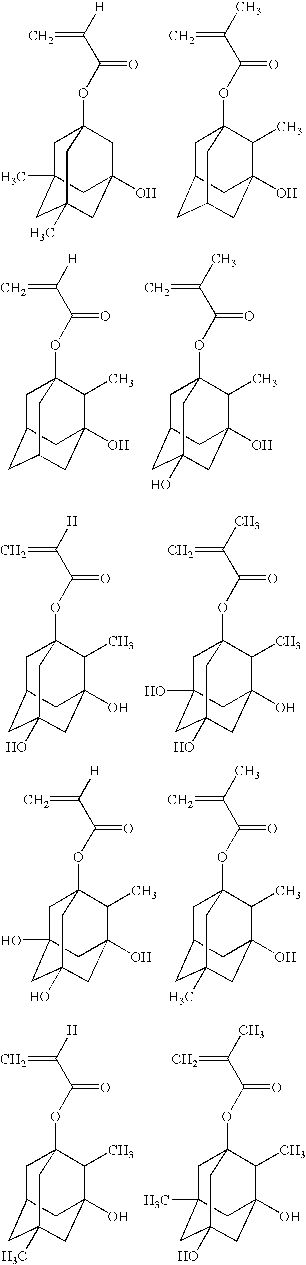

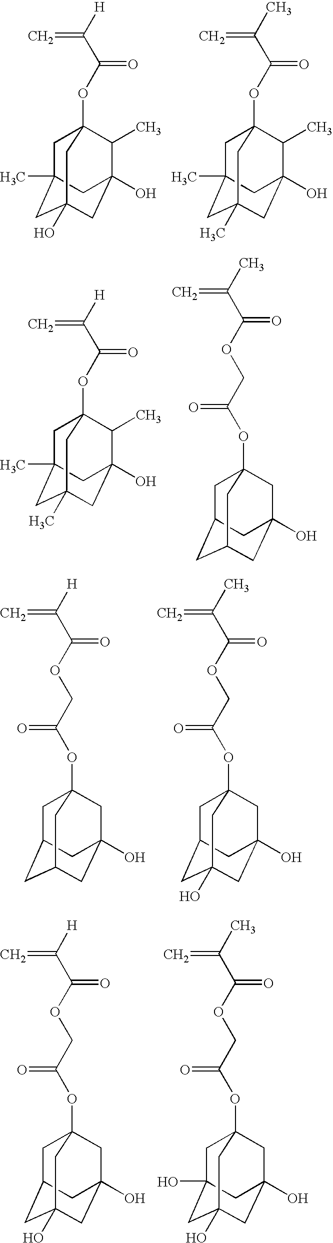

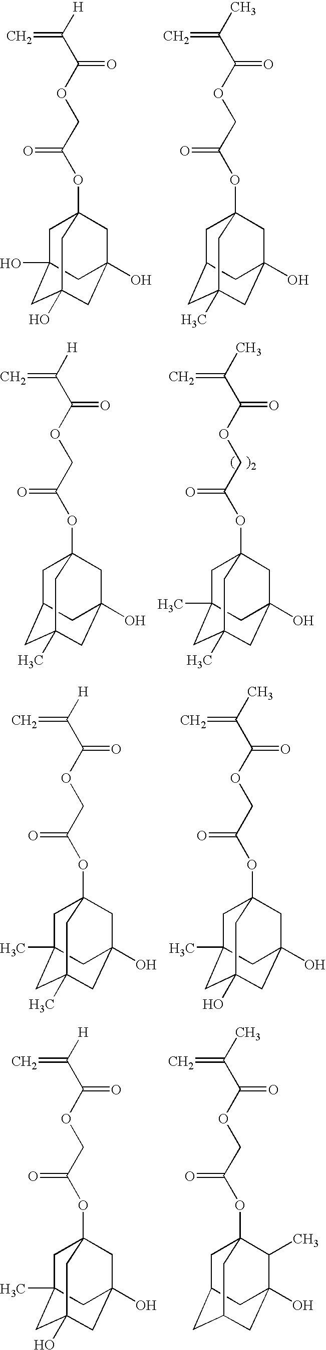

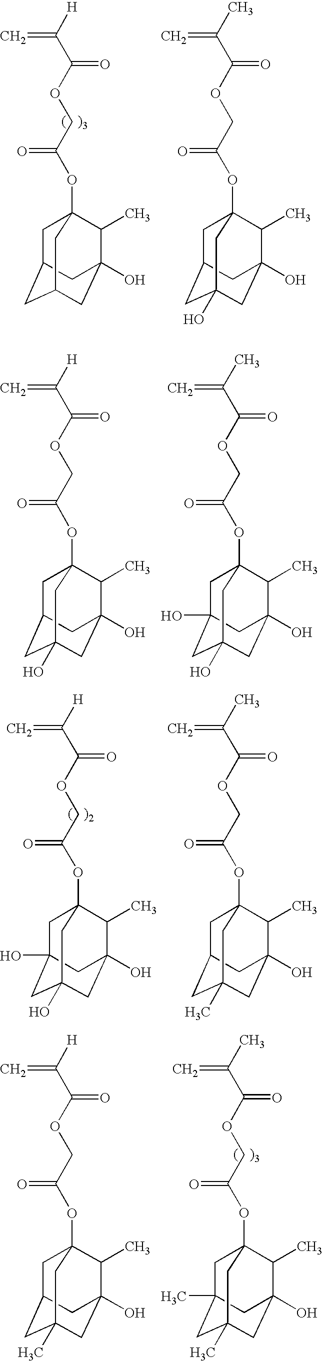

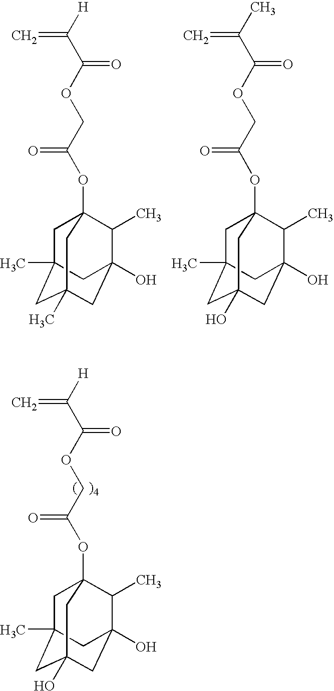

Among these monomers, 3-hydroxy-1-adamantyl acrylate, 3,5-dihydroxy-1-adamantyl acrylate, 3-hydroxy-1-adamantyl methacrylate, 3,5-dihydroxy-1-adamantyl methacrylate, 1-(3-hydroxy-1-adamantyloxycarbonyl)methyl methacrylate and 1-(3,5-dihydroxy-1-adamantyloxycarbony)methyl methacrylate are preferable since excellent resolution is obtained when the resin containing the structural unit derived from such monomer is used in the present resist composition.

3-Hydroxy-1-adamantyl acrylate, 3,5-dihydroxy-1-adamantyl acrylate, 3-hydroxy-1-adamantyl methacrylate and 3,5-dihydroxy-1-adamantylmethacrylate can be produced, for example, by reacting corresponding hydroxyl-substituted adamantane with acrylic acid, methacrylic acid, or its acid halide, and they are also commercially available.

The content of the structural unit (III) is preferably 1 to 40 mol % and more preferably 5 to 35 mol % based on total molar amounts of all the structural units.

The resin may have one or more structural units having a lactone structure. The resin preferably has one or more structural units having a lactone structure.

Examples of the structural unit having a lactone structure include a structural unit having a β-butyrolactone structure, a structural unit having a γ-butyrolactone structure, a structural unit having a cycloalkanelactone structure and a structural unit having a norbornanelactone structure.

Examples of the structural units having a lactone structure include a structural unit represented by the formula (IV):

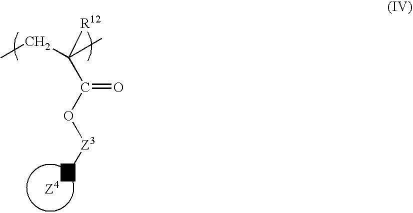

wherein R¹² represents a hydrogen atom or a methyl group, Z³ represents a single bond or —(CH₂)ᵢ—CO—O—, i represents an integer of 1 to 4, and ring Z⁴ represents an unsubstituted or substituted C3-C30 cyclic hydrocarbon group having —CO—O— in the ring structure.

As the structural unit having a lactone structure, the structural units represented by the following formulae (IVa), (IVb) and (IVc):

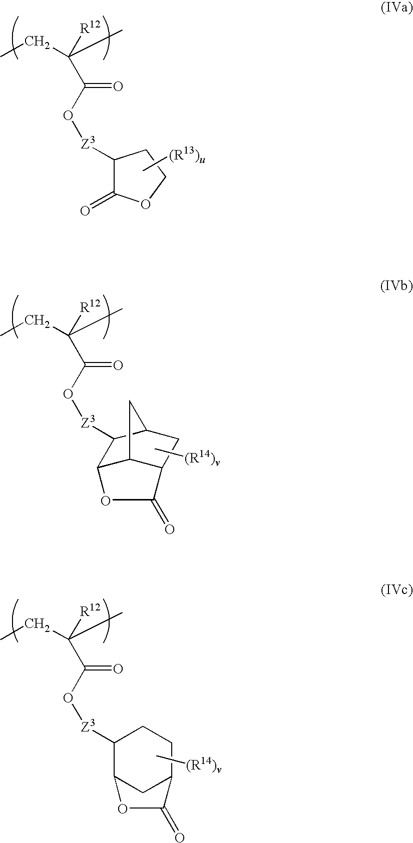

wherein R¹² and Z³ are the same as defined above, and R¹³ represents a methyl group, R¹⁴ is independently in each occurrence a carboxyl group, a cyano group or a C1-C4 hydrocarbon group, u represents an integer of 0 to 5 and v represents an integer of 0 to 9, are preferable.

Examples of the C1-C4 hydrocarbon group include a methyl group, an ethyl group, a propyl group, an isopropyl group, a butyl group, an isobutyl group and a tert-butyl group.

R¹⁴ preferably represents a methyl group, a carboxyl group or a cyano group, and u is preferably 0, 1 or 2, and v is preferably 0, 1 or 2.

Examples of the monomers used for giving the structural units represented by the formulae (IVa), (IVb) and (IVc) include the followings.

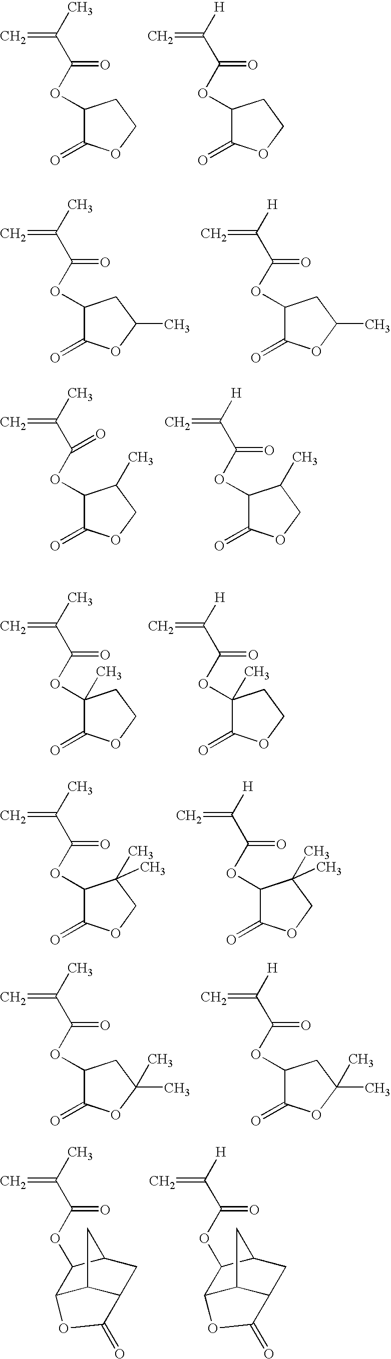

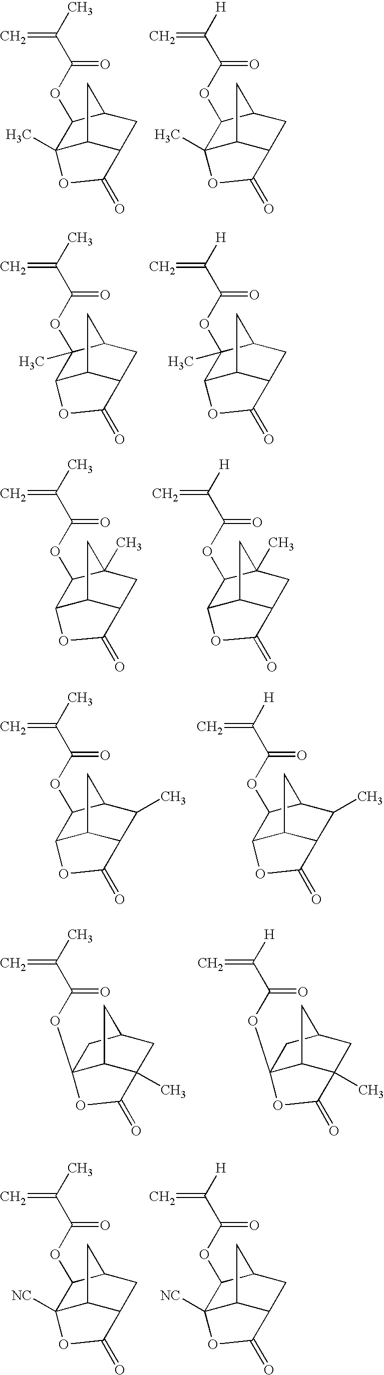

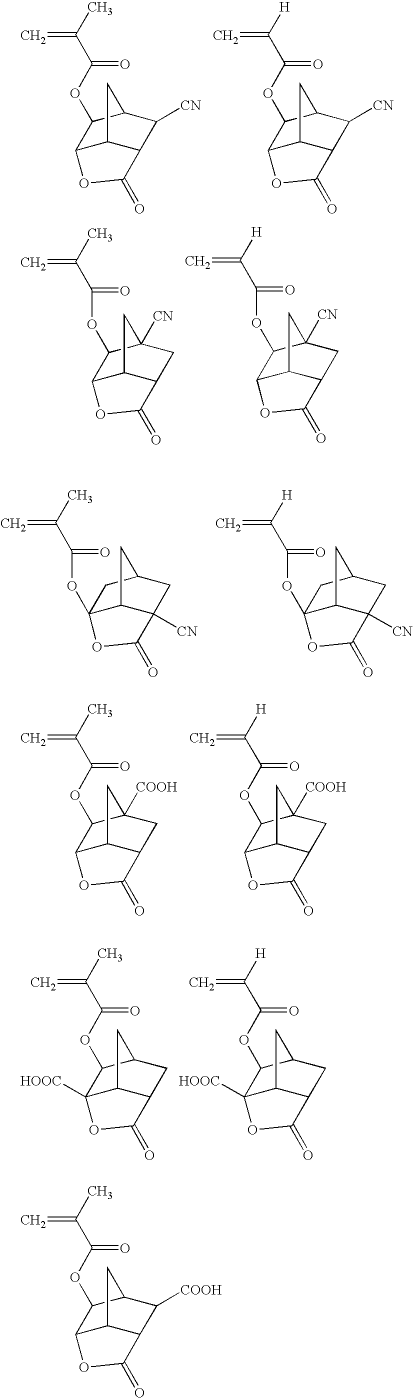

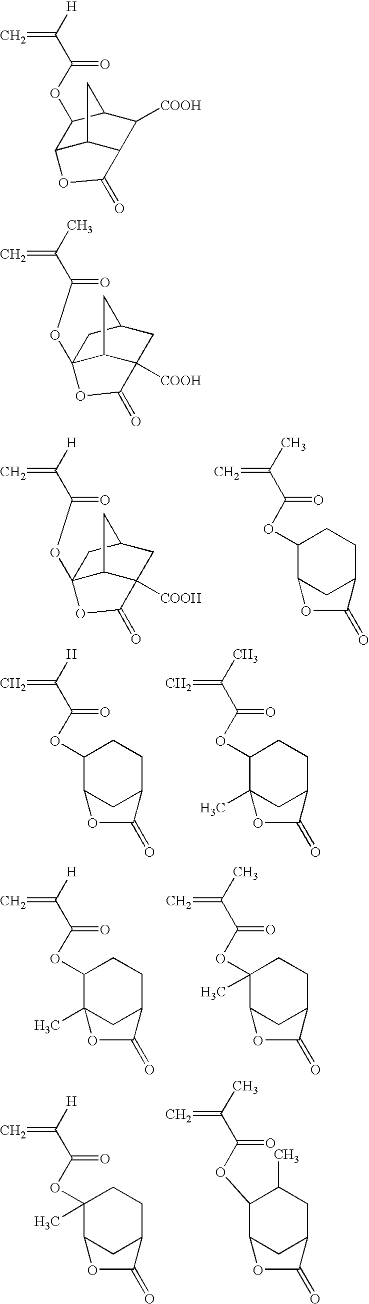

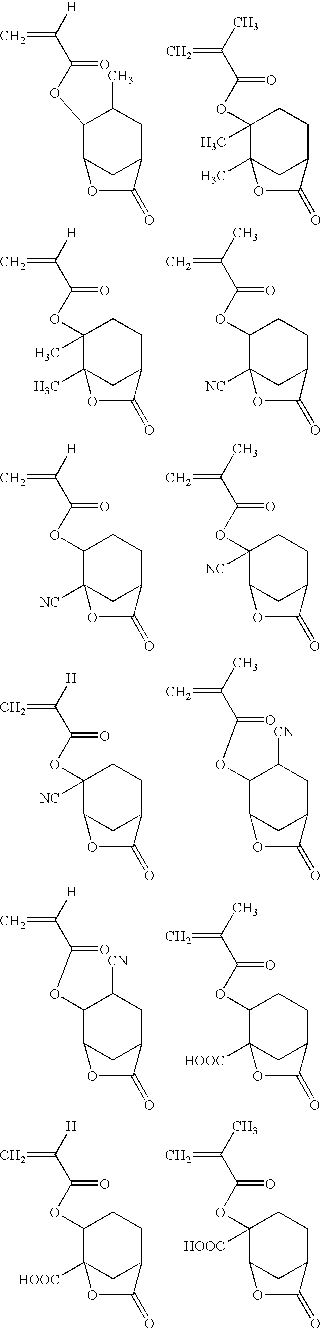

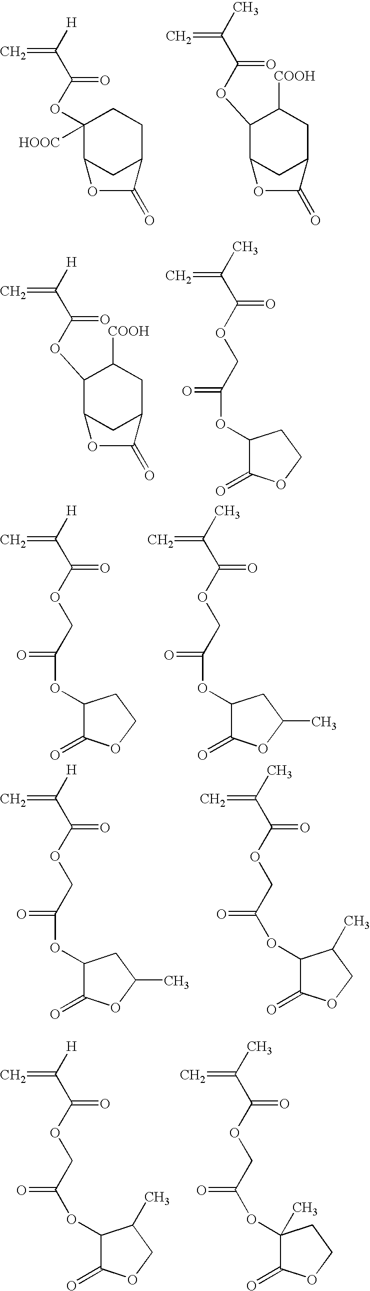

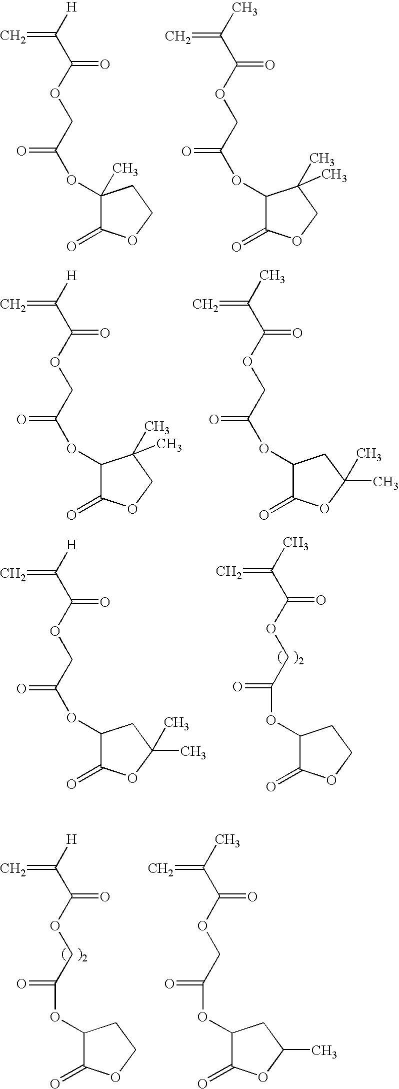

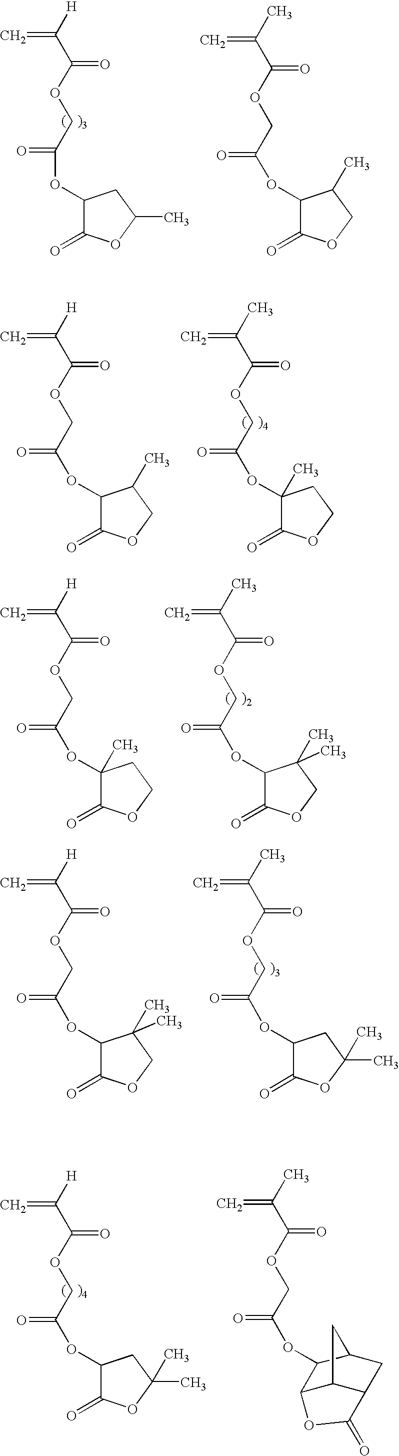

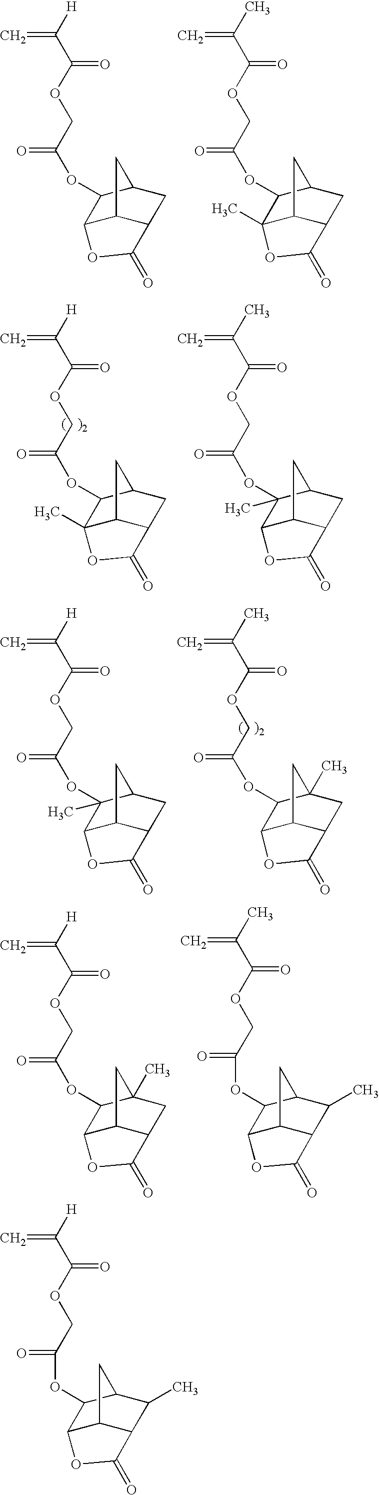

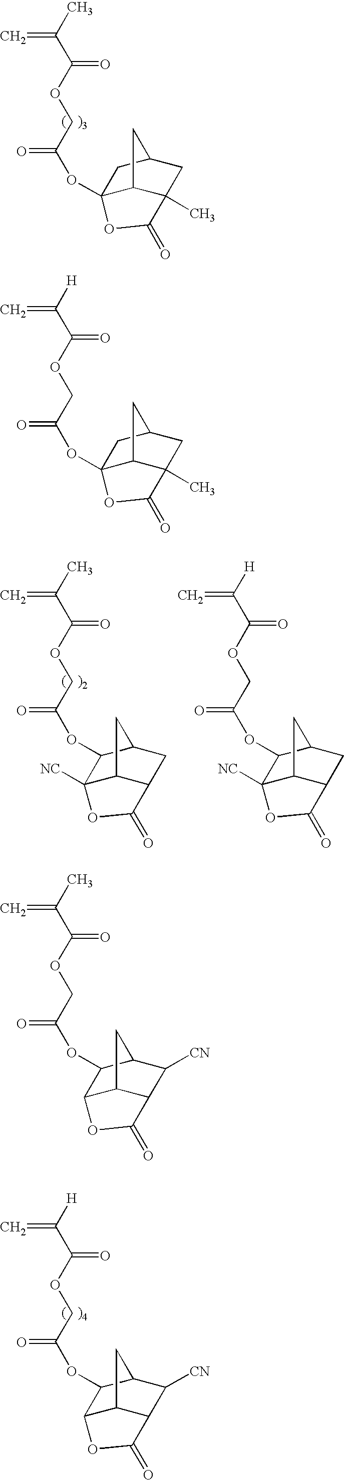

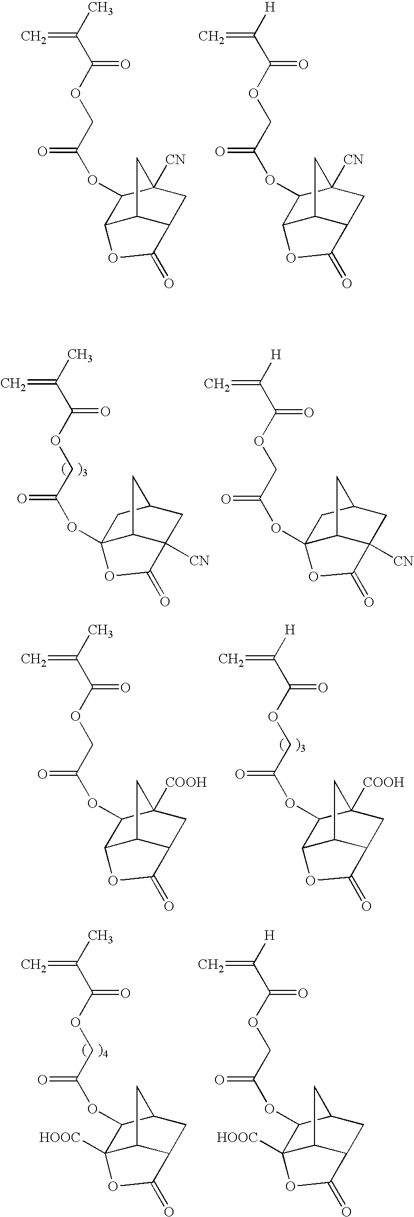

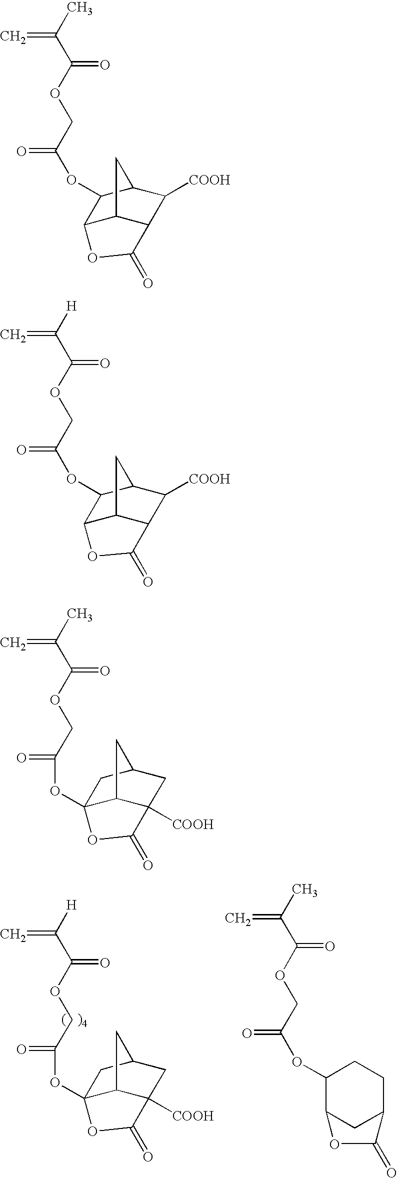

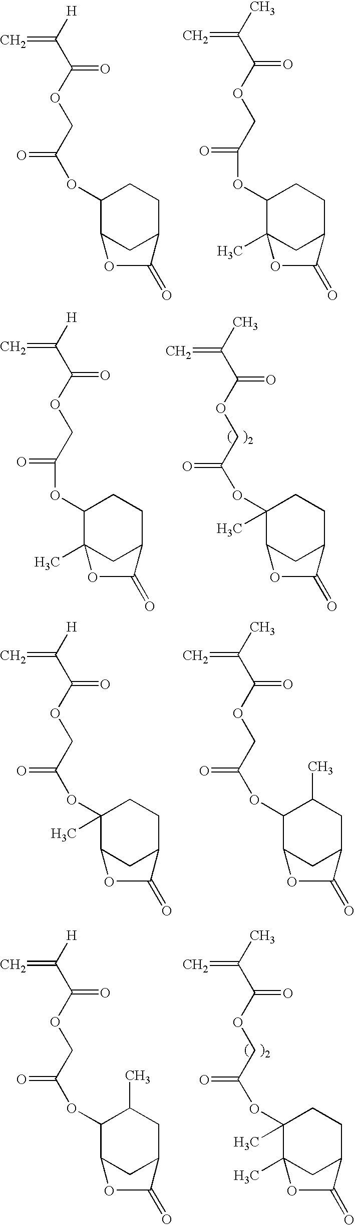

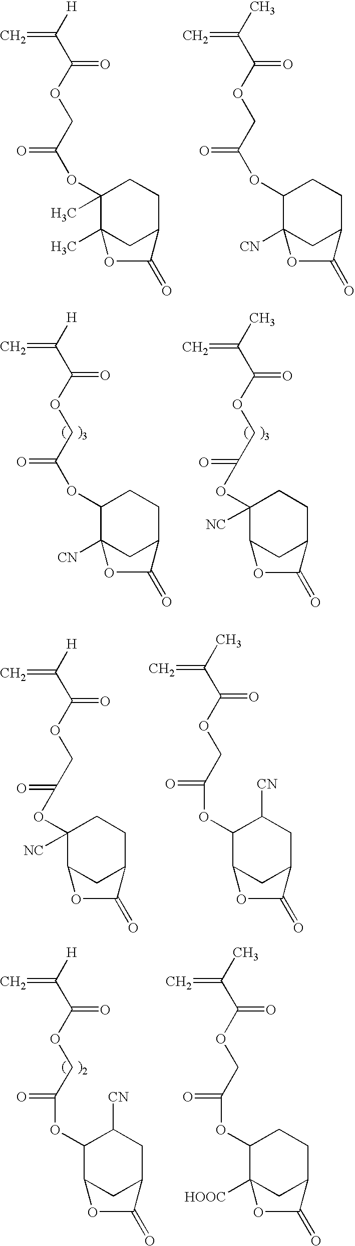

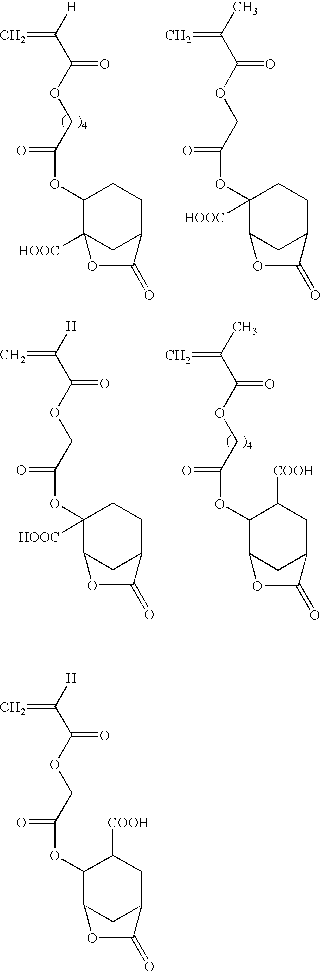

The resin may contain two or more structural units selected from the group consisting of the structural units (IVa), (IVb) and (IVc).

Among the structural units (IVa), (IVb) and (IVc), the structural unit (IVa) is preferable. The structural units derived from hexahydro-2-oxo-3,5-methano-2H-cyclopenta[b]furan-6-yl acrylate, hexahydro-2-oxo-3,5-methano-2H-cyclopenta[b]furan-6-yl methacrylate, tetrahydro-2-oxo-3-furyl acrylate, tetrahydro-2-oxo-3-furyl methacrylate, 2-(5-oxo-4-oxatricyclo[4.2.1.0^{3.7}]nonan-2-yloxy)-2-oxoethyl acrylate and 2-(5-oxo-4-oxatricyclo[4.2.1.0^{3.7}]nonan-2-yloxy)-2-oxoethyl methacrylate are preferable in viewpoint of the adhesiveness of resist composition to a substrate.

The monomers used for giving the structural units represented by the formulae (Iva), (IVb) and (IVc) can usually be produced by a reaction of the corresponding hydroxyl-containing lactone compound with an acrylic halide or methacrylic halide.

The content of the structural unit (IV) is preferably 1 to 50 mol % and more preferably 10 to 50 mol % based on total molar amounts of all the structural units of the resin.

The resin itself is insoluble or poorly soluble in an alkali aqueous solution but becomes soluble in an alkali aqueous solution by the action of an acid.

The resin has usually a polystyrene-equivalent weight-average molecular weight of 1,000 to 500,000 and preferably of 2,000 to 50,000.

The resin can be produced by conducting the polymerization reaction of the corresponding monomer or monomers. The resin can be also produced by conducting the oligomerization reaction of the corresponding monomer or monomers followed by polymerizing the oligomer obtained.

The polymerization reaction is usually carried out in the presence of a radical initiator.

The radical initiator is not limited and examples thereof include an azo compound such as 2,2′-azobisisobutyronitrile, 2,2′-azobis(2-methylbutyronitrile), 1,1′-azobis(cyclohexane-1-carbonitrile), 2,2′-azobis(2,4-dimethylvaleronitrile), 2,2′-azobis(2,4-dimethyl-4-methoxyvaleronitrile), dimethyl-2,2′-azobis(2-methylpropionate) and 2,2′-azobis(2-hydroxymethylpropionitrile); an organic hydroperoxide such as lauroyl peroxide, tert-butyl hydroperoxide, benzoyl peroxide, tert-butyl peroxybenzoate, cumene hydroperoxide, diisopropyl peroxydicarbonate, di-n-propyl peroxydicarbonate, tert-butyl peroxyneodecanoate, tert-butyl peroxypivalate and 3,5,5-trimethylhexanoyl peroxide; and an inorganic peroxide such as potassium peroxodisulfate, ammonium peroxodisulfate and hydrogen peroxide. Among them, the azo compound is preferable and 2,2′-azobisisobutyronitrile, 2,2′-azobis(2-methylbutyronitrile), 1,1′-azobis(cyclohexane-1-carbonitrile), 2,2′-azobis(2,4-dimethylvaleronitrile) and dimethyl-2,2′-azobis(2-methylpropionate) are more preferable, and 2,2′-azobisisobutyronitrile and 2,2′-azobis(2,4-dimethylvaleronitrile) are especially preferable.

These radical initiators may be used alone or in a form of a mixture of two or more kinds thereof. When the mixture of two or more kinds thereof is used, the mixed ratio is not limited.

The amount of the radical initiator is preferably 1 to 20% by mole based on all monomer or oligomer molar amounts.

The polymerization temperature is usually 0 to 150° C., and preferably 40 to 100° C.

The polymerization reaction is usually carried out in the presence of a solvent and it is preferred to use a solvent which is sufficient to dissolve the monomer, the radical initiator and the resin obtained. Examples thereof include a hydrocarbon solvent such as toluene; an ether solvent such as 1,4-dioxane and tetrahydrofuran; a ketone solvent such as methyl isobutyl ketone; an alcohol solvent such as isopropyl alcohol; a cyclic ester solvent such as γ-butyrolactone; a glycol ether ester ester solvent such as propylene glycol monomethyl ether acetate; and an acyclic ester solvent such as ethyl lactate. These solvents may be used alone and a mixture thereof may be used.

The amount of the solvent is not limited, and practically, it is preferably 1 to 5 parts by weight relative to 1 part of all monomers or oligomers.

When an alicyclic compound having an olefinic double bond and an aliphatic unsaturated dicarboxylic anhydride are used as monomers, it is preferable to use them in excess amount in view of a tendency that these are not easily polymerized.

After completion of the polymerization reaction, the resin produced can be isolated, for example, by adding a solvent in which the resin is insoluble or poorly soluble to the reaction mixture obtained and filtering the precipitated resin. If necessary, the isolated resin may be purified, for example, by washing with a suitable solvent.

The present chemically amplified resist composition contains an acid generator.

The acid generator is a substance which is decomposed to generate an acid by applying a radiation such as a light, an electron beam or the like on the substance itself or on a resist composition containing the substance. The acid generated from the acid generator acts on the resin resulting in cleavage of the acid-labile group existing in the resin.

Examples of the acid generator include an onium salt compound, an organo-halogen compound, a sulfone compound, a sulfonate compound, and the like. The onium salt compound is preferable. The acid generators described in JP 2003-5374 A such as an acid generator represented by the following formula:

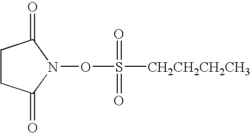

can be used.

A compound represented by the formula:

A⁺B³¹

wherein A⁺ represents an organic counter cation and B⁻ represents a counter anion, are also used as an acid generator. Examples of the counter anion include BF₄⁻, AsF₆⁻, PF₆⁻, SbF₆⁻, SiF₆²⁻, ClO₄⁻, a perfluoroalkanesulfonic acid anion such as CF₃SO₃⁻, pentafluorobenzenesulfonic acid anion, a condensed polynuclear aromatic sulfonic acid anion such as naphthalene-1-sulfonic acid anion, anthraquinonesulfonic acid anion, and a dye containing a sulfonic acid group. Additionally, anions described in JP 2003-5374 A1 such as an anion represented by the following formula:

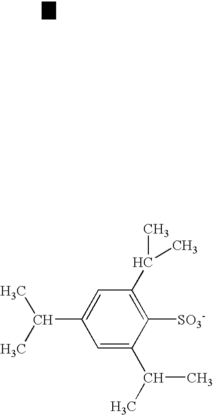

are also listed as the counter anion.

Examples of the preferable acid generator include a salt represented by the formula (V):

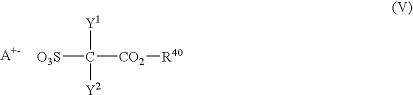

(hereinafter, simply referred to as Salt (V)).

In the formula (V), Y¹ and Y² each independently represent a fluorine atom or a C1-C6 perfluoroalkyl group, R⁹⁰ representsa C1-C36 hydrocarbon group which may have at least one selected from the group consisting of a C1-C6 alkoxy group, a C1-C4 perfluoroalkyl group, a C1-C6 hydroxyalkyl group, a hydroxyl group and a cyano group, and one or more —CH₂— in the hydrocarbon group may be replaced by —CO—, —O— or —COO—, and A⁺ represents an organic counter ion.

Examples of the C1-C6 perfluoroalkyl group represented by Y¹ and Y² include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Y¹ and Y² each independently is preferably a fluorine atom or a trifluoromethyl group, and is more preferably fluorine atoms.

The C1-C36 hydrocarbon group represented by R⁴⁰ may have an alicyclic structure or structures and may have an aromatic group or groups. The C1-C36 hydrocarbon group may have a carbon-carbon double bond or bonds. Examples of the C1-C36 hydrocarbon group include a C1-C6 alkyl group such as a methyl group, an ethyl group, a propyl group, an isopropyl group, a butyl group, an isobutyl group, a sec-butyl group, a tert-butyl group, a pentyl group and a hexyl group, a C3-C36 saturated cyclic hydrocarbon group, a C6-C36 aromatic hydrocarbon group, and a group combined two groups among the above-mentioned groups.

Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group. Examples of the C1-C4 perfluoroalkyl group include a trifluoromethyl group, a pentafluoroethyl group, a heptafluoropropyl group and a nonafluorobutyl group.

Specific examples of the anion part of Salt (V) include the followings.

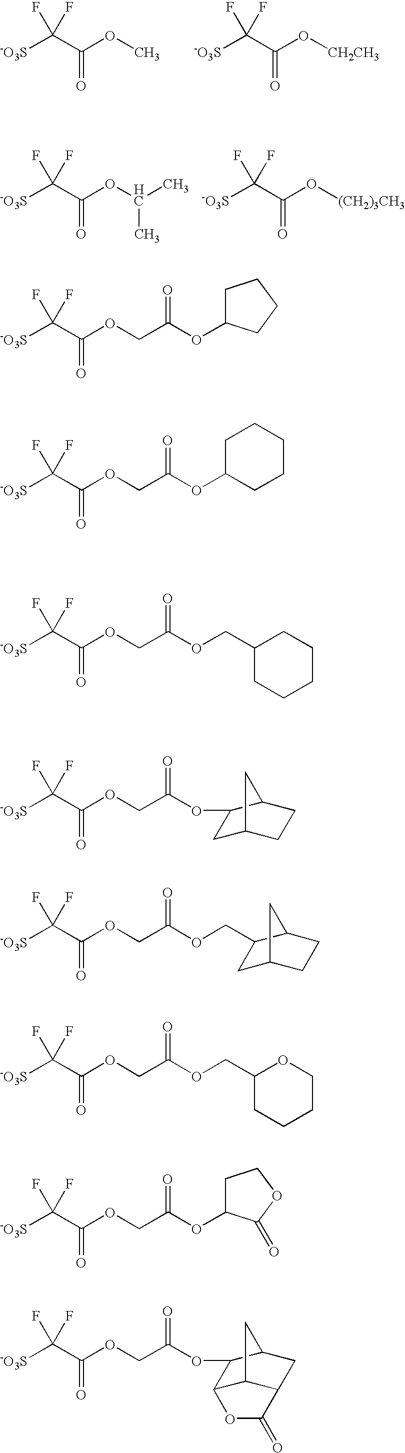

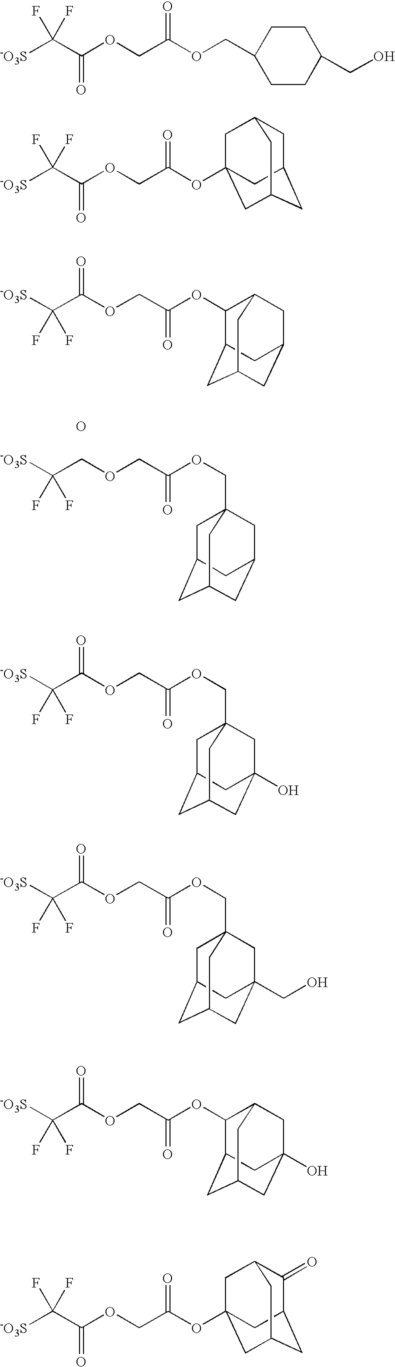

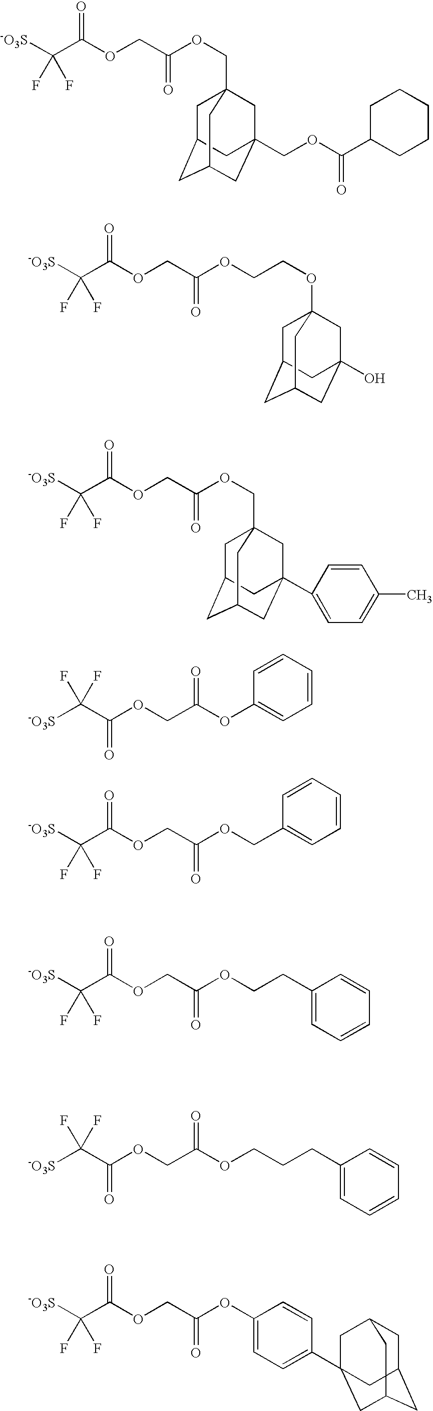

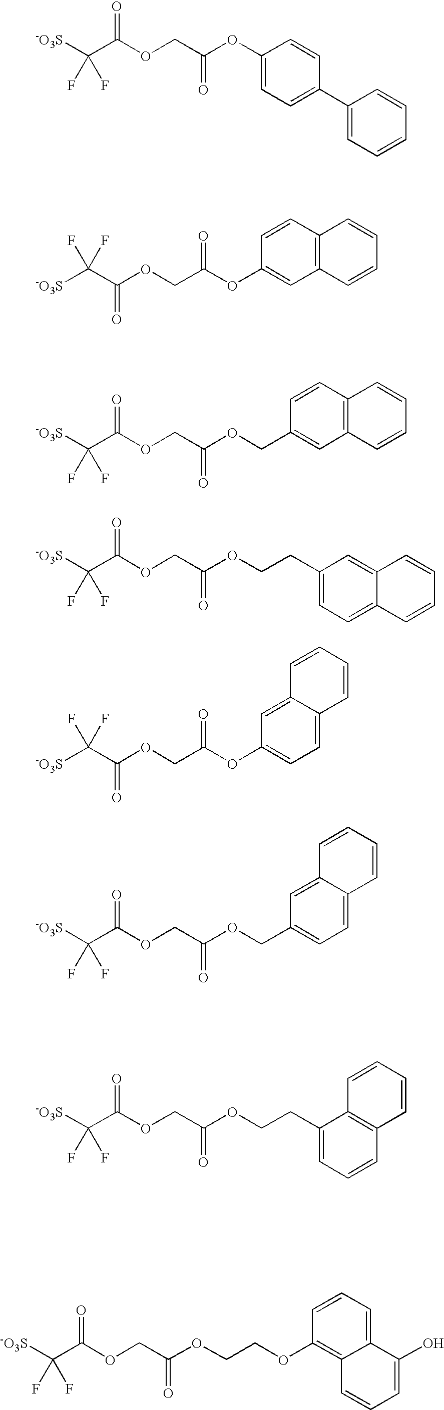

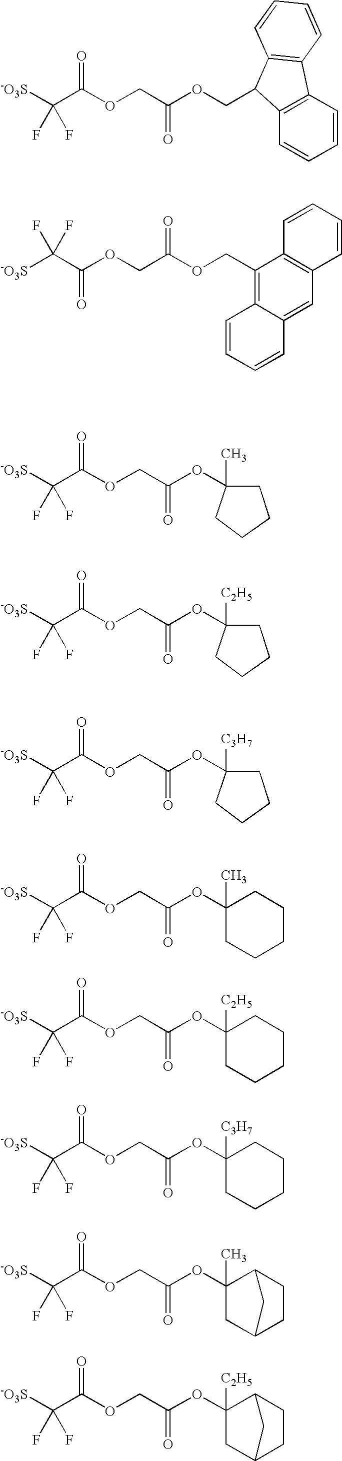

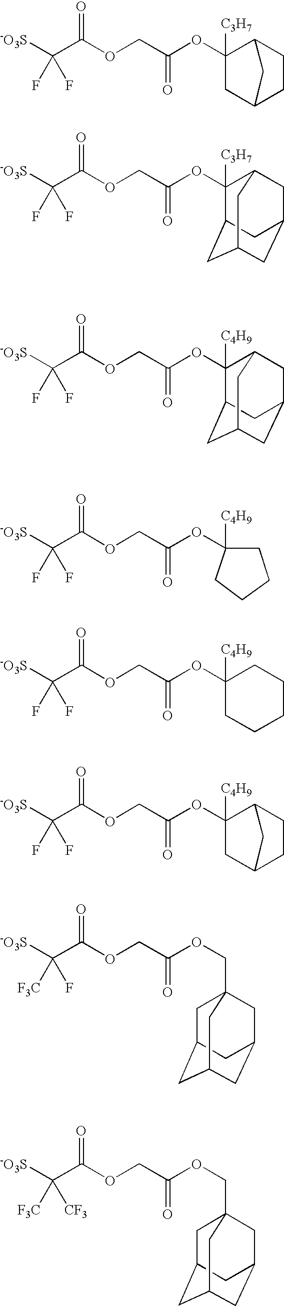

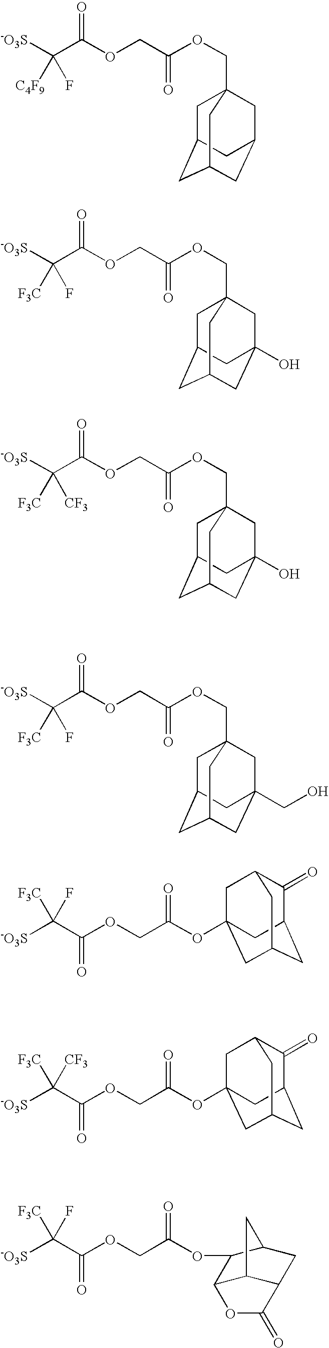

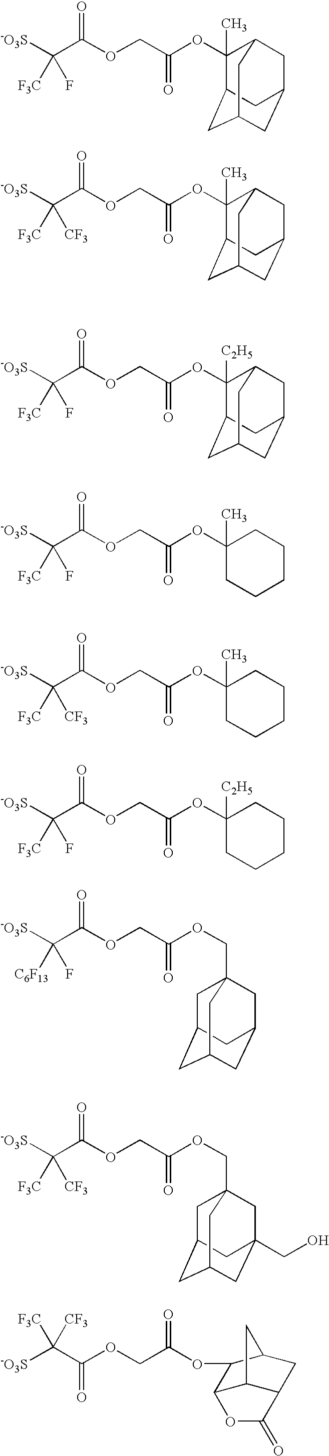

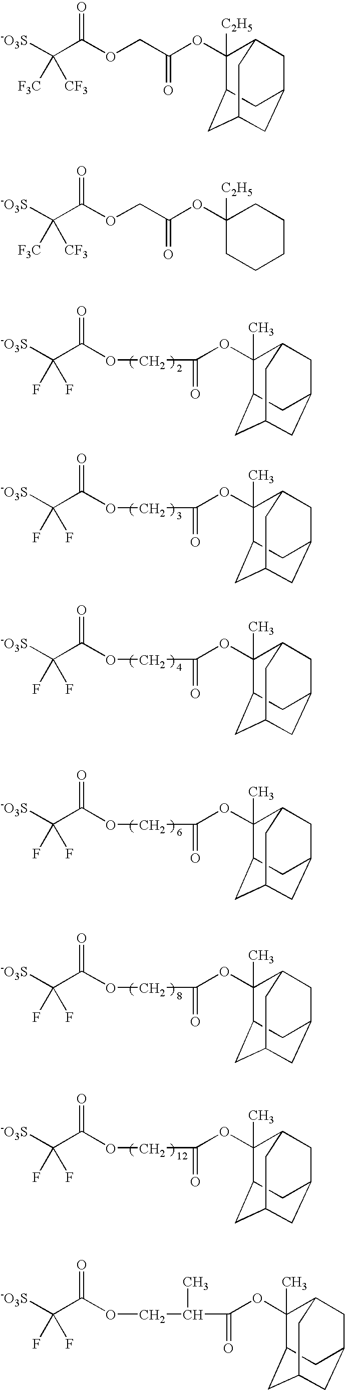

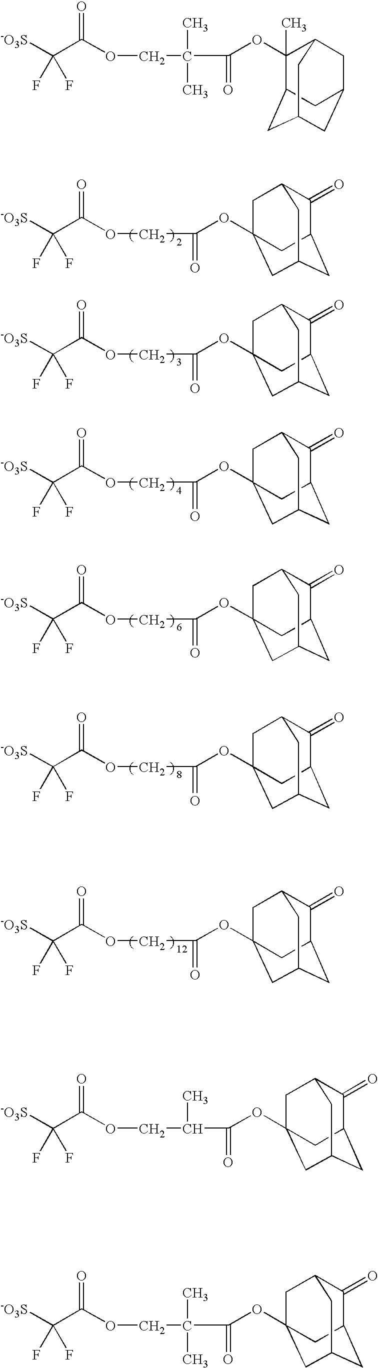

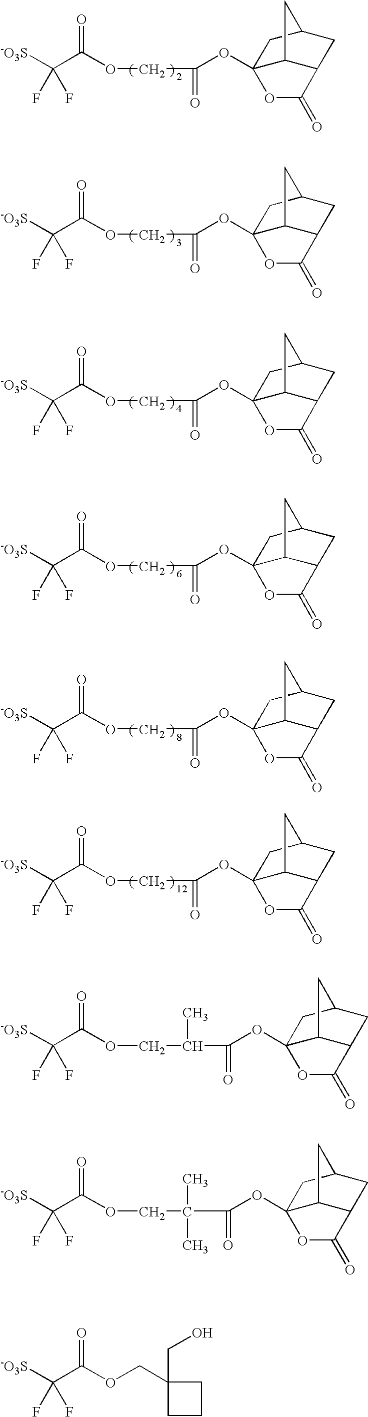

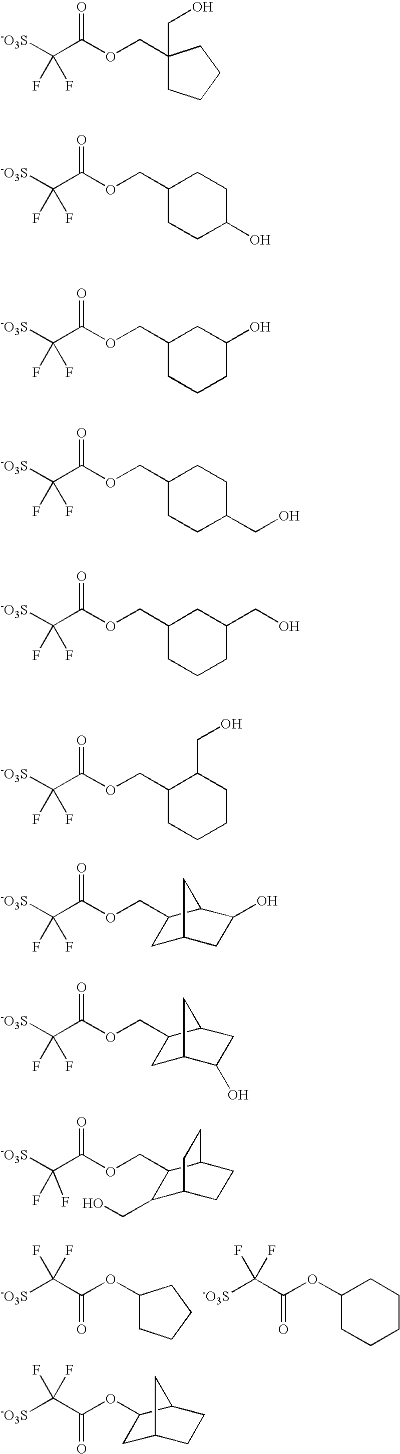

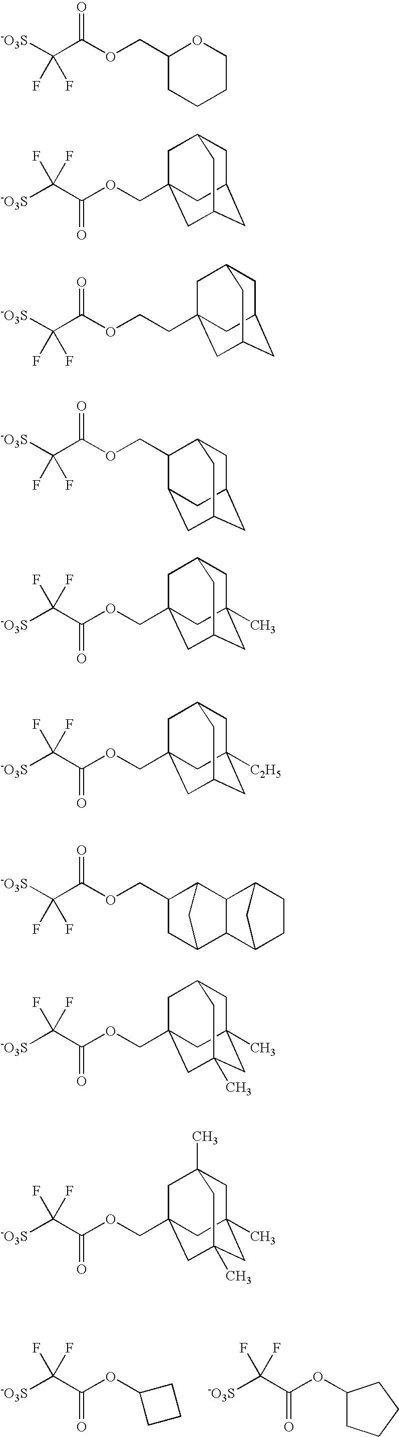

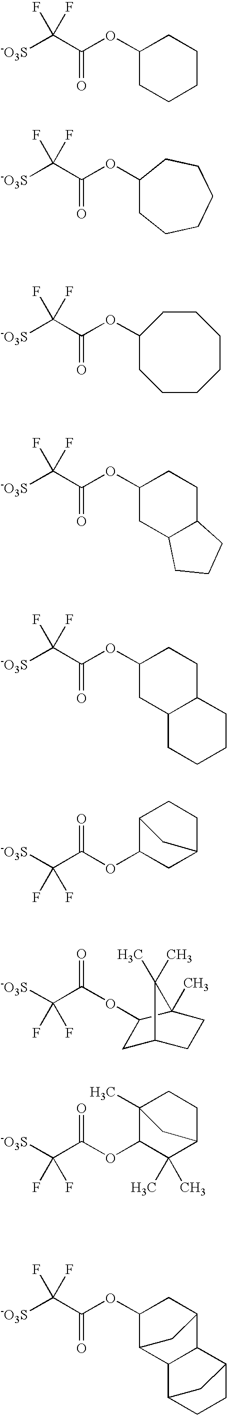

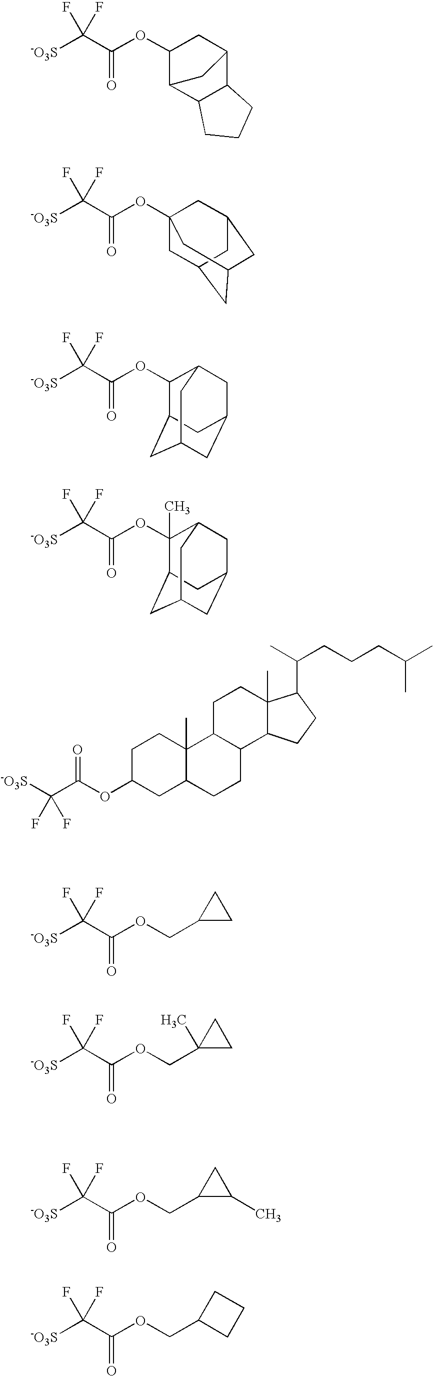

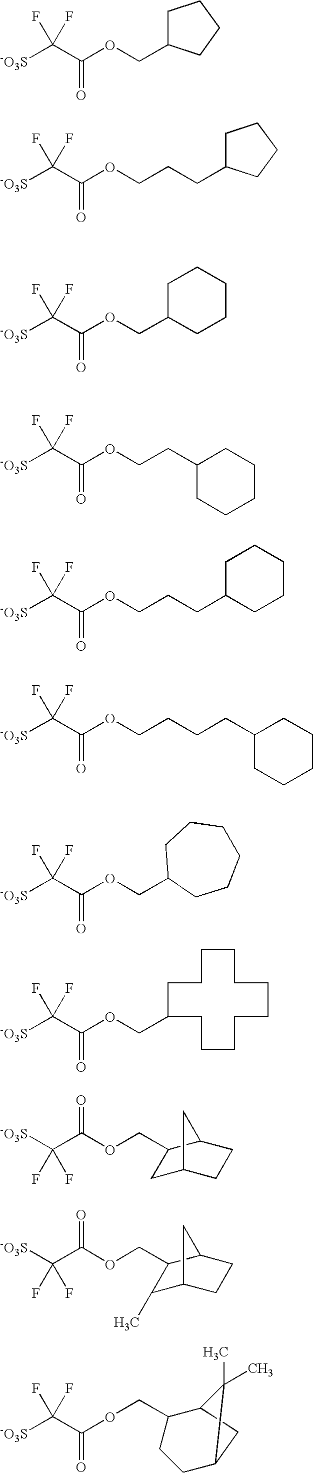

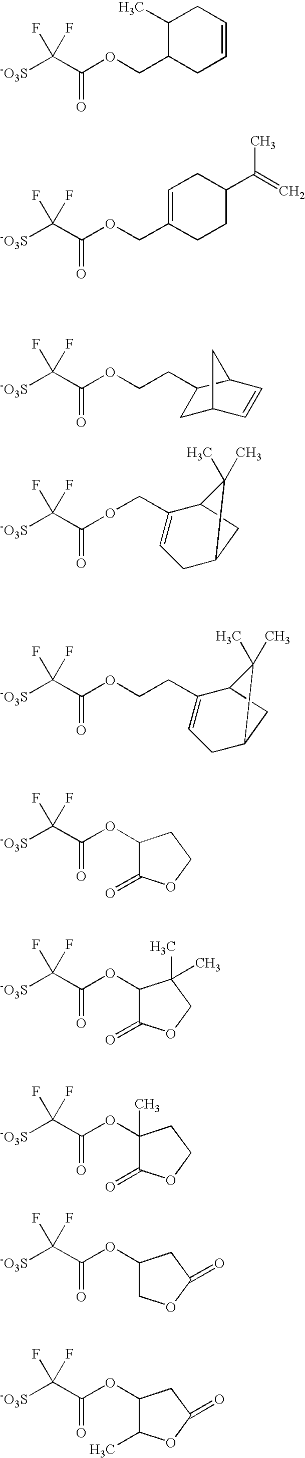

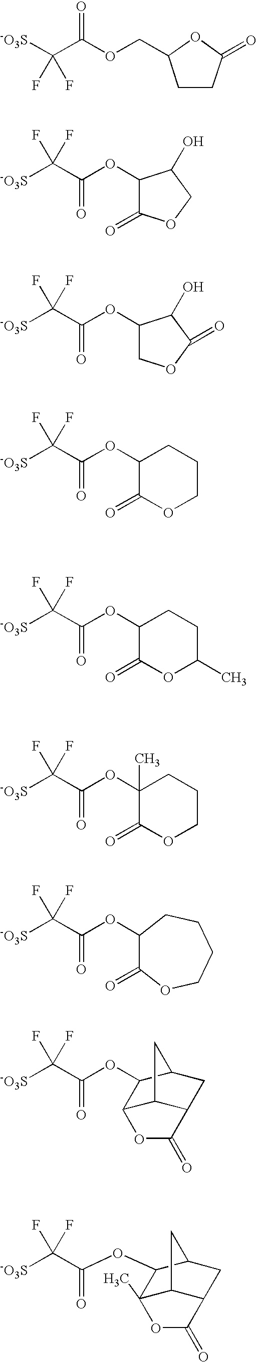

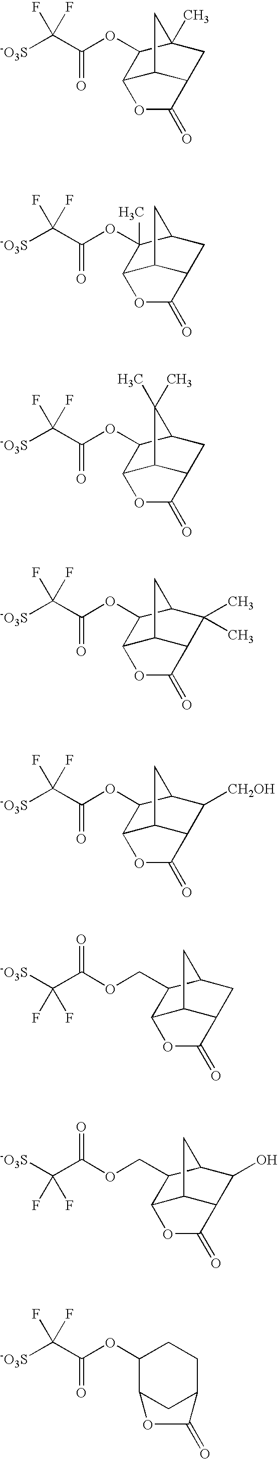

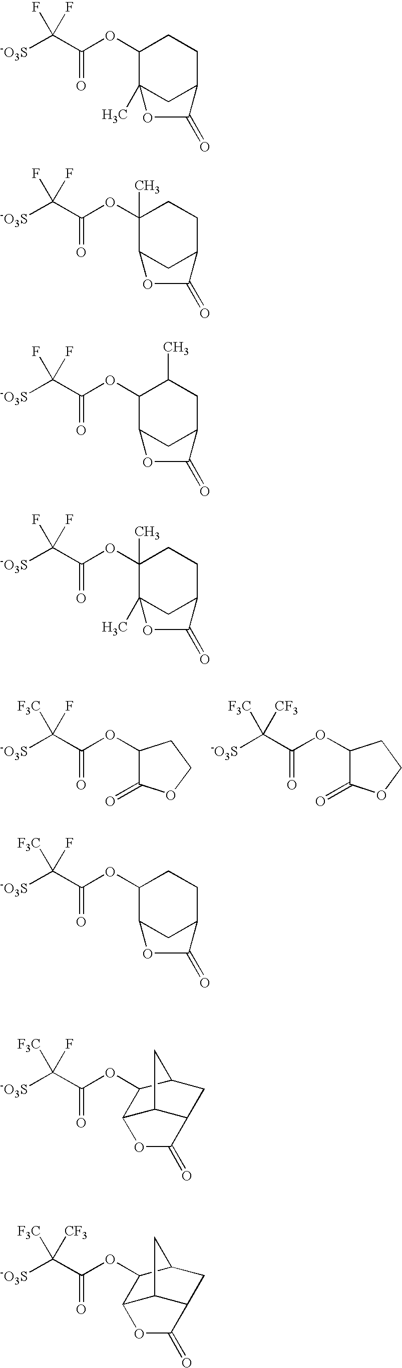

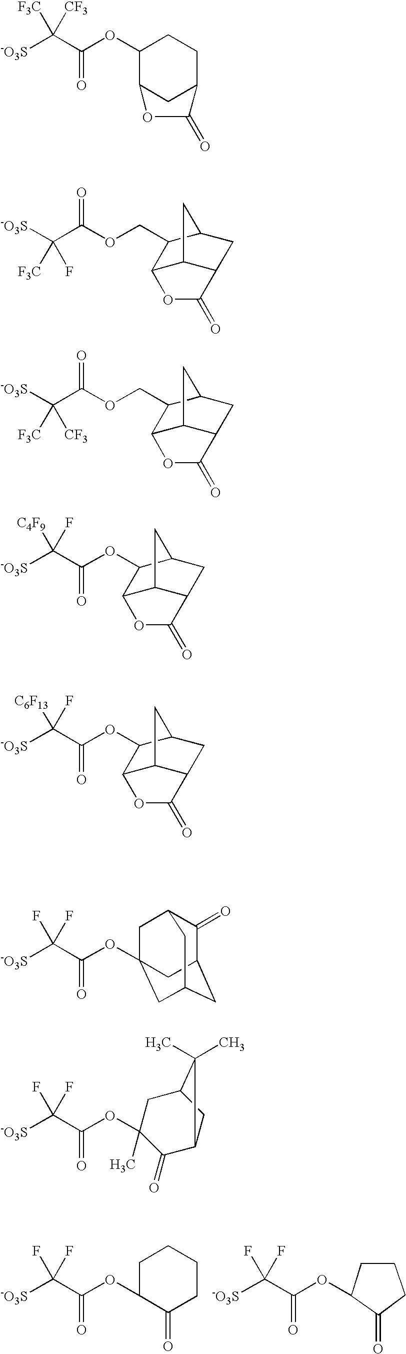

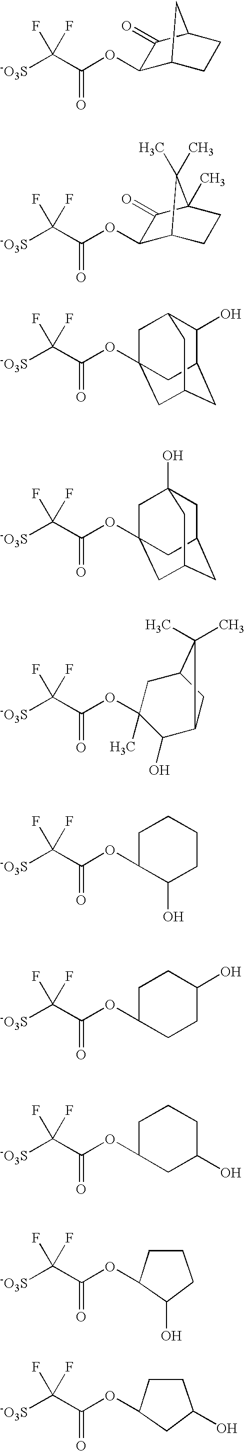

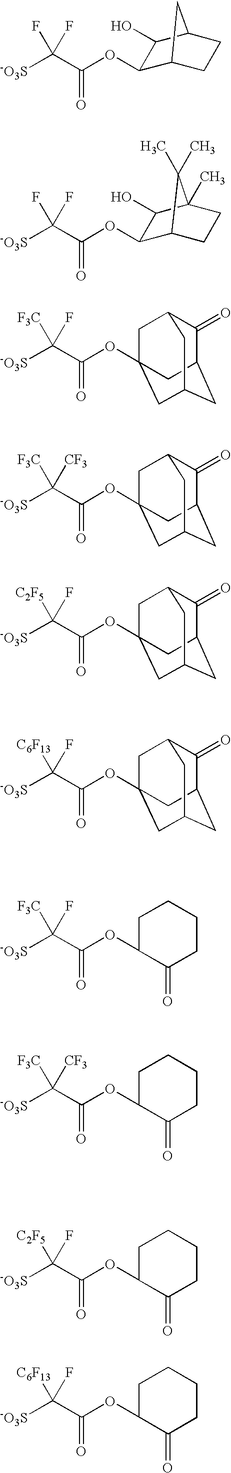

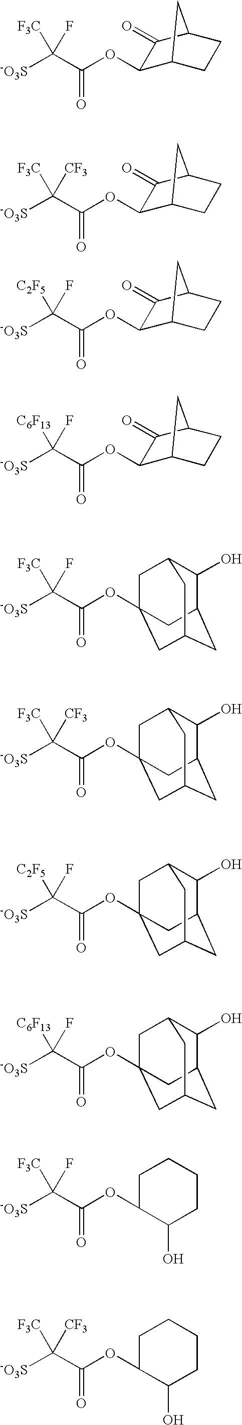

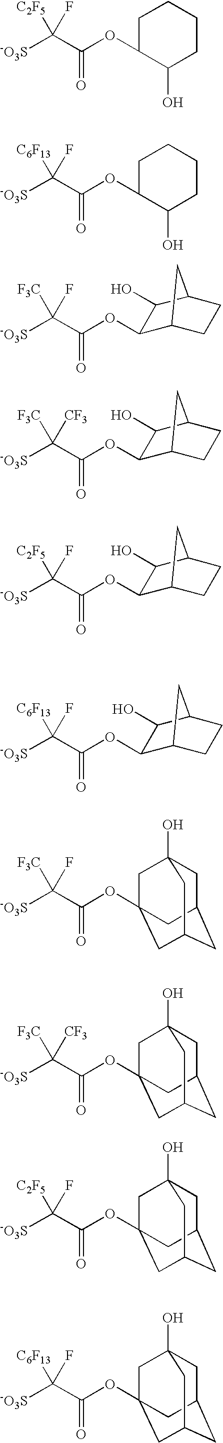

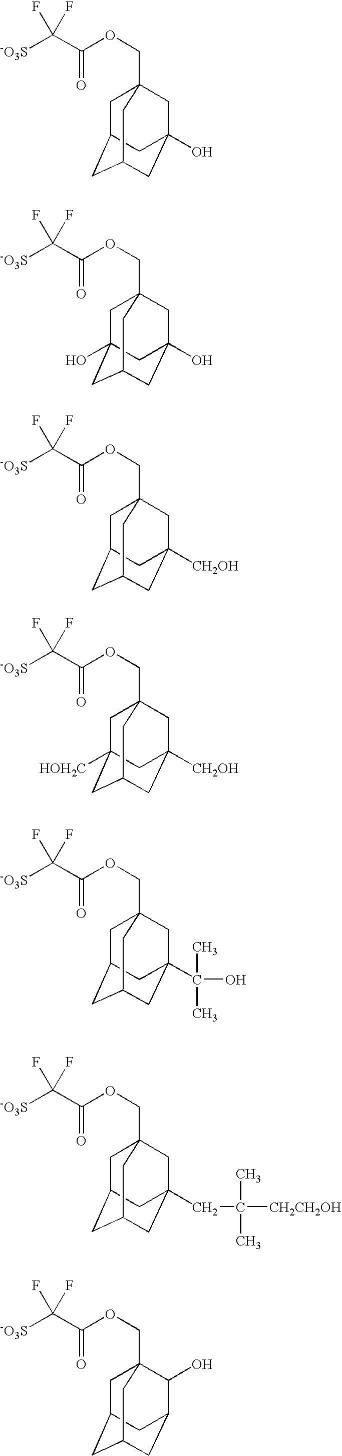

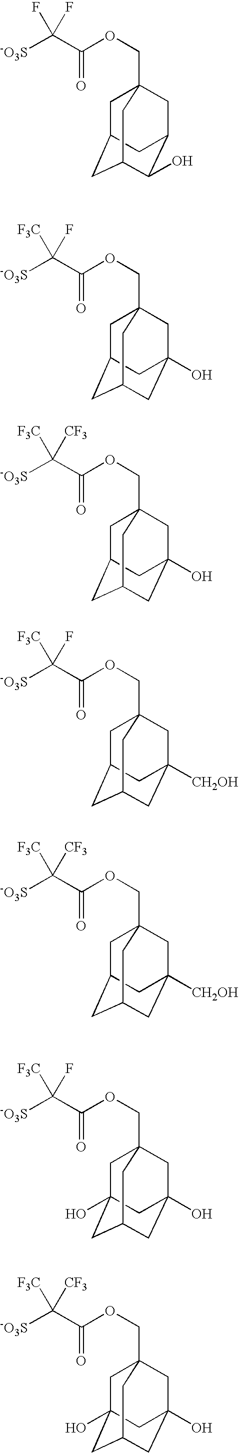

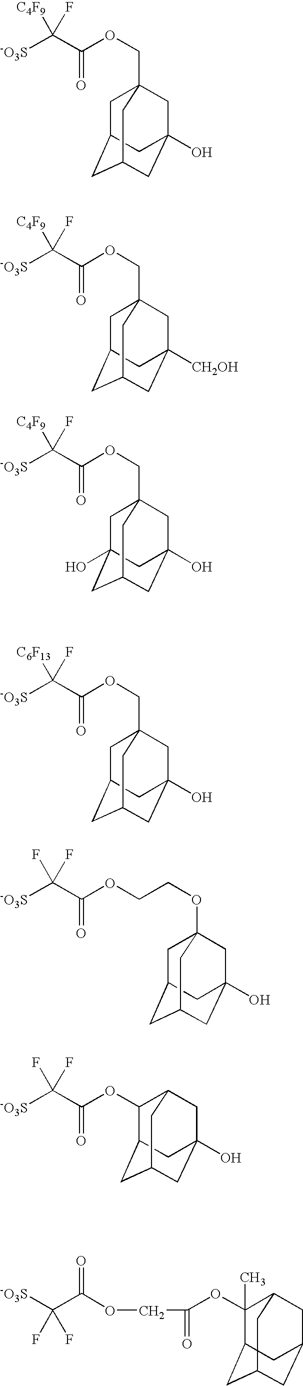

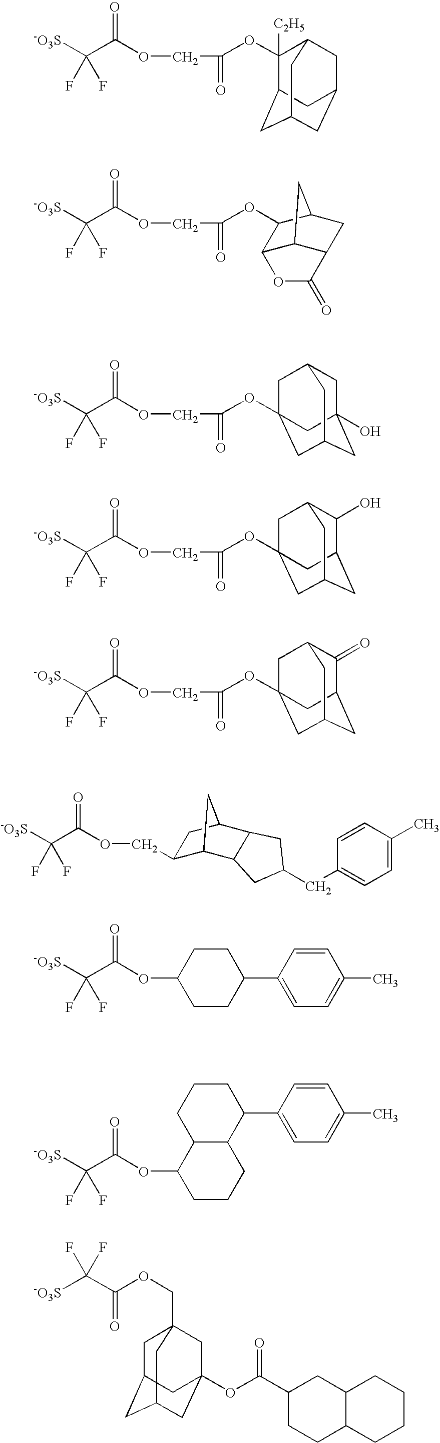

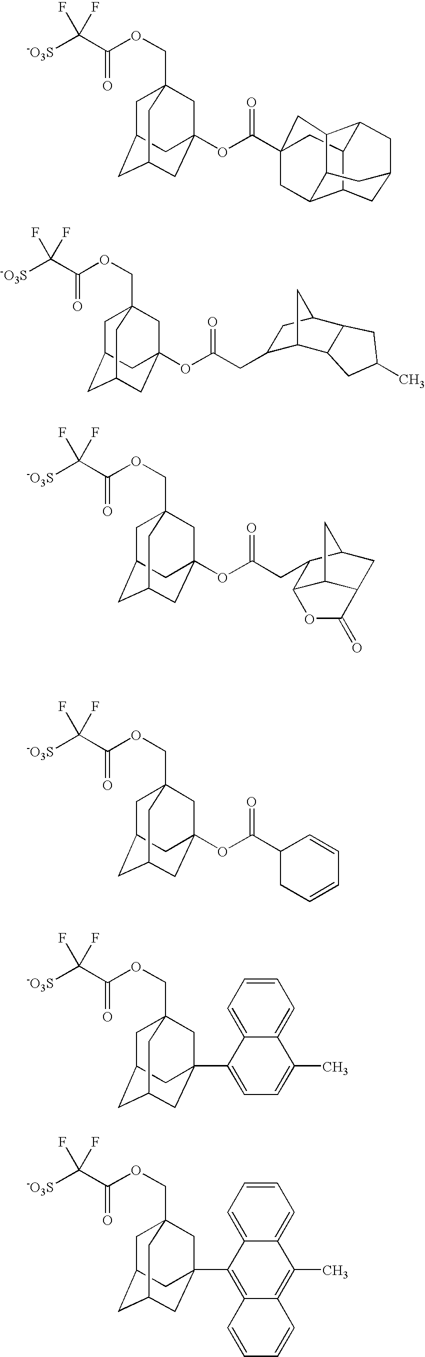

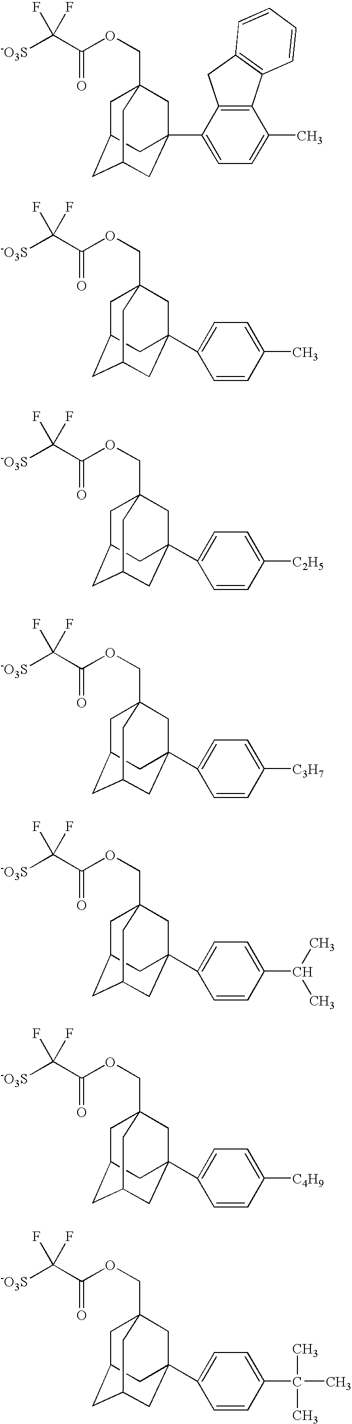

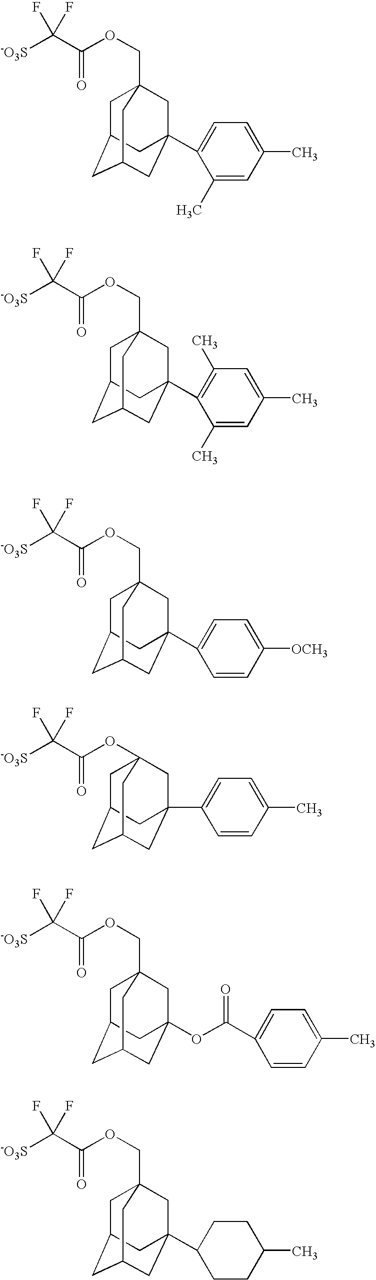

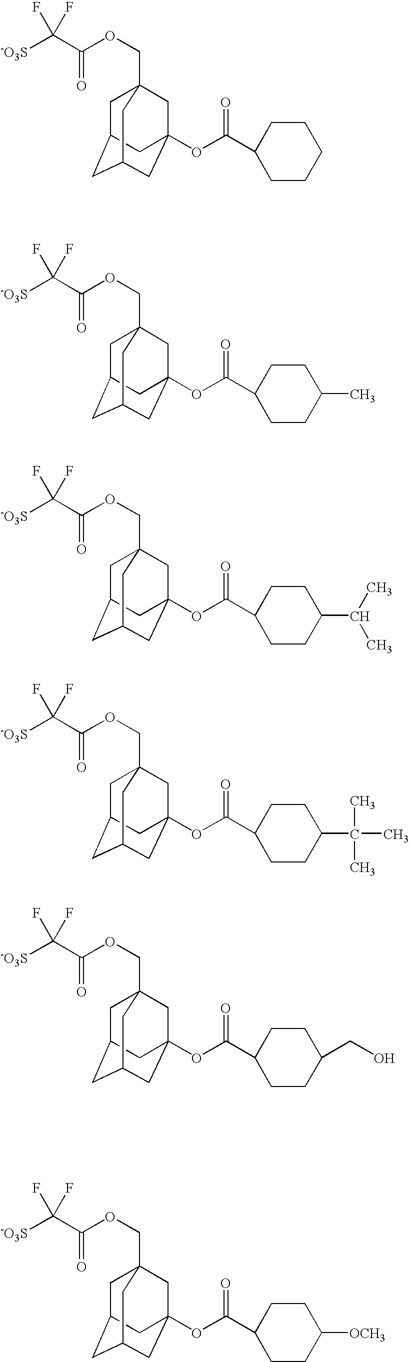

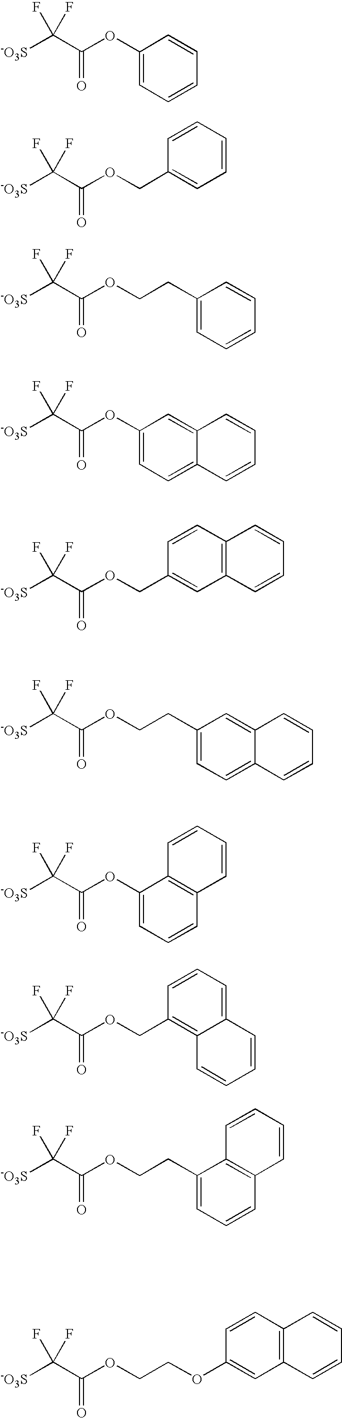

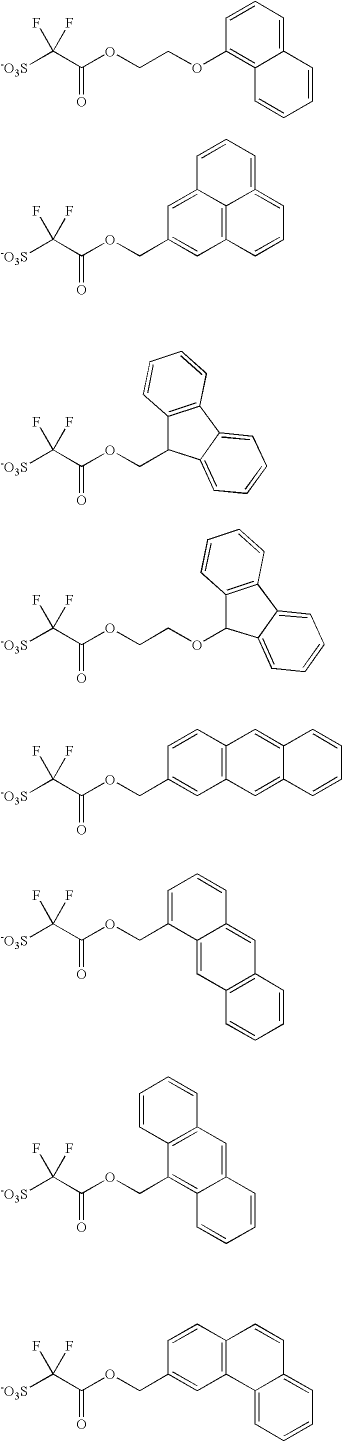

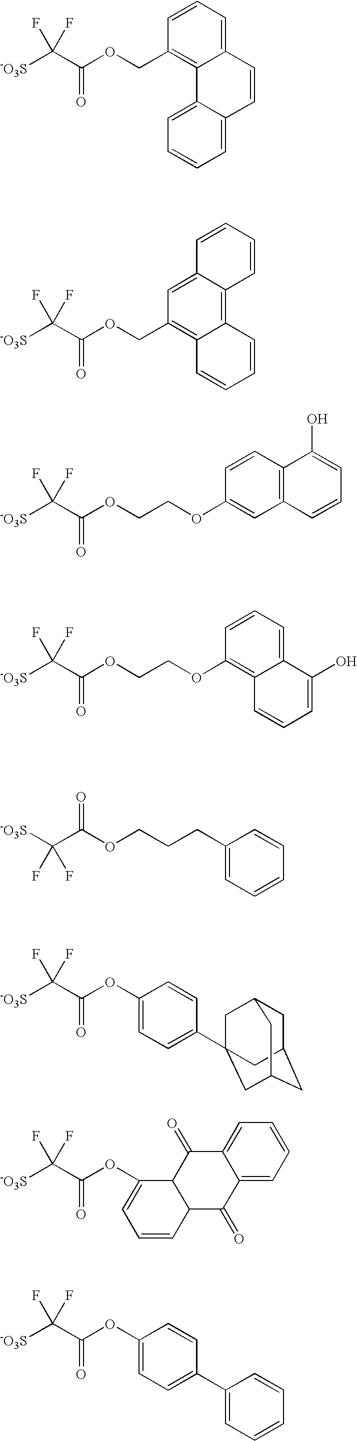

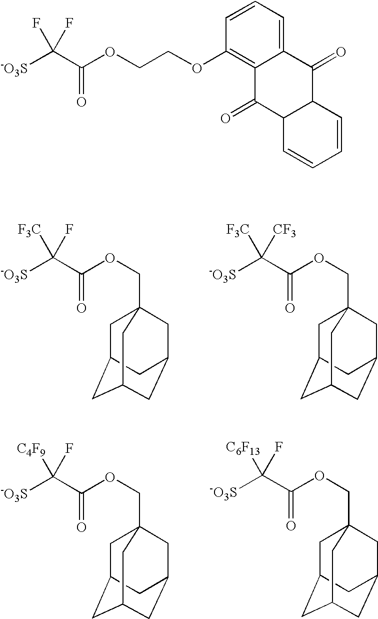

Among Salt (V), a salt represented by the formula (VI):

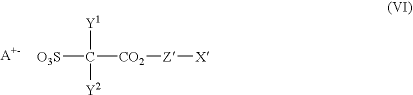

wherein Y¹, Y² and A⁺ are the same meanings as defined above, Z′ represents a single bond or a C1-C4 alkylene group, and X′ represents a C3-C30 monocyclic or polycyclic hydrocarbon group having a hydroxyl group or a carbonyl group, and one or more hydrogen atoms in the monocyclic or polycyclic hydrocarbon group may be replaced by a C1-C6 alkoxy group, a C1-C4 perfluoroalkyl group, a C1-C6 hydroxyalkyl group, a hydroxyl group or a cyano group (hereinafter, simply referred to as Salt (VI)) is preferable.

Examples of the C1-C6 alkoxy group, the C1-C4 perfluoroalkyl group and the C1-C6 hydroxyalkyl group in X′ include the same groups as described above, respectively.

Examples of the C1-C4 alkylene group in Z′ include a methylene group, an ethylene group, a trimethylene group and a tetramethylene group. Z′ is preferably a single bond, a methylene group or an ethylene group, and is more preferable a single bond or a methylene group.

Examples of X′ include a C4-C8 cycloalkyl group such as a cyclobutyl group, a cyclopentyl group, a cyclohexyl group and a cyclooctyl group, an adamantyl group, and a norbornyl group, in all of which one or more hydrogen atoms may be replaced by the C1-06 alkoxy group, the C1-C4 perfluoroalkyl group, the C1-C6 hydroxyalkyl group, a hydroxyl group or a cyano group.

Specific examples of X′ include a 2-oxocyclopentyl group, a 2-oxocyclohexyl group, a 3-oxocyclopentyl group, a 3-oxocyclohexyl group, a 4-oxocyclohexyl group, a 2-hydroxycyclopentyl group, a 2-hydroxycyclohexyl group, a 3-hydroxycyclopentyl group, a 3-hydroxycyclohexyl group, a 4-hydroxycyclohexyl group, a 4-oxo-2-adamantyl group, a 3-hydroxy-1-adamantyl group, a 4-hydroxy-1-adamantyl group, a 5-oxonorbornan-2-yl group, a 1,7,7-trimethyl-2-oxonorbornan-2-yl group, a 3,6,6-trimethyl-2-oxo-bicyclo[3.1.1]heptan-3-yl group, a 2-hydroxy-norbornan-3-yl group, a 1,7,7-trimethyl-2-hydroxynorbornan-3-yl group, a 3,6,6-trimethyl-2-hydroxybicyclo[3.1.1]heptan-3-yl group, and the following groups (in the following formulae, straight line with an open end shows a bond which is extended from an adjacent group).

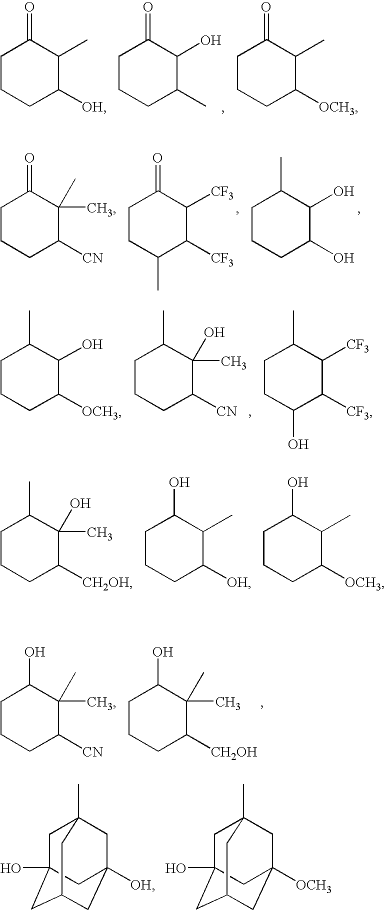

Specific examples of the anion part of Salt (VI) include the followings.

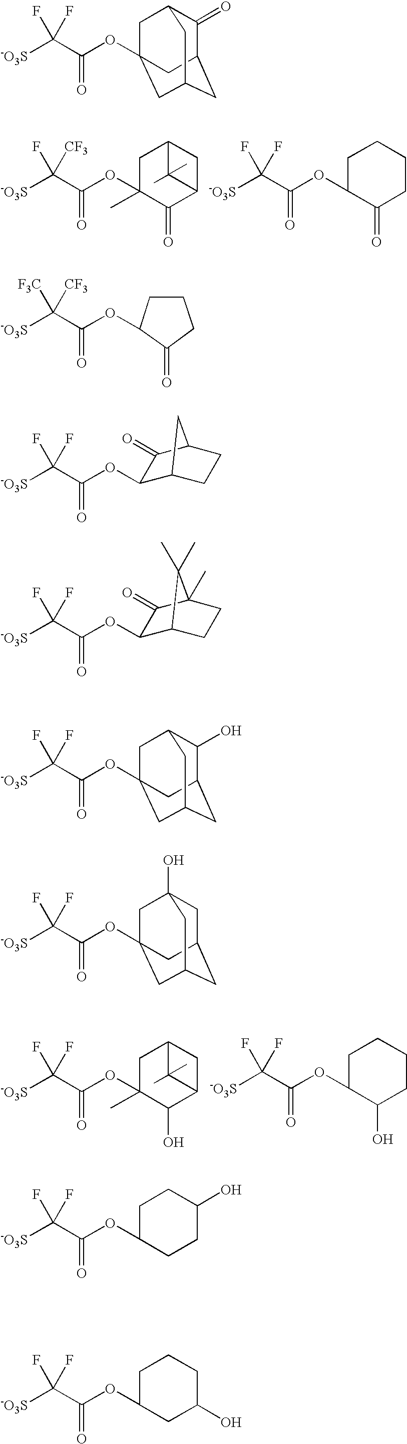

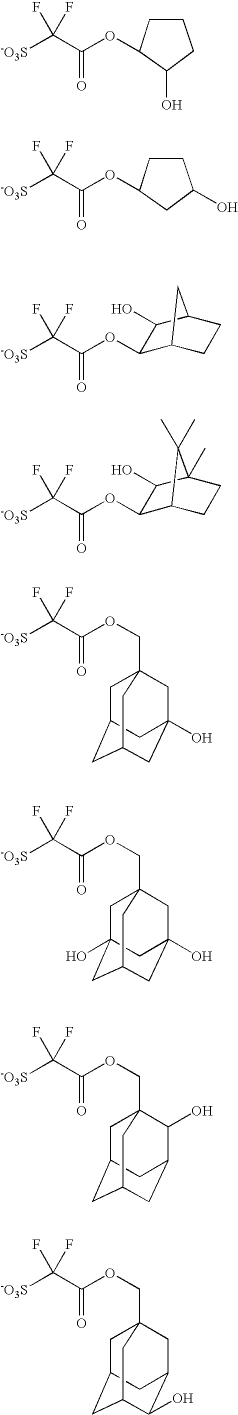

Other examples of the acid generator include a salt represented by the formula (VIII):

A⁺⁻O₃S—R⁵² (VIII)

wherein R⁵² represents a linear or branched chain C1-C6 perfluoroalkyl group and A⁺ is the same as defined above (hereinafter, simply referred to as Salt (VIII)).

In Salt (VIII), examples of the linear or branched chain C1-C6 perfluoroalkyl group include a trifluoromethyl group, a pentafluoroethyl group, a heptafluoropropyl group, a nonafluorobutyl group and a tridecafluorohexyl group.

Specific examples of the anion part of Salt (VIII) include the followings.

CF₃—SO₃⁻

CF₃CF₂CF₂—SO₃⁻

CF₃CF₂CF₂CF₂—SO₃⁻

CF₃CF₂CF₂CF₂CF₂CF₂—SO₃⁻

In Salt (V), Salt (VI) and Salt (VIII), A⁺ represents an organic counter ion. Examples of the organic counter ion include a cation represented by the formula (IXz):

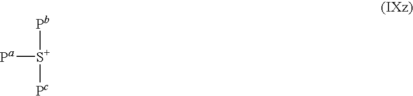

wherein P^{a}, P^{b} and P^{c} each independently represent a C1-C30 alkyl group or a C3-C30 cyclic hydrocarbon group, and the alkyl group may have one or more substituents selected from the group consisting of a hydroxyl group, a C3-C12 cyclic hydrocarbon group and a C1-C12 alkoxy group, and the cyclic hydrocarbon group may have one or more substituents selected from the group consisting of a hydroxyl group and a C1-C12 alkoxy group (hereinafter, simply referred to as the cation (IXz)), a cation represented by the formula (IXb):

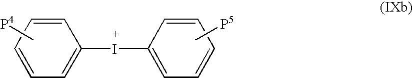

wherein P⁴ and P⁵ each independently represent a hydrogen atom, a hydroxyl group, a C1-C12 alkyl group or a C1-C12 alkoxy group (hereinafter, simply referred to as the cation (IXb)),
a cation represented by the formula (IXc):

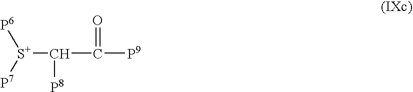

wherein P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group may be replaced by —CO—, —O— or —S—, P⁸ represents a hydrogen atom, P⁹ represents a C1-C12 alkyl group, a C3-C12 cycloalkyl group or an aromatic group which may have one or more substituents, or P⁸ and P⁹ are bonded to form a divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S— (hereinafter, simply referred to as the cation (IXc)); and
a cation represented by the formula (IXd):

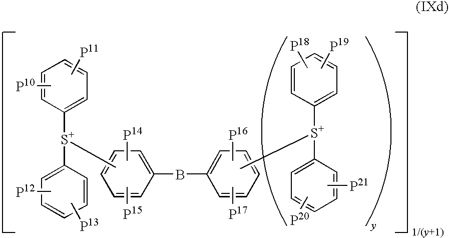

wherein P¹⁰, P¹¹, P¹², P¹³, P¹⁴, P¹⁵, P¹⁶, P¹⁷, P¹⁸, P¹⁹, P²⁰ and P²¹ each independently represent a hydrogen atom, a hydroxyl group, a C1-C12 alkyl group or a C1-C12 alkoxy group, B represents a sulfur atom or an oxygen atom and y represents 0 or 1 (hereinafter, simply referred to as the cation (IXd)).

Examples of the C1-C12 alkoxy group in the cations (IXz), (IXb) and (IXd) include a methoxy group, an ethoxy group, a propoxy group, an isopropoxy group, a butoxy group, an isobutoxy group, a sec-butoxy group, a tert-butoxy group, a pentyloxy group, a hexyloxy group, an octyloxy group and a 2-ethylhexyloxy group.

Examples of the C3-C12 cyclic hydrocarbon group in the cation (IXz) include a cyclopentyl group, a cyclohexyl group, a 1-adamantyl group, a 2-adamantyl group, a phenyl group, a 2-methylphenyl group, a 4-methylphenyl group, a 1-naphthyl group and a 2-naphthyl group.

Examples of the C1-C30 alkyl group which may have one or more substituents selected from the group consisting of a hydroxyl group, a C3-C12 cyclic hydrocarbon group and a C1-C12 alkoxy group in the cation (IXz) include a methyl group, an ethyl group, a propyl group, an isopropyl group, a butyl group, an isobutyl group, a sec-butyl group, a tert-butyl group, a pentyl group, a hexyl group, an octyl group, a 2-ethylhexyl group and a benzyl group.

Examples of the C3-C30 cyclic hydrocarbon group which may have one or more substituents selected from the group consisting of a hydroxyl group and a C1-C12 alkoxy group in the cation (IXz) include a cyclopentyl group, a cyclohexyl group, a 1-adamantyl group, a 2-adamantyl group, a bicyclohexyl group, a phenyl group, a 2-methylphenyl group, a 4-methylphenyl group, a 4-ethylphenyl group, a 4-isopropylphenyl group, a 4-tert-butylphenyl group, a 2,4-dimethylphenyl group, a 2,4,6-trimethylphenyl group, a 4-hexylphenyl group, a 4-octylphenyl group, a 1-naphthyl group, a 2-naphthyl group, a fluorenyl group, a 4-phenylphenyl group, a 4-hydroxyphenyl group, a 4-methoxyphenyl group, a 4-tert-butoxyphenyl group and a 4-hexyloxyphenyl group.

Examples of the C1-C12 alkyl group in the cations (IXb), (IXc) and (IXd) include a methyl group, an ethyl group, a propyl group, an isopropyl group, a butyl group, an isobutyl group, a sec-butyl group, a tert-butyl group, a pentyl group, a hexyl group, an octyl group and a 2-ethylhexyl group.

Examples of the C3-C12 cycloalkyl group in the cation (IXc) include a cyclopropyl group, a cyclobutyl group, a cyclopentyl group, a cyclohexyl group, a cycloheptyl group, a cyclooctyl group and a cyclodecyl group. Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and oxybisethylenesulfonio group.

Examples of the aromatic group in the cation (IXc) include a phenyl group, a tolyl group, a xylyl group, a 4-butylphenyl group, a 4-isobutylphenyl group, a 4-tert-butylphenyl group, a 4-cyclohexylphenyl group, a 4-phenylphenyl group, a 1-naphthyl group and a 2-naphthyl group. The aromatic group may have one or more substituents, and examples of the substituents include a C1-C6 alkoxy group such as a methoxy group, an ethoxy group, a propoxy group, a butoxy group, a tert-butoxy group and a hexyloxy group; a C2-C12 acyloxy group such as an acetyloxy group and a 1-adamantylcarbonyloxy group; and a nitro group.

Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include a 2-oxocyclopentyl group and a 2-oxocyclohexyl group.

Examples of the cation (IXz) include the followings:

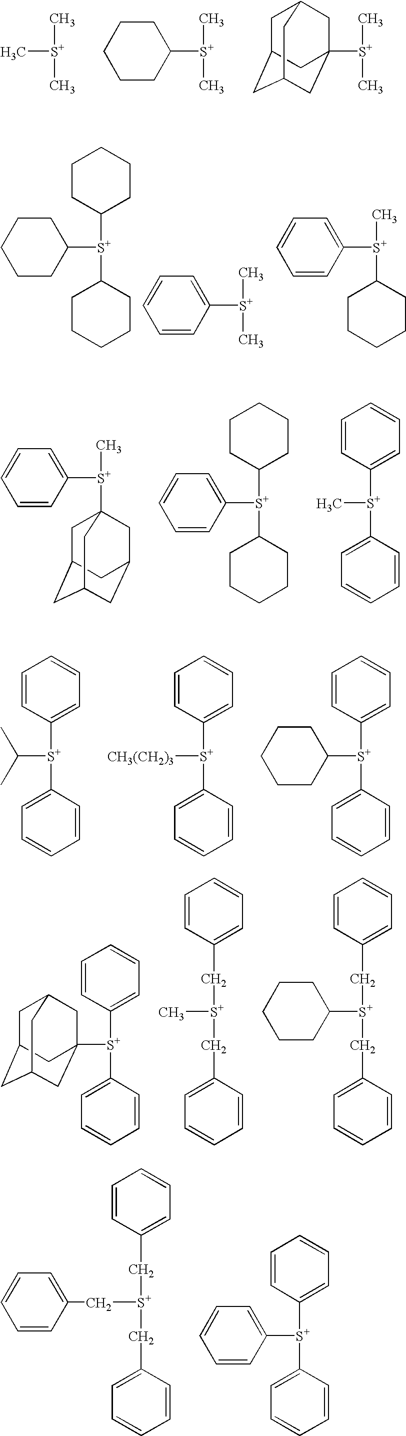

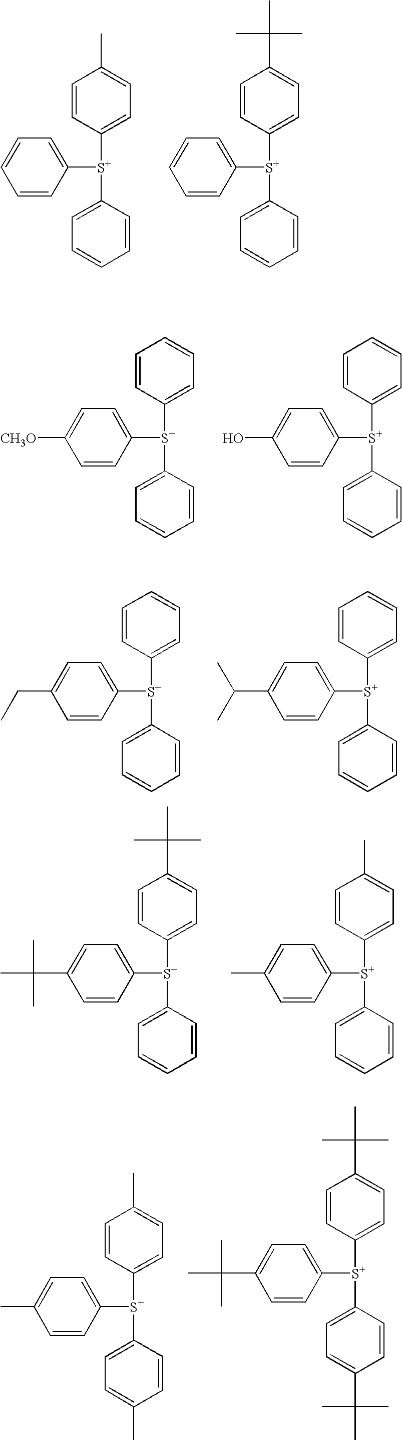

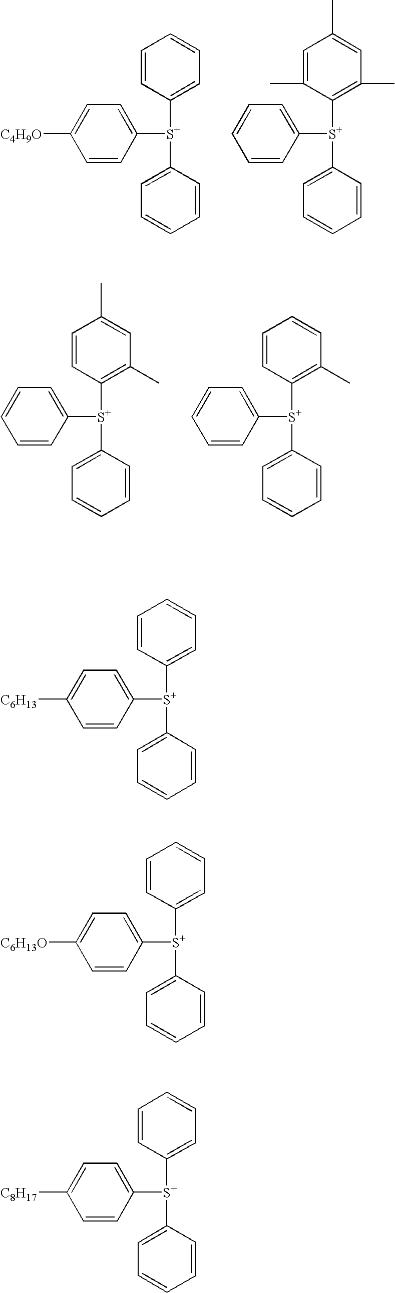

Specific examples of the cation (IXb) include the following:

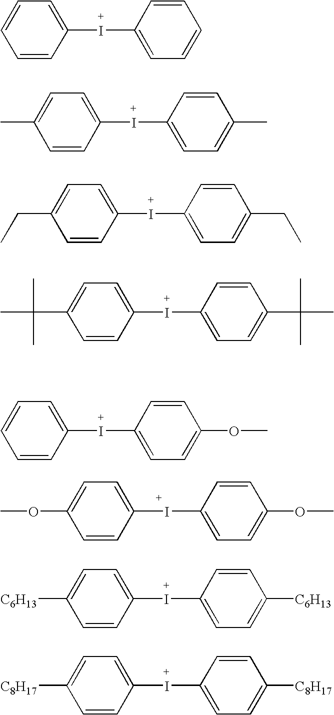

Specific examples of the cation (IXc) include the following:

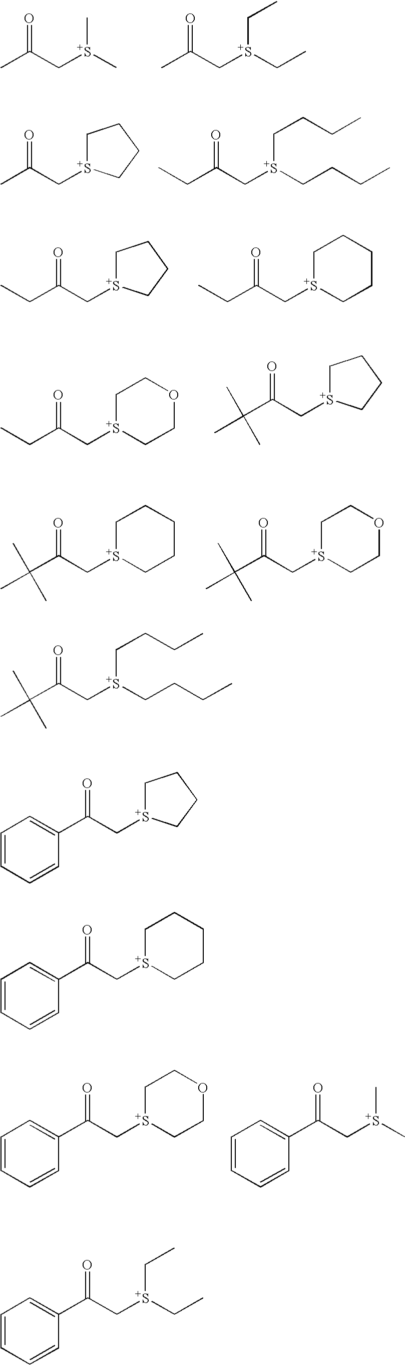

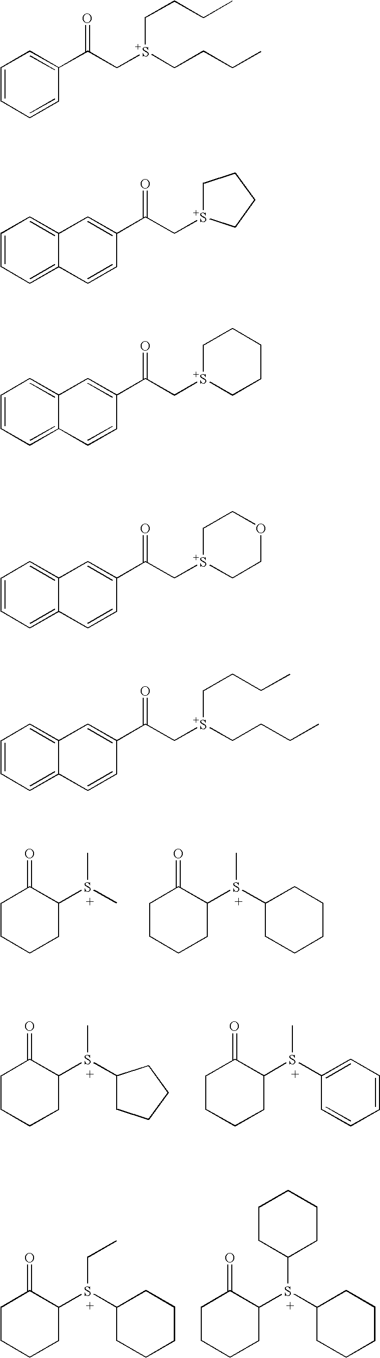

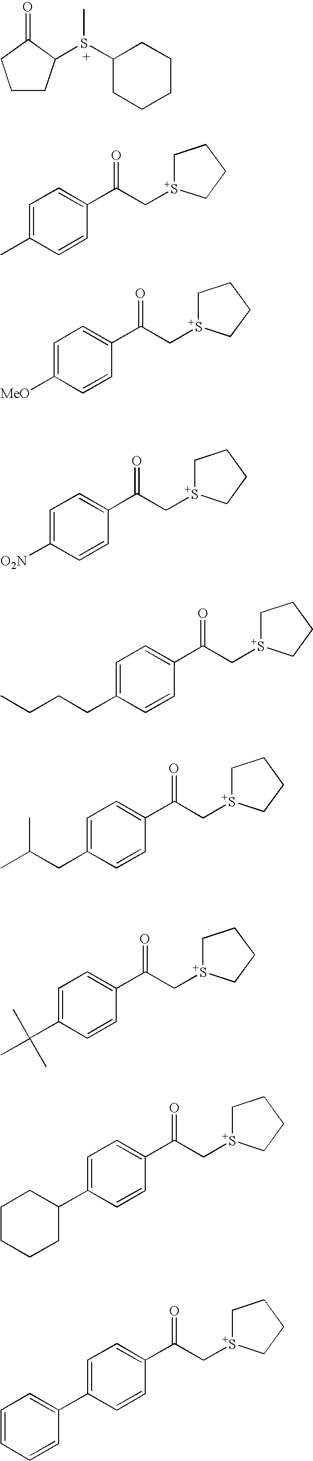

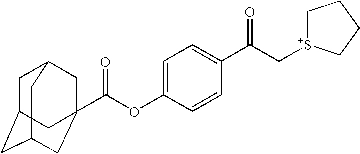

Specific examples of the cation (IXd) include the following:

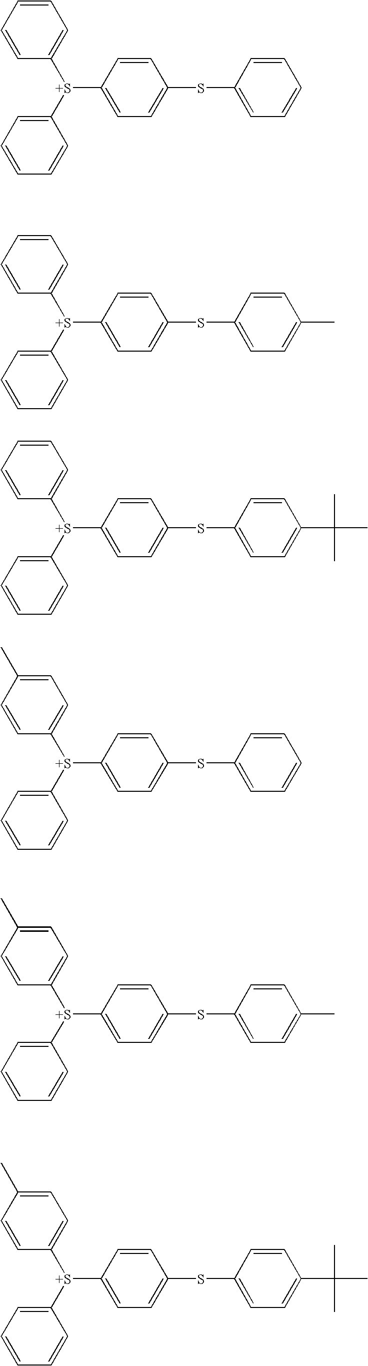

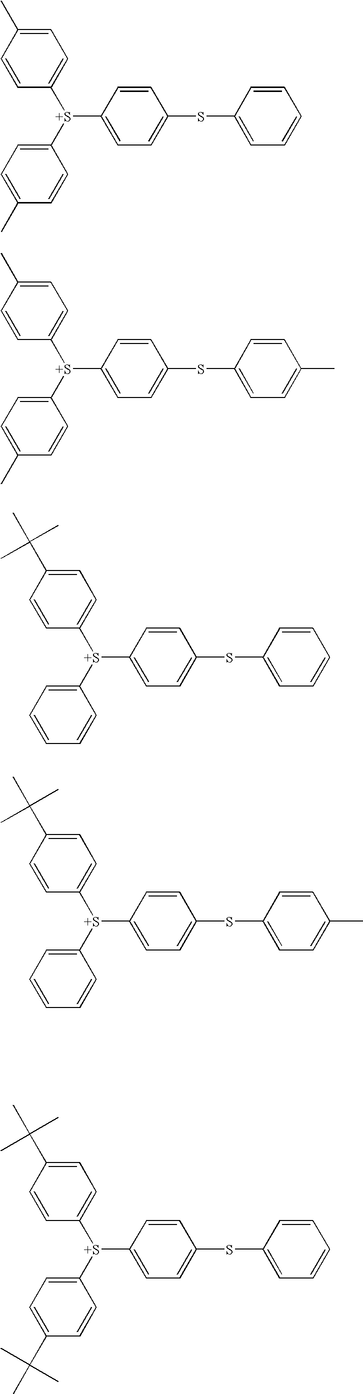

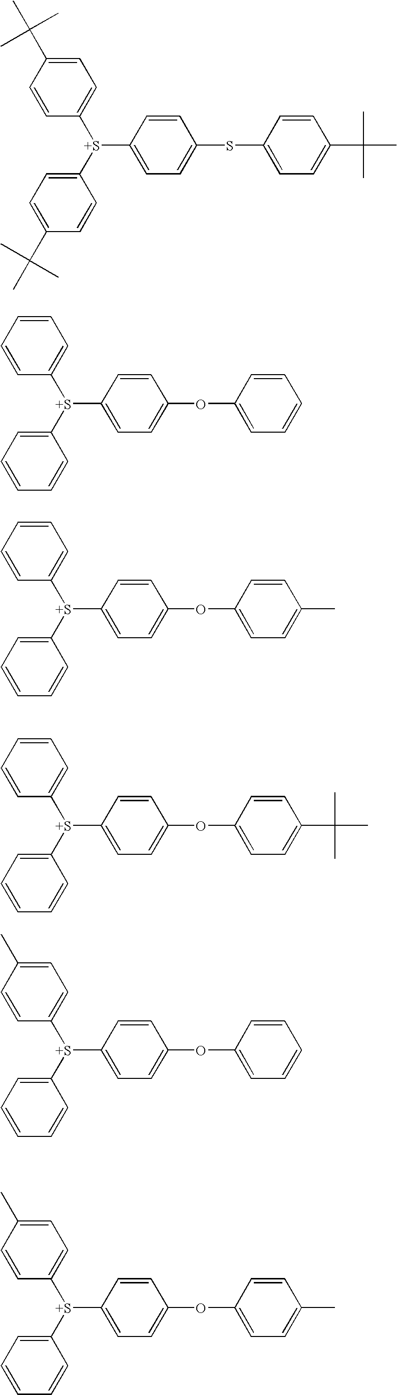

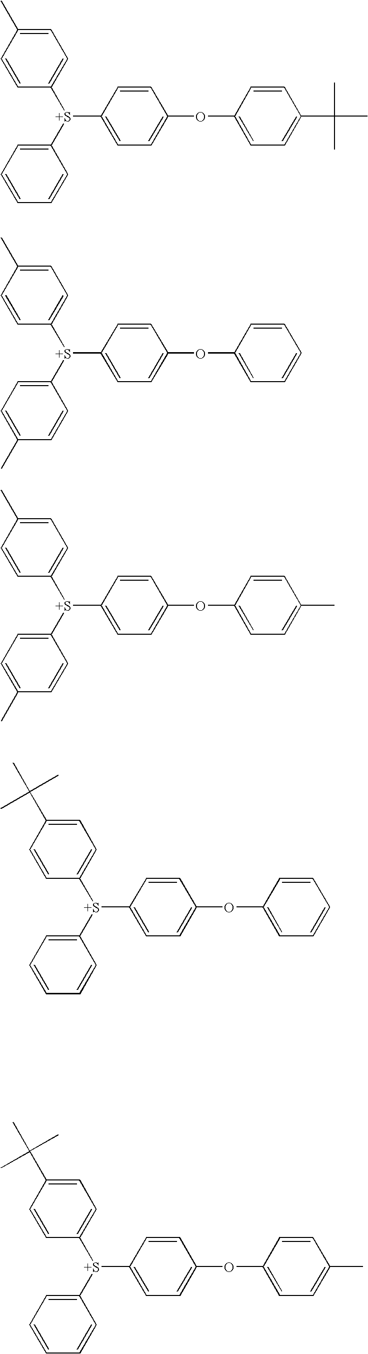

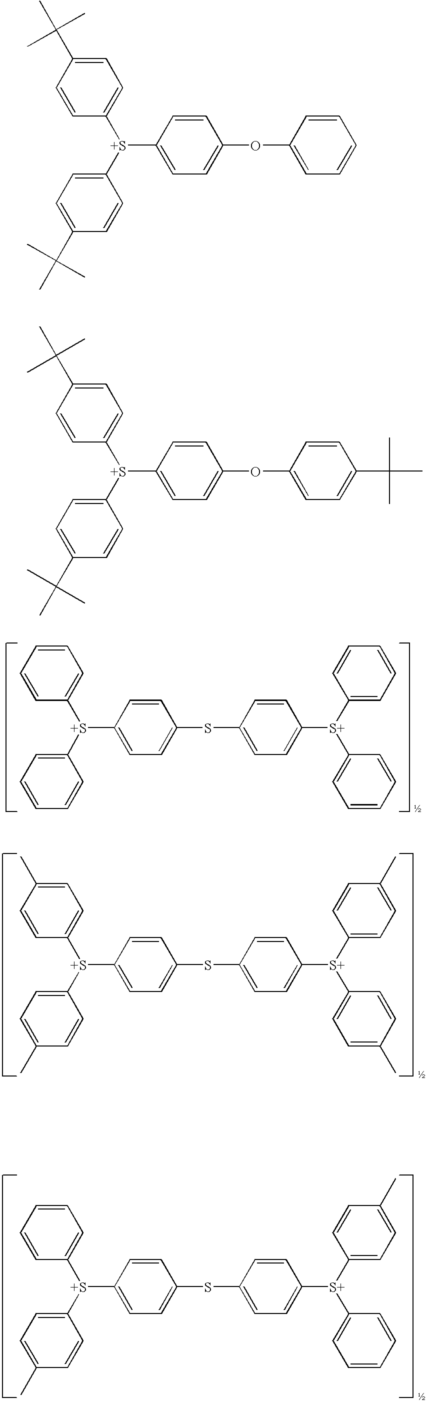

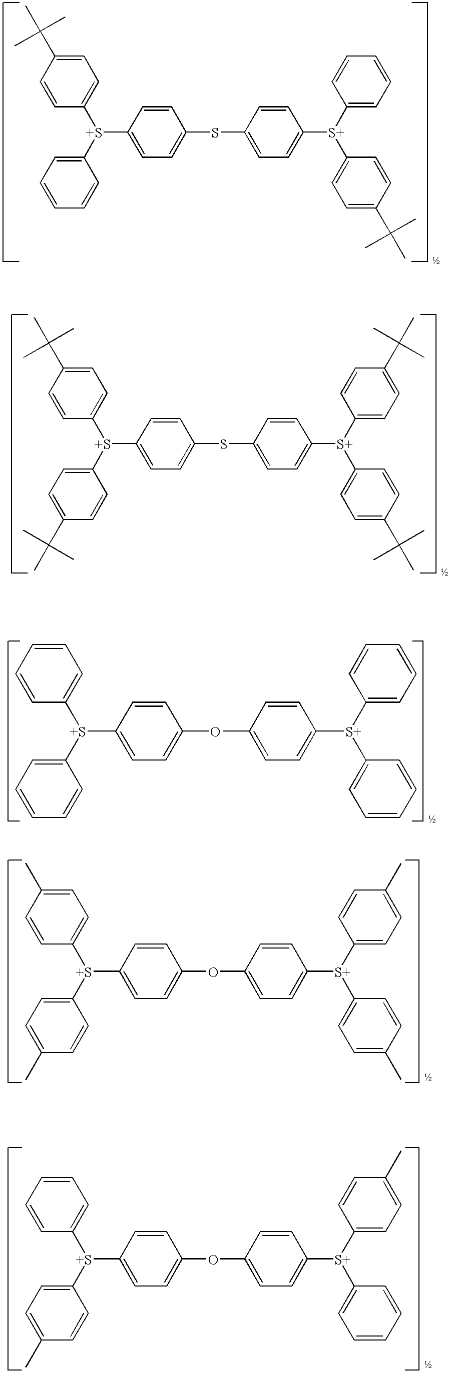

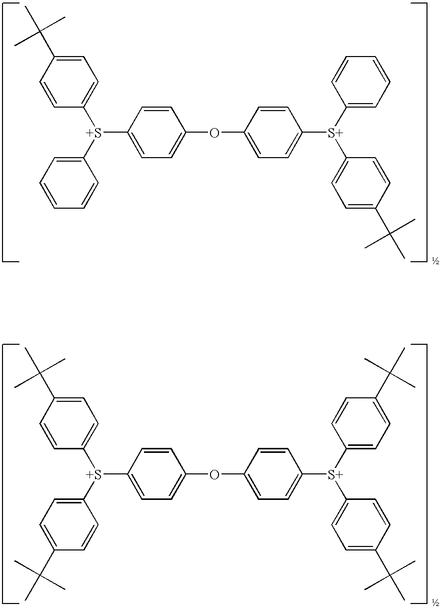

Among the cation (IXz), the cation represented by the formula (IXa):

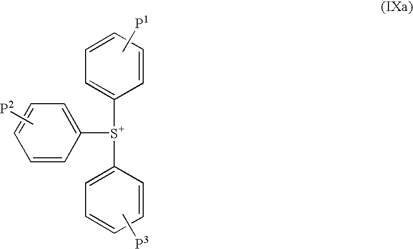

wherein P¹, P² and P³ each independently represent a hydrogen atom, a hydroxyl group, a C1-C12 alkyl group or a C1-C12 alkoxy group, is preferable. Examples of the C1-C12 alkyl group and the C1-C12 alkoxy group include the same as described above.

As the organic counter ion represented by A⁺, a cation represented by the following formulae (IXe):

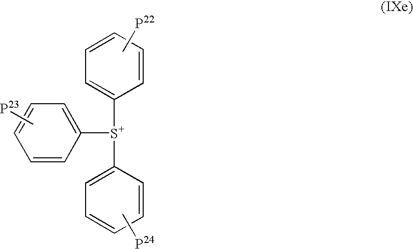

wherein P²², P²³ and P²⁴ each independently represent a hydrogen atom or a C1-C4 alkyl group, is also preferable.

As the Salt (VI), a salt wherein A⁺ is the cation represented by the following formulae (IXe) and the anion part is the following:

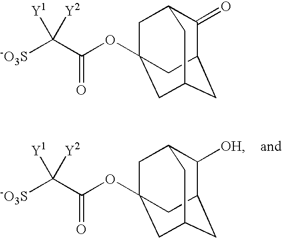

a salt wherein A⁺ is the cation represented by the following formulae (IXc) and the anion part is the following:

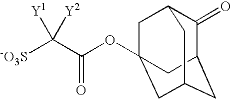

are preferable.

Salt (VI) can be produced according to known methods such as a method described in JP 2007-249192 A1.

The salts represented by the formulae (Xd) and (Xe):

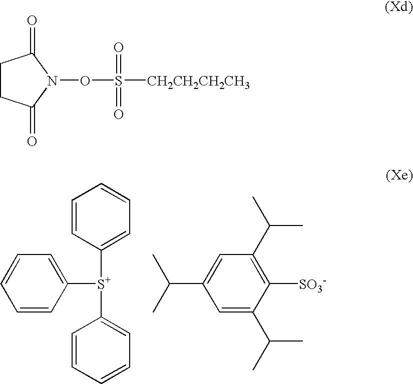

are also preferable.

The salt represented by the formula (Xf):

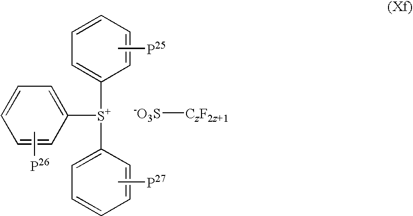

wherein P²⁵, P²⁶ and P²⁷ are the same as defined above and z represents an integer of 1 to 6, is also preferable.

The present resist composition preferably includes 60 to 99.9% by weight of the resin and 0.1 to 40% by weight of an acid generator based on the total amount of the resin and an acid generator.

In the present resist composition, performance deterioration caused by inactivation of acid which occurs due to post exposure delay can be diminished by adding an organic base compound, particularly a nitrogen-containing organic base compound as a quencher.

Specific examples of the nitrogen-containing organic base compound include an amine compound represented by the following formulae:

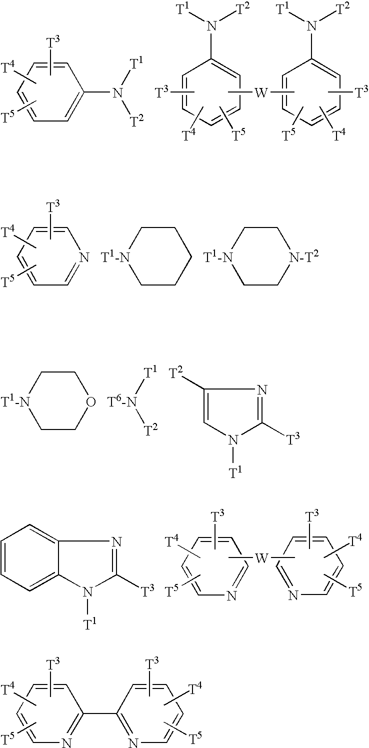

wherein T¹ and T² each independently represent a hydrogen atom, an alkyl group, a cycloalkyl group or an aryl group, and the alkyl, cycloalkyl and aryl groups may have one or more substituents selected from the group consisting of a hydroxyl group, an amino group which have one or two C1-C4 alkyl groups and a C1-C6 alkoxy group,
T³ and T⁴ each independently represent a hydrogen atom, an alkyl group, a cycloalkyl group, an aryl group or an alkoxy group, and the alkyl, cycloalkyl, aryl and alkoxy groups may have one or more substituents selected from the group consisting of a hydroxyl group, an amino group which may have one or more C1-C4 alkyl groups and a C1-C6 alkoxy group, or T³ and T⁴ are bonded each other to form an aromatic ring together with the carbon atoms to which they are bonded,
T⁵ represents a hydrogen atom, an alkyl group, a cycloalkyl group, an aryl group, an alkoxy group or a nitro group, and the alkyl, cycloalkyl, aryl and alkoxy groups may have one or more substituents selected from the group consisting of a hydroxyl group, an amino group which may have one or two C1-C4 alkyl groups and a C1-C6 alkoxy group,
T⁶ represents an alkyl group or a cycloalkyl group, and the alkyl and cycloalkyl groups may have one or more substituents selected from the group consisting of a hydroxyl group, an amino group which may have one or two C1-C4 alkyl groups and a C1-C6 alkoxy group, and W represents —CO—, —NH—, —S—, —S—S—, an alkylene group of which one or more —CH₂— may be replaced by —O—, or an alkenylene group of which one or more —CH₂— may be replaced by —O—,
   and a quaternary ammonium hydroxide represented by the following formula:

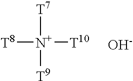

wherein T⁷, T⁸, T⁹ and T¹⁰ each independently represent an alkyl group, a cycloalkyl group or an aryl group, and the alkyl, cycloalkyl and aryl groups may have one or more substituents selected from the group consisting of a hydroxyl group, an amino group which may have one or two C1-C4 alkyl groups and a C1-C6 alkoxy group.

The alkyl group in T¹, T², T³, T⁴, T⁵, T⁶, T⁷, T⁸, T⁹ and T¹⁰ preferably has about 1 to 10 carbon atoms, and more preferably has about 1 to 6 carbon atoms.

Examples of the amino group which may have one or two C1-C4 alkyl groups include an amino group, a methylamino group, an ethylamino group, a butylamino group, a dimethylamino group and a diethylamino group. Examples of the C1-C6 alkoxy group which may be substituted with the C1-C6 alkoxy group or groups include a methoxy group, an ethoxy group, a propoxy group, an isopropoxy group, a butoxy group, a tert-butoxy group, a pentyloxy group, a hexyloxy group and a 2-methoxyethoxy group.

Specific examples of the alkyl group which may have one or more substituents selected from the group consisting of a hydroxyl group, an amino group which may have one or two C1-C4 alkyl groups, and a C1-C6 alkoxy group include a methyl group, an ethyl group, a propyl group, an isopropyl group, a butyl group, a tert-butyl group, a pentyl group, a hexyl group, an octyl group, a nonyl group, a decyl group, a 2-(2-methoxyethoxy)ethyl group, a 2-hydroxyethyl group, a 2-hydroxypropyl group, a 2-aminoethyl group, a 4-aminobutyl group and a 6-aminohexyl group.

The cycloalkyl group in T¹, T², T³, T⁴, T⁵, T⁶, T⁷, T⁸, T⁹ and T¹⁰ preferably has about 5 to 10 carbon atoms. Specific examples of the cycloalkyl group which may have one or more substituents selected from the group consisting of a hydroxyl group, an amino group which may have one or two C1-C4 alkyl groups and a C1-C6 alkoxy group include a cyclopentyl group, a cyclohexyl group, a cycloheptyl group and a cyclooctyl group.

The aryl group in T¹, T², T³, T⁴, T⁵, T⁶, T⁷, T⁸, T⁹ and T¹⁰ preferably has about 6 to 10 carbon atoms. Specific examples of the aryl group which may have one or more substituents selected from the group consisting of a hydroxyl group, an amino group which may have one or two C1-C4 alkyl groups and a C1-C6 alkoxy group include a phenyl group and a naphthyl group.

The alkoxy group in T³, T⁴ and T⁵ preferably has about 1 to 6 carbon atoms and specific examples thereof include a methoxy group, an ethoxy group, a propoxy group, an isopropoxy group, a butoxy group, a tert-butoxy group, a pentyloxy group and a hexyloxy group.

The alkylene and alkenylene groups in W preferably have 2 to 6 carbon atoms. Specific examples of the alkylene group include an ethylene group, a trimethylene group, a tetramethylene group, a methylenedioxy group and an ethylene-1,2-dioxy group, and specific examples of the alkenylene group include an ethene-1,2-diyl group, a 1-propene-1,3-diyl group and a 2-butene-1,4-diyl group.

Specific examples of the amine compound include hexylamine, heptylamine, octylamine, nonylamine, decylamine, aniline, 2-methylaniline, 3-methylaniline, 4-methylaniline, 4-nitroaniline, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 1,2-bis(4-pyridyl)ethylene, 2,2′-dipicolylamine and 3,3′-dipicolylamine.

Examples of the quaternary ammonium hydroxide include tetramethylammonium hydroxide, tetraisopropylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).

A hindered amine compound having a piperidine skeleton as disclosed in JP 11-52575 A1 can be also used as the quencher.

In the point of forming patterns having higher resolution, the quaternary ammonium hydroxide is preferably used as the quencher.

When the basic compound is used as the quencher, the present resist composition preferably includes 0.01 to 5% by weight of the basic compound based on the total amount of the solid components.

The present resist composition can contain, if necessary, a small amount of various additives such as a sensitizer, a dissolution inhibitor, other polymers, a surfactant, a stabilizer and a dye as long as the effect of the present invention is not prevented.

The present resist composition is usually in the form of a resist liquid composition in which the above-mentioned ingredients are dissolved in a solvent and the resist liquid composition is applied onto a substrate such as a silicon wafer by a conventional process such as spin coating. The solvent used is sufficient to dissolve the above-mentioned ingredients, have an adequate drying rate, and give a uniform and smooth coat after evaporation of the solvent. Solvents generally used in the art can be used.

Examples of the solvent include a glycol ether ester such as ethyl cellosolve acetate, methyl cellosolve acetate and propylene glycol monomethyl ether acetate; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

A resist film applied onto the substrate and then dried is subjected to exposure for patterning, then heat-treated to facilitate a deblocking reaction, and thereafter developed with an alkali developer. The alkali developer used may be any one of various alkaline aqueous solution used in the art. Generally, an aqueous solution of tetramethylammonium hydroxide or (2-hydroxyethyl)trimethylammonium hydroxide (commonly known as “choline”) is often used.

The present resist composition is especially suitable for ArF excimer laser lithography, KrF excimer laser lithography and ArF immersion lithography.

It should be construed that embodiments disclosed here are examples in all aspects and not restrictive. It is intended that the scope of the present invention is determined not by the above descriptions but by appended claims, and includes all variations of the equivalent meanings and ranges to the claims.

The present invention will be described more specifically by way of examples, which are not construed to limit the scope of the present invention. The “%” and “part(s)” used to represent the content of any component and the amount of any material used in the following examples and comparative examples are on a weight basis unless otherwise specifically noted. The weight-average molecular weight of any material used in the following examples is a value found by gel permeation chromatography [Column (Three Columns): TSKgel Multipore HXL-M, Solvent: Tetrahydrofuran, manufactured by TOSOH CORPORATION] using polystyrene as a standard reference material.

Monomers used in the following Resin Synthetic Examples are following monomers M1, M2, M3, M4, M5, M6, M7, M8 and M9.

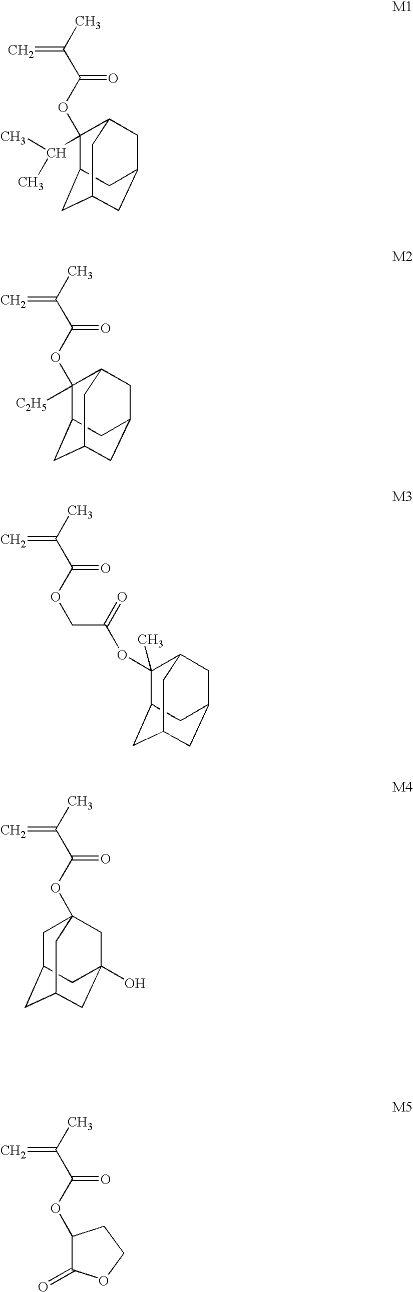

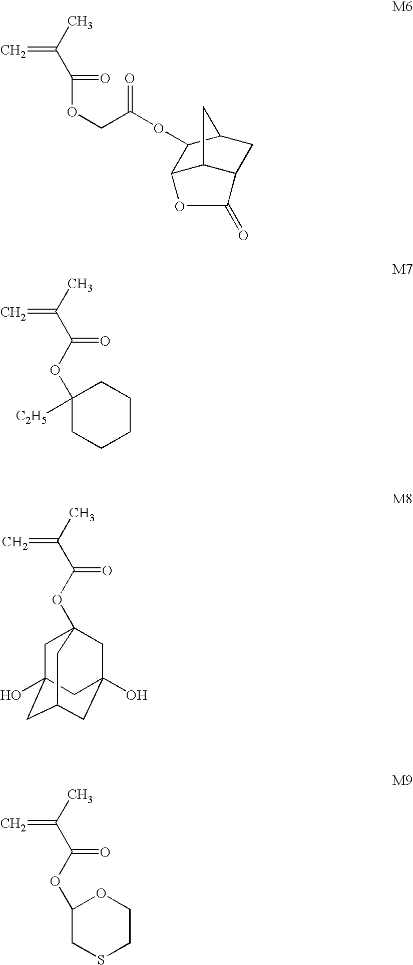

### Resin Synthetic Example 1

Into a flask equipped with a condenser and a thermometer, 10.31 parts of 1,4-dioxane was charged and a nitrogen gas was blown into it for 30 minutes. After heating it up to 75° C. under nitrogen, a solution obtained by mixing 29.70 parts of monomer M1, 4.12 parts of monomer M4, 7.41 parts of monomer M5, 0.29 parts of 2,2′-azobisisobutyronitrile, 1.30 parts of 2,2′-azobis(2,4-dimethylvaleronitrile) and 30.92 parts of 1,4-dioxane was added dropwise thereto over 1 hour at 75° C. The resultant mixture was stirred for 5 hours at 75° C. After cooling the reaction mixture, the reaction mixture was diluted with 65.96 parts of 1,4-dioxane and the resultant solution was poured into 536 parts of methanol to cause precipitation. The precipitate was isolated and mixed with 268 parts of methanol. The resultant mixture was stirred followed by filtrating to obtain the precipitate. The operation wherein the precipitate was mixed with 268 parts of methanol and the resultant mixture was stirred followed by filtrating to obtain the precipitate was repeated twice. The obtained precipitate was dried under reduced pressure to obtain 19 parts of a resin having a weight-average molecular weight (Mw) of 6.7×10³ and a dispersion degree (Mw/Mn) of 1.45 in a yield of 46%. This resin had the structural units represented by the formula A, D and E. This is called as resin R1. The ratio of the structural units represented by the formula A, ID and E (A/D/E) was 52/13/35.

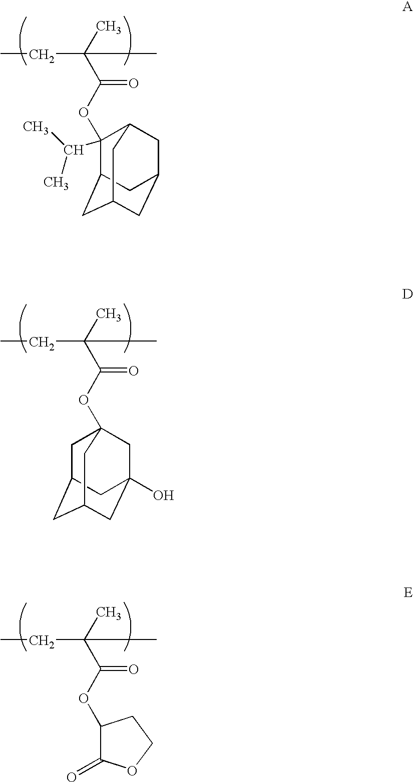

### Resin Synthetic Example 2

Into a flask equipped with a condenser and a thermometer, 21.21 parts of 1,4-dioxane was charged and a nitrogen gas was blown into it for 30 minutes. After heating it up to 72° C. under nitrogen, a solution obtained by mixing 60.00 parts of monomer M1, 7.09 parts of monomer M3, 6.55 parts of monomer M4, 11.20 parts of monomer M5, 0.57 parts of 2,2′-azobisisobutyronitrile, 2.58 parts of 2,2′-azobis(2,4-dimethylvaleronitrile) and 63.63 parts of 1,4-dioxane was added dropwise thereto over 2 hours at 72° C. The resultant mixture was stirred for 5 hours at 72° C. After cooling the reaction mixture, the reaction mixture was diluted with 135.75 parts of 1,4-dioxane and the resultant solution was poured into a mixture of 882 parts of methanol and 221 parts of ion-exchanged water to cause precipitation. The precipitate was isolated and mixed with 551 parts of methanol. The resultant mixture was stirred followed by filtrating to obtain the precipitate. The operation wherein the precipitate was mixed with 551 parts of methanol and the resultant mixture was stirred followed by filtrating to obtain the precipitate was repeated twice. The obtained precipitate was dried under reduced pressure to obtain 52 parts of a resin having a weight-average molecular weight (Mw) of 5.9×10³ and a dispersion degree (Mw/Mn) of 1.91 in a yield of 62%. This resin had the structural units represented by the formula A, C, D and E. This is called as resin R2. The ratio of the structural units represented by the formula A, C, D and E (A/C/D/E) was 52/10/11/27.

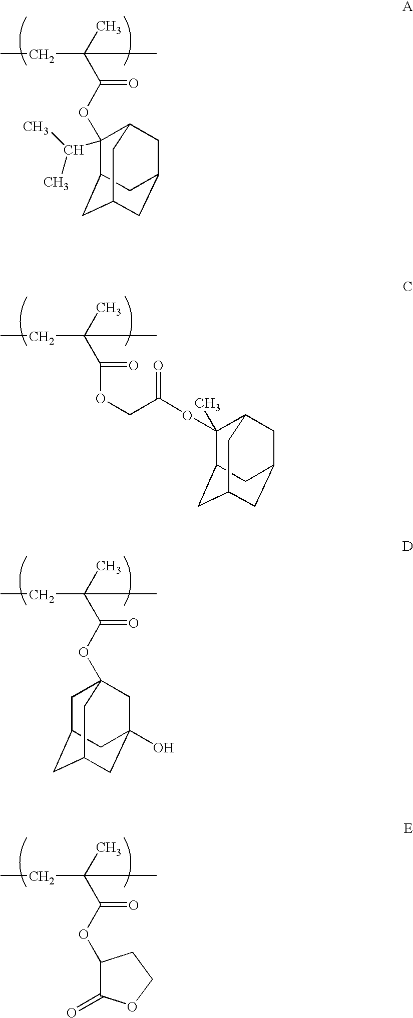

### Resin Synthetic Example 3

Into a flask equipped with a condenser and a thermometer, 11.51 parts of 1,4-dioxane was charged and a nitrogen gas was blown into it for 30 minutes. After heating it up to 73° C. under nitrogen, a solution obtained by mixing 30.00 parts of monomer M1, 3.55 parts of monomer M3, 3.27 parts of monomer M4, 9.22 parts of monomer M6, 0.28 parts of 2,2′-azobisisobutyronitrile, 1.29 parts of 2,2′-azobis(2,4-dimethylvaleronitrile) and 34.53 parts of 1,4-dioxane was added dropwise thereto over 1 hour at 73° C. The resultant mixture was stirred for 5 hours at 73° C. After cooling the reaction mixture, the reaction mixture was diluted with 73.67 parts of 1,4-dioxane and the resultant solution was poured into a mixture of 479 parts of methanol and 120 parts of ion-exchanged water to cause precipitation. The precipitate was isolated and mixed with 299 parts of methanol. The resultant mixture was stirred followed by filtrating to obtain the precipitate. The operation wherein the precipitate was mixed with 299 parts of methanol and the resultant mixture was stirred followed by filtrating to obtain the precipitate was repeated twice. The obtained precipitate was dried under reduced pressure to obtain 27 parts of a resin having a weight-average molecular weight (Mw) of 7.7×10³ and a dispersion degree (Mw/Mn) of 1.87 in a yield of 60%. This resin had the structural units represented by the formula A, C, D and F. This is called as resin R3. The ratio of the structural units represented by the formula A, C, D and F (A/C/D/F) was 54/9/11/26.

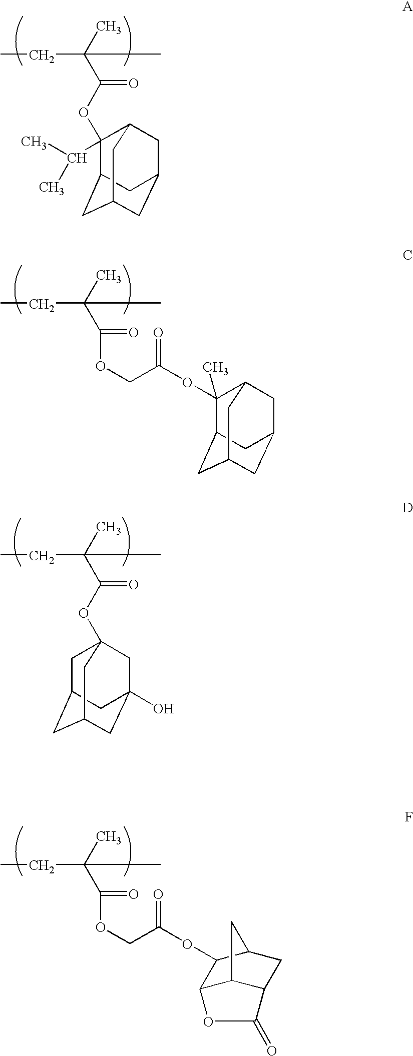

### Comparative Resin Synthetic Example 1

Into a flask equipped with a condenser and a thermometer, 70.91 parts of methyl isobutyl ketone was charged and a nitrogen gas was blown into it for 30 minutes. After heating it up to 87° C. under nitrogen, a solution obtained by mixing 30.00 parts of monomer M2, 14.27 parts of monomer M4, 10.28 parts of monomer M5, 0.79 parts of 2,2′-azobisisobutyronitrile and 70.91 parts of methyl isobutyl ketone was added dropwise thereto over 2 hours at 87° C. The resultant mixture was stirred for 6 hours at 87° C. After cooling the reaction mixture, the reaction mixture was poured into a mixture of 895 parts of methanol and 196 parts of ion-exchanged water to cause precipitation. The precipitate was isolated and mixed with 344 parts of methanol. The resultant mixture was stirred followed by filtrating to obtain the precipitate. The operation wherein the precipitate was mixed with 344 parts of methanol and the resultant mixture was stirred followed by filtrating to obtain the precipitate was repeated twice. The obtained precipitate was dried under reduced pressure to obtain 25 parts of a resin having a weight-average molecular weight (Mw) of 9.4×10³ and a dispersion degree (Mw/Mn) of 1.52 in a yield of 47%. This resin had the structural units represented by the formula B, D and E. This is called as resin R4. The ratio of the structural units represented by the formula B, D and E (B/D/E) was 33/33/34.

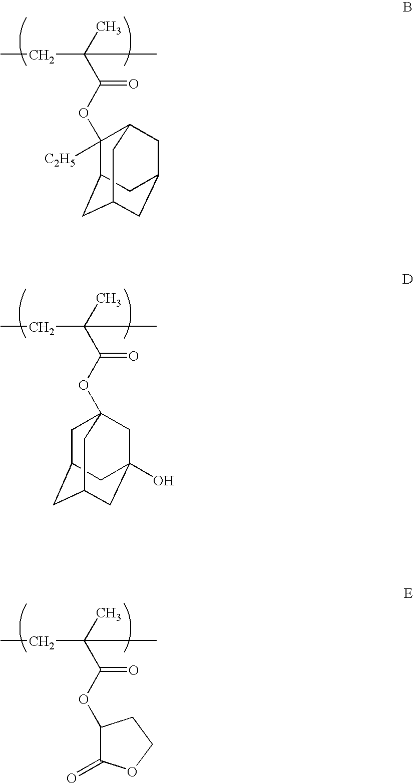

### Resin Synthetic Example 4

Into a flask equipped with a condenser and a thermometer, 23.97 parts of 1,4-dioxane was charged and a nitrogen gas was blown into it for 30 minutes. After heating it up to 75° C. under nitrogen, a solution obtained by mixing 17.50 parts of monomer M1, 4.91 parts of monomer M7, 3.94 parts of monomer M4, 9.35 parts of monomer M6, 4.26 parts of monomer M5, 0.27 parts of 2,2′-azobisisobutyronitrile, 1.24 parts of 2,2′-azobis(2,4-dimethylvaleronitrile) and 35.96 parts of 1,4-dioxane was added dropwise thereto over 1 hour at 75° C. The resultant mixture was stirred for 5 hours at 75° C. After cooling the reaction mixture, the reaction mixture was diluted with 43.95 parts of 1,4-dioxane and the resultant solution was poured into a mixture of 415 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 30 parts of a resin having a weight-average molecular weight (Mw) of 7.5×10³ and a dispersion degree (Mw/Mn) of 1.90 in a yield of 74%. This resin had the structural units represented by the formula A, G, D, F and E. This is called as resin R5. The ratio of the structural units represented by the formula A, G, D, F and E (A/G/D/F/E) was 29/15/12/25/19.

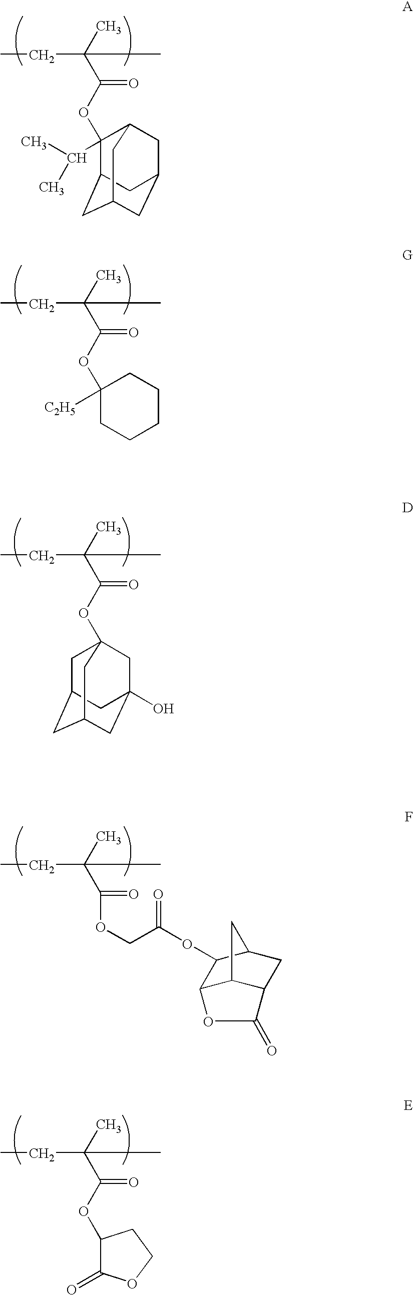

### Resin Synthetic Example 5

Into a flask equipped with a condenser and a thermometer, 24.04 parts of 1,4-dioxane was charged and a nitrogen gas was blown into it for 30 minutes. After heating it up to 73° C. under nitrogen, a solution obtained by mixing 18.00 parts of monomer M1, 2.09 parts of monomer M7, 2.88 parts of monomer M4, 17.09 parts of monomer M6, 0.25 parts of 2,2′-azobisisobutyronitrile, 1.14 parts of 2,2′-azobis(2,4-dimethylvaleronitrile) and 36.06parts of 1,4-dioxane was added dropwise thereto over 1 hour at 73° C. The resultant mixture was stirred for 5 hours at 73° C. After cooling the reaction mixture, the reaction mixture was diluted with 44.07 parts of 1,4-dioxane and the resultant solution was poured into a mixture of 415 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 28 parts of a resin having a weight-average molecular weight (Mw) of 7.1×10³ and a dispersion degree (Mw/Mn) of 1.82 in a yield of 69%. This resin had the structural units represented by the formula A, G, D and F. This is called as resin R6. The ratio of the structural units represented by the formula A, G, D and F (A/G/D/F) was 33/7/10/50.

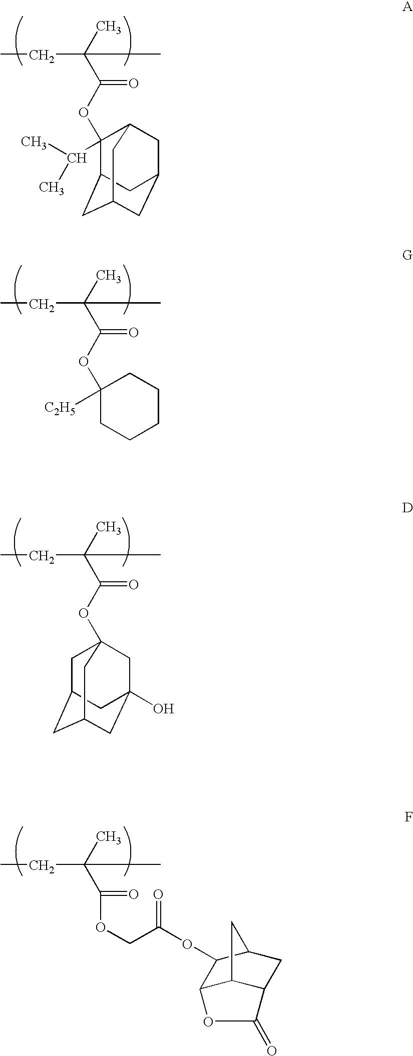

### Resin Synthetic Example 6

Into a flask equipped with a condenser and a thermometer, 24.04 parts of 1,4-dioxane was charged and a nitrogen gas was blown into it for 30 minutes. After heating it up to 75° C. under nitrogen, a solution obtained by mixing 18.50 parts of monomer M1, 3.01 parts of monomer M7, 3.09 parts of monomer M8, 15.46 parts of monomer M6, 0.25 parts of 2,2′-azobisisobutyronitrile, 1.14 parts of 2,2′-azobis(2,4-dimethylvaleronitrile) and 36.06 parts of 1,4-dioxane was added dropwise thereto over 1 hour at 75° C. The resultant mixture was stirred for 5 hours at 75° C. After cooling the reaction mixture, the reaction mixture was diluted with 44.07 parts of 1,4-dioxane and the resultant solution was poured into a mixture of 417 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 29 parts of a resin having a weight-average molecular weight (Mw) of 7.3×10³ and a dispersion degree (Mw/Mn) of 1.66 in a yield of 73%. This resin had the structural units represented by the formula A, G, H and F. This is called as resin R7. The ratio of the structural units represented by the formula A, G, H and F (A/G/H/F) was 35/10/10/45.

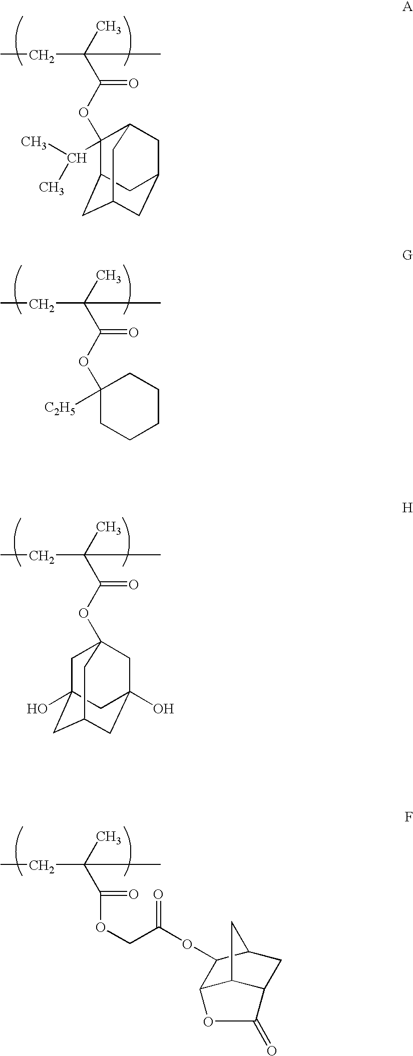

### Resin Synthetic Example 7

Into a flask equipped with a condenser and a thermometer, 19.18 parts of 1,4-dioxane was charged and a nitrogen gas was blown into it for 30 minutes. After heating it up to 75° C. under nitrogen, a solution obtained by mixing 22.80 parts of monomer M1, 3.41 parts of monomer M7, 10.47 parts of monomer M9, 3.29 parts of monomer M4, 0.29 parts of 2,2′-azobisisobutyronitrile, 1.29 parts of 2,2′-azobis(2,4-dimethylvaleronitrile) and 28.77 parts of 1,4-dioxane was added dropwise thereto over 1 hour at 75° C. The resultant mixture was stirred for 5 hours at 75° C. After cooling the reaction mixture, the reaction mixture was diluted with 55.95 parts of 1,4-dioxane and the resultant solution was poured into a mixture of 416 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 28 parts of a resin having a weight-average molecular weight (Mw) of 7.1×10³ and a dispersion degree (Mw/Mn) of 2.01 in a yield of 71%. This resin had the structural units represented by the formula A, G, I and D. This is called as resin R8. The ratio of the structural units represented by the formula A, G, I and D (A/G/I/D) was 41/10/39/10.

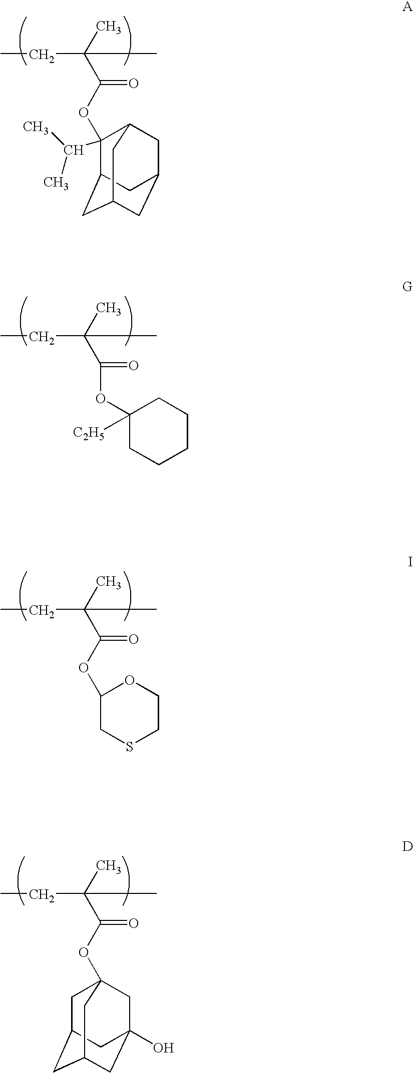

### Resin Synthetic Example 8

Into a flask equipped with a condenser and a thermometer, 19.17 parts of 1,4-dioxane was charged and a nitrogen gas was blown into it for 30 minutes. After heating it up to 75° C. under nitrogen, a solution obtained by mixing 21.50 parts of monomer M1, 5.55 parts of monomer M9, 3.31 parts of monomer M8, 7.35 parts of monomer M6, 2.23 parts of monomer M5, 0.27 parts of 2,2′-azobisisobutyronitrile, 1.22 parts of 2,2′-azobis(2,4-dimethylvaleronitrile) and 28.76 parts of 1,4-dioxane was added dropwise thereto over 1 hour at 75° C. The resultant mixture was stirred for 5 hours at 75° C. After cooling the reaction mixture, the reaction mixture was diluted with 55.92 parts of 1,4-dioxane and the resultant solution was poured into a mixture of 415 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 30 parts of a resin having a weight-average molecular weight (Mw) of 7.7×10³ and a dispersion degree (Mw/Mn) of 1.76 in a yield of 74%. This resin had the structural units represented by the formula A, I, H, F and E. This is called as resin R9. The ratio of the structural units represented by the formula A, I, H, F and E (A/I/H/F/E) was 39/22/10/19/10.

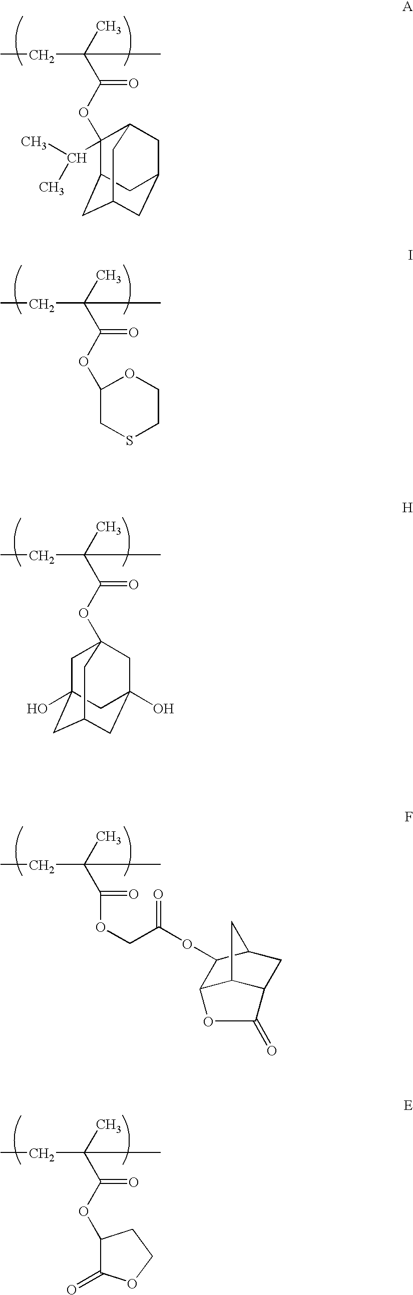

### Resin Synthetic Example 9

Into a flask equipped with a condenser and a thermometer, 14.39 parts of 1,4-dioxane was charged and a nitrogen gas was blown into it for 30 minutes. After heating it up to 75° C. under nitrogen, a solution obtained by mixing 19.50 parts of monomer M1, 4.35 parts of monomer M3, 2.81 parts of monomer M4, 13.33 parts of monomer M6, 0.24 parts of 2,2′-azobisisobutyronitrile, 1.11 parts of 2,2′-azobis(2,4-dimethylvaleronitrile) and 33.59 parts of 1,4-dioxane was added dropwise thereto over 1 hour at 75° C. The resultant mixture was stirred for 5 hours at 75° C. After cooling the reaction mixture, the reaction mixture was diluted with 55.98 parts of 1,4-dioxane and the resultant solution was poured into a mixture of 416 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 28 parts of a resin having a weight-average molecular weight (Mw) of 8.2×10³ and a dispersion degree (Mw/Mn) of 1.86 in a yield of 71%. This resin had the structural units represented by the formula A, C, D and F. This is called as resin R10. The ratio of the structural units represented by the formula A, C, D and F (A/C/D/F) was 39/12/10/39.

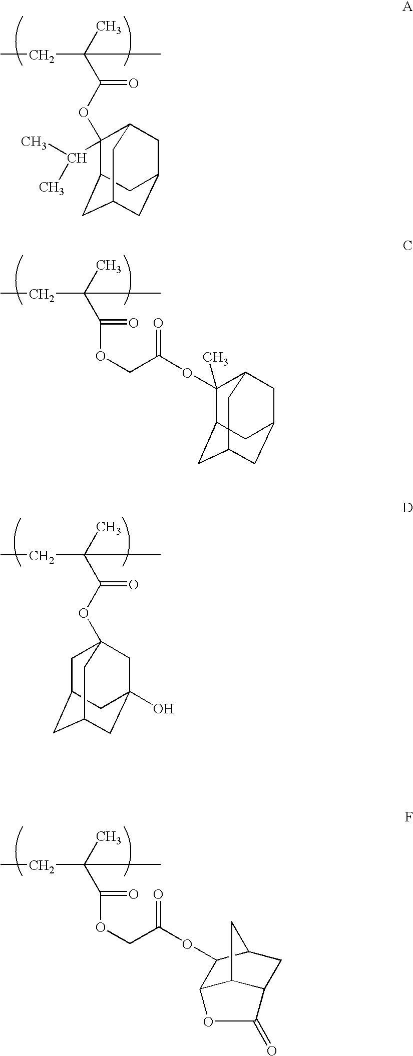

### Resin Synthetic Example 10

Into a flask equipped with a condenser and a thermometer, 10.01 parts of 1,4-dioxane was charged and a nitrogen gas was blown into it for 30 minutes. After heating it up to 75° C. under nitrogen, a solution obtained by mixing 25.40 parts of monomer M1, 4.16 parts of monomer M4, 10.48 parts of monomer M5, 0.29 parts of 2,2′-azobisisobutyronitrile, 1.31 parts of 2,2′-azobis(2,4-dimethylvaleronitrile) and 30.03 parts of 1,4-dioxane was added dropwise thereto over 1 hour at 75° C. The resultant mixture was stirred for 5 hours at 75° C. After cooling the reaction mixture, the reaction mixture was diluted with 64.07 parts of 1,4-dioxane and the resultant solution was poured into 521 parts of methanol to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 21 parts of a resin having a weight-average molecular weight (Mw) of 7.7×10³ and a dispersion degree (Mw/Mn) of 1.48 in a yield of 53%. This resin had the structural units represented by the formula A, D and E. This is called as resin R11. The ratio of the structural units represented by the formula A, D and E (A/D/E) was 43/12/45.

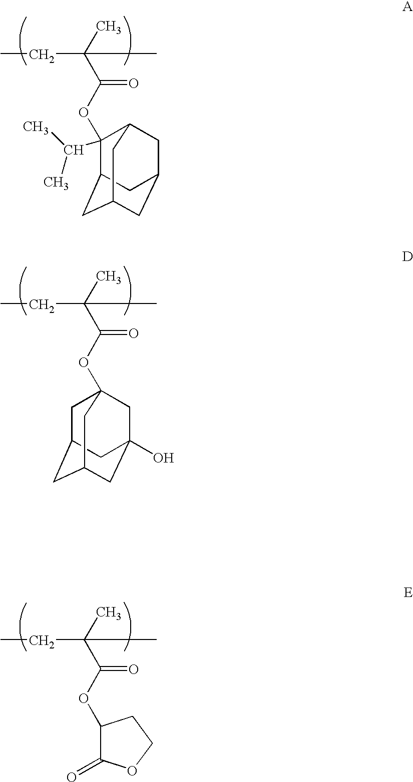

### Resin Synthetic Example 11

Into a flask equipped with a condenser and a thermometer, 10.00 parts of 1,4-dioxane was charged and a nitrogen gas was blown into it for 30 minutes. After heating it up to 70° C. under nitrogen, a solution obtained by mixing 35.80 parts of monomer M1, 1.50 parts of monomer M4, 2.70 parts of monomer M5, 0.26 parts of 2,2′-azobisisobutyronitrile, 1.18 parts of 2,2′-azobis(2,4-dimethylvaleronitrile) and 30.00 parts of 1,4-dioxane was added dropwise thereto over 1 hour at 70° C. The resultant mixture was stirred for 5 hours at 70° C. After cooling the reaction mixture, the reaction mixture was diluted with 64.00 parts of 1,4-dioxane and the resultant solution was poured into a mixture of 416 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 18 parts of a resin having a weight-average molecular weight (Mw) of 4.3×10³ and a dispersion degree (Mw/Mn) of 1.65 in a yield of 46%. This resin had the structural units represented by the formula A, D and E. This is called as resin R12. The ratio of the structural units represented by the formula A, D and E (A/D/E) was 75/7/18.

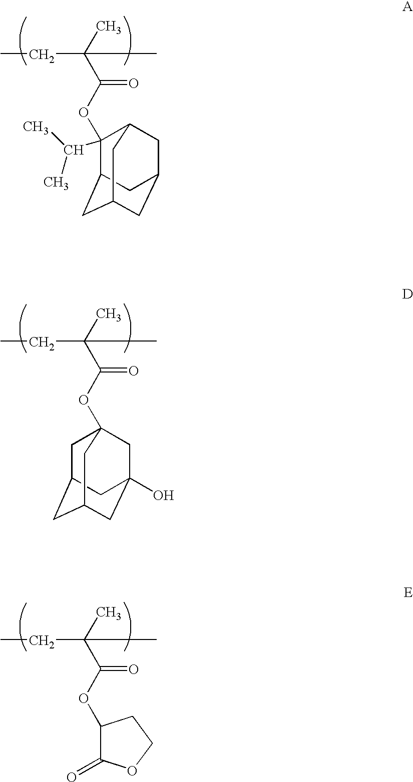

### Resin Synthetic Example 12

Into a flask equipped with a condenser and a thermometer, 19.16 parts of 1,4-dioxane was charged and a nitrogen gas was blown into it for 30 minutes. After heating it up to 75° C. under nitrogen, a solution obtained by mixing 20.00 parts of monomer M1, 2.99 parts of monomer M7, 1.54 parts of monomer M8, 15.38 parts of monomer M6, 0.25 parts of 2,2′-azobisisobutyronitrile, 1.14 parts of 2,2′-azobis(2,4-dimethylvaleronitrile) and 28.74 parts of 1,4-dioxane was added dropwise thereto over 1 hour at 75° C. The resultant mixture was stirred for 5 hours at 75° C. After cooling the reaction mixture, the reaction mixture was diluted with 55.88 parts of 1,4-dioxane and the resultant solution was poured into a mixture of 415 parts of methanol and 104 parts of ion-exchanged water to cause precipitation. The precipitate was isolated and mixed with 259 parts of methanol. The resultant mixture was stirred followed by filtrating to obtain the precipitate. The operation wherein the precipitate was mixed with 259 parts of methanol and the resultant mixture was stirred followed by filtrating to obtain the precipitate was repeated twice. The obtained precipitate was dried under reduced pressure to obtain 29 parts of a resin having a weight-average molecular weight (Mw) of 7.5×10³ and a dispersion degree (Mw/Mn) of 1.83 in a yield of 72%. This resin had the structural units represented by the formula A, G, H and F.

This is called as resin R13. The ratio of the structural units represented by the formula A, G, H and F (A/G/H/F) was 39/11/5/45.

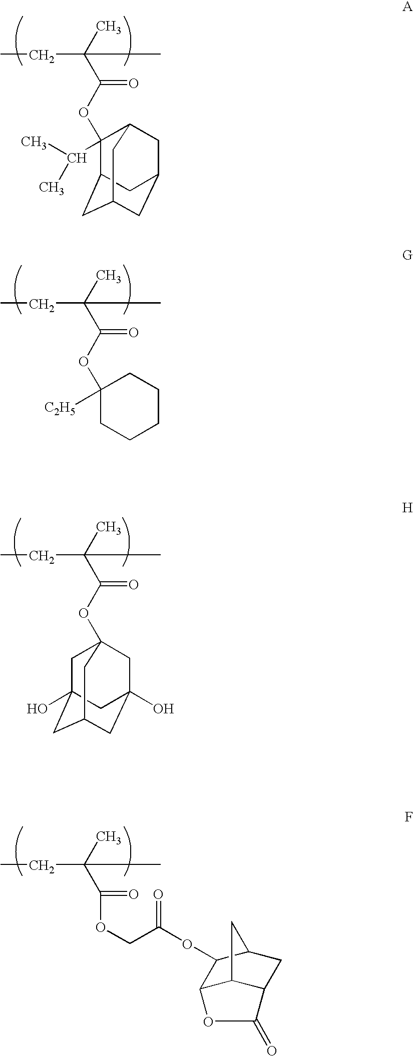

### Resin Synthetic Example 13

Into a flask equipped with a condenser and a thermometer, 19.21 parts of 1,4-dioxane was charged and a nitrogen gas was blown into it for 30 minutes. After heating it up to 75° C. under nitrogen, a solution obtained by mixing 21.40 parts of monomer M1, 3.20 parts of monomer M7, 1.65 parts of monomer M8, 9.60 parts of monomer M6, 4.16 parts of monomer M5, 0.25 parts of 2,2′-azobisisobutyronitrile, 1.15 parts of 2,2′-azobis(2,4-dimethylvaleronitrile) and 28.81 parts of 1,4-dioxane was added dropwise thereto over 1 hour at 75° C. The resultant mixture was stirred for 5 hours at 75° C. After cooling the reaction mixture, the reaction mixture was diluted with 56.02 parts of 1,4-dioxane and the resultant solution was poured into a mixture of 416 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 28 parts of a resin having a weight-average molecular weight (Mw) of 7.1×10³ and a dispersion degree (Mw/Mn) of 1.83 in a yield of 71%. This resin had the structural units represented by the formula A, G, H, F and

E. This is called as resin R14. The ratio of the structural units represented by the formula A, G, H, F and E (A/G/H/F/E) was 39/10/5/27/19.

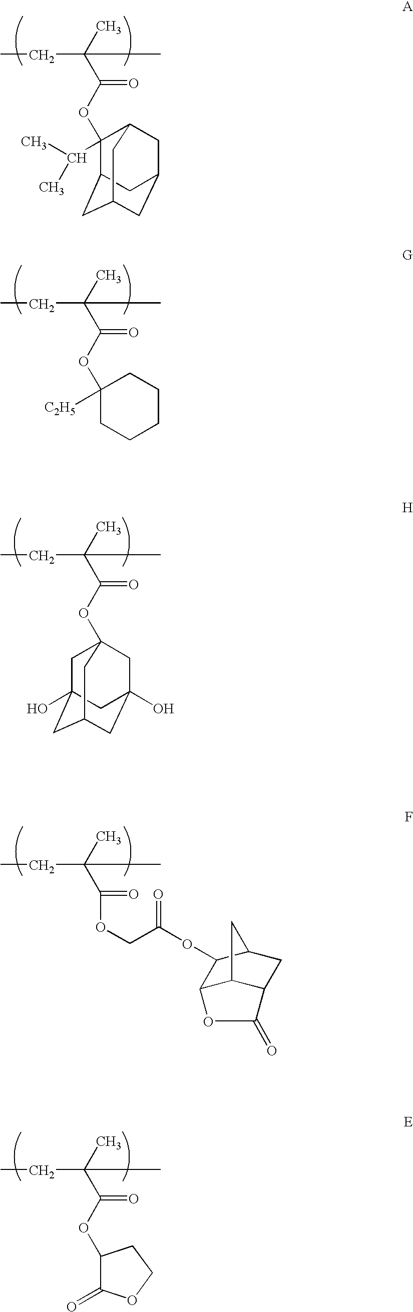

### Resin Synthetic Example 14

Into a flask equipped with a condenser and a thermometer, 10.01 parts of 1,4-dioxane was charged and a nitrogen gas was blown into it for 30 minutes. After heating it up to 75° C. under nitrogen, a solution obtained by mixing 24.90 parts of monomer M1, 2.96 parts of monomer M4, 12.19 parts of monomer M5, 0.29 parts of 2,2′-azobisisobutyronitrile, 1.33 parts of 2,2′-azobis(2,4-dimethylvaleronitrile) and 30.04 parts of 1,4-dioxane was added dropwise thereto over 1 hour at 75° C. The resultant mixture was stirred for 5 hours at 75° C. After cooling the reaction mixture, the reaction mixture was diluted with 64.08 parts of 1,4-dioxane and the resultant solution was poured into a mixture of 417 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 28 parts of a resin having a weight-average molecular weight (Mw) of 6.7×10³ and a dispersion degree (Mw/Mn) of 1.75 in a yield of 70%. This resin had the structural units represented by the formula A, D and E. This is called as resin R15. The ratio of the structural units represented by the formula A, D and E (A/D/E) was 41/9/50.

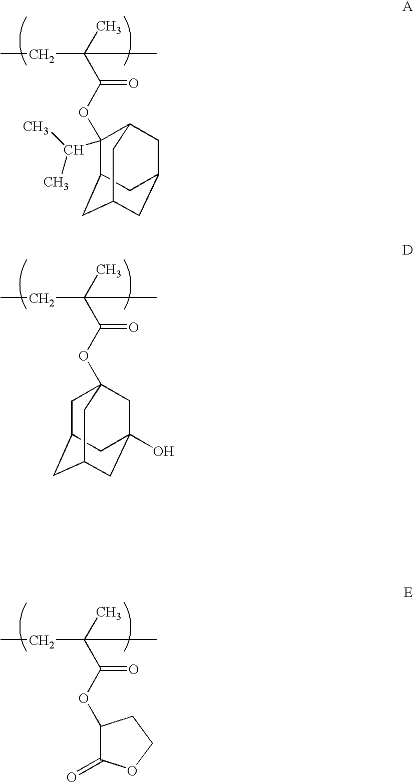

### Resin Synthetic Example 15

Into a flask equipped with a condenser and a thermometer, 19.18 parts of 1,4-dioxane was charged and a nitrogen gas was blown into it for 30 minutes. After heating it up to 75° C. under nitrogen, a solution obtained by mixing 23.60 parts of monomer M1, 3.53 parts of monomer M7, 1.82 parts of monomer M8, 11.02 parts of monomer M5, 0.30 parts of 2,2′-azobisisobutyronitrile, 1.34 parts of 2,2′-azobis(2,4-dimethylvaleronitrile) and 28.78 parts of 1,4-dioxane was added dropwise thereto over 1 hour at 75° C. The resultant mixture was stirred for 5 hours at 75° C. After cooling the reaction mixture, the reaction mixture was diluted with 55.95 parts of 1,4-dioxane and the resultant solution was poured into a mixture of 416 parts of methanol and 104 parts of ion-exchanged water to cause precipitation. The precipitate was isolated and mixed with 260 parts of methanol. The resultant mixture was stirred followed by filtrating to obtain the precipitate. The operation wherein the precipitate was mixed with 260 parts of methanol and the resultant mixture was stirred followed by filtrating to obtain the precipitate was repeated twice. The obtained precipitate was dried under reduced pressure to obtain 27 parts of a resin having a weight-average molecular weight (Mw) of 6.1×10³ and a dispersion degree (Mw/Mn) of 1.81 in a yield of 68%. This resin had the structural units represented by the formula A, G, H and E. This is called as resin R16. The ratio of the structural units represented by the formula A, G, H and E (A/G/H/E) was 39/10/5/46.

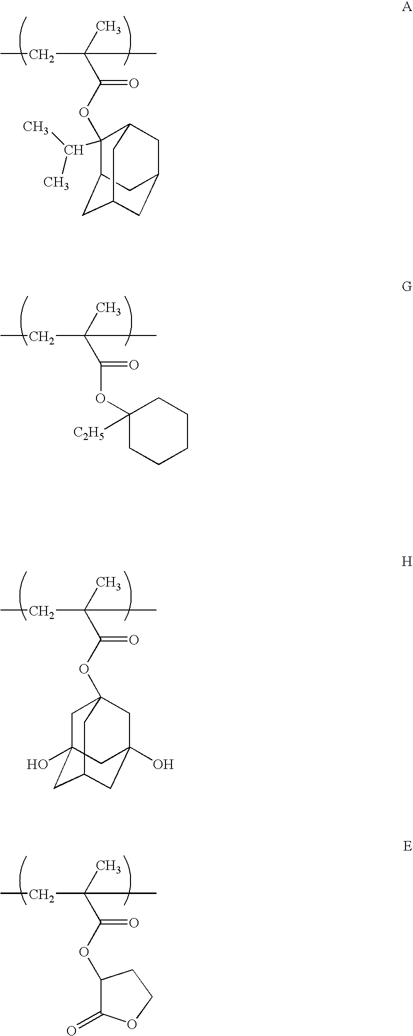

### Examples 1 to 17 and Comparative Example 1

### <Acid Generator>

Acid generator C1: (4-methylphenyl)diphenylsulfonium perfluorobutanesulfonate
Acid generator C2:

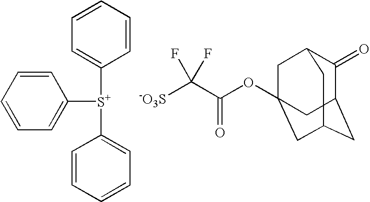

### <Resin>

Resin R1 to R16

### <Quencher>

Q1: 2,6-diisopropylaniline

### <Solvent>

| | | |
|---|---|---|
| S1: | propylene glycol monomethyl ether acetate | 130 parts |
| | propylene glycol monomethyl ether | 35 parts |
| | 2-heptanone | 20 parts |
| | γ-butyrolactone | 5 parts |

The following components were mixed and dissolved, further, filtrated through a nylon filter having pore diameter of 0.2 μm, a fluorine resin filter having pore diameter of 0.1 μm and a polyethylene filter having pore diameter of 0.03 μm, to prepare resist composition.
Resin (kind and amount are described in Table 1)
Acid generator (kind and amount are described in Table 1)
Quencher (kind and amount are described in Table 1)
Solvent (kind is described in Table 1)

TABLE 1

| | | Acid | | | |
|---|---|---|---|---|---|
| | Resin | generator | Quencher | | |
| Ex. | (kind/amount | (kind/amount | (kind/amount | | PEB |
| No. | (part)) | (part)) | (part)) | Solvent | (° C.) |
| Ex. 1 | R1/10 | C1/0.5 | Q1/0.02 | S1 | 85 |
| Ex. 2 | R2/10 | C1/0.5 | Q1/0.02 | S1 | 85 |
| Ex. 3 | R3/10 | C1/0.5 | Q1/0.02 | S1 | 85 |
| Ex. 4 | R2/10 | C2/0.5 | Q1/0.02 | S1 | 90 |
| Ex. 5 | R3/10 | C2/0.5 | Q1/0.02 | S1 | 90 |
| Ex. 6 | R5/10 | C1/0.5 | Q1/0.02 | S1 | 85 |
| Ex. 7 | R6/10 | C1/0.5 | Q1/0.02 | S1 | 85 |
| Ex. 8 | R7/10 | C1/0.5 | Q1/0.02 | S1 | 85 |
| Ex. 9 | R8/10 | C1/0.5 | Q1/0.02 | S1 | 85 |
| Ex. 10 | R9/10 | C1/0.5 | Q1/0.02 | S1 | 85 |
| Ex. 11 | R10/10 | C1/0.5 | Q1/0.02 | S1 | 85 |
| Ex. 12 | R11/10 | C1/0.5 | Q1/0.02 | S1 | 85 |
| Ex. 13 | R12/10 | C1/0.5 | Q1/0.02 | S1 | 85 |
| Ex. 14 | R13/10 | C1/0.5 | Q1/0.02 | S1 | 85 |
| Ex. 15 | R14/10 | C1/0.5 | Q1/0.02 | S1 | 85 |
| Ex. 16 | R15/10 | C1/0.5 | Q1/0.02 | S1 | 85 |
| Ex. 17 | R16/10 | C1/0.5 | Q1/0.02 | S1 | 85 |
| Comp. | R4/10 | C1/0.5 | Q1/0.02 | S1 | 110 |
| Ex. 1 | | | | | |

Silicon wafers were each coated with “ARC-29A”, which is an organic anti-reflective coating composition available from Nissan Chemical Industries, Ltd., and then baked under the conditions: 205° C., 60 seconds, to form a 780 Å-thick organic anti-reflective coating. Each of the resist liquids prepared as above was spin-coated over the anti-reflective coating so that the thickness of the resulting film became 150 nm after drying. The silicon wafers thus coated with the respective resist liquids were each prebaked on a direct hotplate at 110° C. for 60 seconds. Using an ArF excimer stepper (“FPA5000-AS3” manufactured by CANON INC., NA=0.75, σ=0.85), each wafer thus formed with the respective resist film was subjected to contact hole pattern exposure, with the exposure quantity being varied by 0.5 mJ/cm².

After the exposure, each wafer was subjected to post-exposure baking on a hotplate at a temperature shown in column of “PEB” of Table 1 for 60 seconds and then to paddle development for 60 seconds with an aqueous solution of 2.38wt % tetramethylammonium hydroxide.

Each of hole patterns developed on the organic anti-reflective coating substrate after the development was observed with a scanning electron microscope, the results of which are shown in Tables 2.

Effective Sensitivity (ES): It was expressed as the amount of exposure that hole diameter of the hole pattern became 110 nm after exposure using a mask having a pitch of 210 nm and a hole diameter of 130 nm and development.

Mask Error Enhancement Factor (MEEF): Hole diameters of each hole patterns exposed at ES using masks having a pitch of 210 nm and a hole diameter of 125 to 135 nm with 1 nm increments in between and developed were measured. Hole diameters measured were plotted against the hole diameters of masks, and the slope of the line was calculated. MEEF was expressed as the value of the slope of the line. The smaller the value is, the better MEEF is.

Pattern Profile: The hole patterns after exposure using a mask having a pitch of 210 nm and a hole diameter of 140 nm and development were observed with a scanning electron microscope. In one filed of the scanning electron microscope, 25 holes were observed, and when neighboring holes were connected, resolution is bad and its evaluation is marked by “×”, and when neighboring holes were not connected, resolution is good and its evaluation is marked by “◯”.

TABLE 2

| Ex. No. | ES (mJ/cm²) | MEEF | Pattern Profile |
|---|---|---|---|
| Ex. 1 | 31 | 5.04 | ◯ |
| Ex. 2 | 26 | 5.29 | ◯ |
| Ex. 3 | 25 | 5.25 | ◯ |
| Ex. 4 | 35 | 4.82 | ◯ |
| Ex. 5 | 34 | 4.68 | ◯ |
| Ex. 6 | 34 | 5.46 | ◯ |
| Ex. 7 | 33 | 5.36 | ◯ |
| Ex. 8 | 37 | 5.24 | ◯ |
| Ex. 9 | 41 | 5.60 | ◯ |
| Ex. 10 | 42 | 5.09 | ◯ |
| Ex. 11 | 29 | 5.60 | ◯ |
| Ex. 12 | 33 | 5.06 | ◯ |
| Ex. 13 | 28 | 5.21 | ◯ |
| Ex. 14 | 23 | 5.58 | ◯ |
| Ex. 15 | 22 | 5.64 | ◯ |
| Ex. 16 | 26 | 5.41 | ◯ |
| Ex. 17 | 22 | 5.50 | ◯ |
| Comp. | 25 | 5.85 | X |
| Ex. 1 | | | |

The present resist composition provides a resist pattern having good pattern profile and good MEEF, and is especially suitable for ArF excimer laser lithography, KrF excimer laser lithography and ArF immersion lithography.

What is claimed is:

1. A chemically amplified positive resist composition comprising: a resin comprising a structural unit having an acid-labile group in a side chain and an acid generator wherein the resin contains 40 to 90% by mole of the structural unit having an acid-labile group in a side chain based on total molar amounts of all the structural units and the structural unit having an acid-labile group in a side chain contains a structural unit represented by the formula (I): 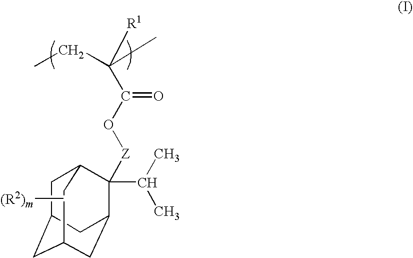
wherein R¹ represents a hydrogen atom or a methyl group, Z represents a single bond or —(CH₂)ₖ—CO—O—, k represents an integer of 1 to 4, R² is independently in each occurrence a C1-C6 alkyl group, and m represents an integer of 0 to 14.

2. The chemically amplified positive resist composition according to claim 1, wherein the resin contains 50 to 70% by mole of the structural unit having an acid-labile group in a side chain based on total molar amounts of all the structural units.

3. The chemically amplified positive resist composition according to claim 1, wherein the structural unit having an acid-labile group in a side chain further contains a structural unit represented by the formula (II): 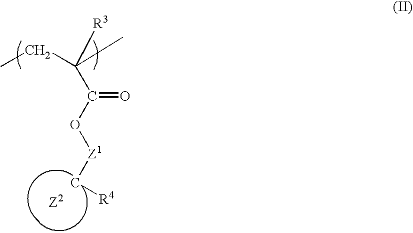
wherein R³ represents a hydrogen atom or a methyl group, Z¹ represents a single bond or —(CH₂)ⱼ—CO—O—, j represents an integer of 1 to 4, R⁴ represents a C1-C8 alkyl group or a C3-C8 cycloalkyl group, and ring Z² represents an unsubstituted or substituted C3-C30 cyclic hydrocarbon group, in addition to the structural unit represented by the formula (I), with the proviso that the structural unit represented by the formula (II) is different from the unit represented by the formula (I).

4. The chemically amplified positive resist composition according to claim 1, wherein the resin further contains a structural unit represented by the formula (IV): 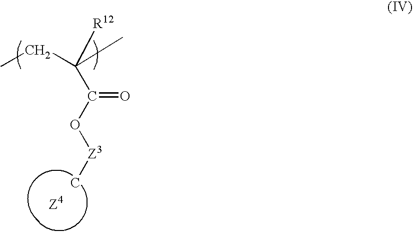
wherein R¹² represents a hydrogen atom or a methyl group, Z³ represents a single bond or —(CH₂)ᵢ—CO—O—, i represents an integer of 1 to 4, and ring Z⁴ represents an unsubstituted or substituted C3-C30 cyclic hydrocarbon group having —CO—O— in the ring structure.

5. The chemically amplified positive resist composition according to claim 1, wherein the acid generator is an acid generator represented by the formula (V): 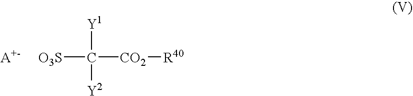
wherein Y¹ and Y² each independently represent a fluorine atom or a C1-C6 perfluoroalkyl group, R⁴⁰ representsa C1-C36 hydrocarbon group which may have at least one selected from the group consisting of a C1-C6 alkoxy group, a C1-C4 perfluoroalkyl group, a C1-C6 hydroxyalkyl group, a hydroxyl group and a cyano group, and one or more —CH₂— in the hydrocarbon group may be replaced by —CO—, —O— or —COO—, and A⁺ represents an organic counter ion.
